(19) United States
(12) Patent Application Publication
(10) Pub. No.: US 2026/0169377 A1
(43) Pub. Date: Jun. 18, 2026

(54) RESIST COMPOSITION, METHOD FOR MANUFACTURING SEMICONDUCTOR DEVICES USING THE SAME AND MULTILAYERED STRUCTURE FORMED USING THE SAME

(71) Applicants: Samsung Electronics Co., Ltd., Suwon-si (KR); Inha University Research and Business Foundation, Incheon (KR)

(72) Inventors: Sung Il LEE, Suwon-si (KR); Jin-Kyun LEE, Incheon (KR); Jin CHOI, Suwon-si (KR); Changyoung JEONG, Suwon-si (KR); Choonghan RYU, Suwon-si (KR); Gayoung KIM, Incheon (KR); Subin JEON, Incheon (KR); Yejin KU, Incheon (KR); Suyoung YOO, Incheon (KR)

(73) Assignees: Samsung Electronics Co., Ltd., Suwon-si (KR); Inha University Research and Business Foundation, Incheon (KR)

(21) Appl. No.: 19/418,210

(22) Filed: Dec. 12, 2025

(30) Foreign Application Priority Data
Dec. 13, 2024 (KR) 10-2024-0186488
Aug. 27, 2025 (KR) 10-2025-0120535

(51) Int. Cl. G03F 7/004; G03F 7/32; H10P 76/20

(52) U.S. Cl. CPC G03F 7/0043; H10P 76/2041; G03F 7/322

(57) ABSTRACT

A resist composition includes a tin oxide nanocluster. The tin oxide nanocluster includes a core structure including tin oxide, a counter anion bonded to the core structure, and an organic ligand bonded to the core structure. The counter anion includes a functional group functioning as a Lewis base.

### CROSS-REFERENCE TO RELATED APPLICATION

This application claims priority to Korean Patent Application No. 10-2024-0186488, filed in the Korean Intellectual Property Office on Dec. 13, 2024, and Korean Patent Application No. 10-2025-0120535, filed in the Korean Intellectual Property Office on Aug. 27, 2025, the entire contents of which are hereby incorporated by reference.

### BACKGROUND

### Field

The present disclosure relates to a resist composition, a method for manufacturing a semiconductor device using the resist composition, and a multilayer structure formed using the resist composition.

### Description of Related Art

Photolithography may include an exposure process and a development process. Performing the exposure process may include irradiating light of a specific wavelength onto a portion of a resist film to cause a change in the chemical structure of the exposed portion of the resist film. Performing the development process may include selectively removing an exposed portion or an unexposed portion of the resist film using a difference in solubility between the exposed portion and the unexposed portion of the resist film. The remaining resist film may be used as a mask in a subsequent photolithography process.

Recently, as semiconductor devices have become highly integrated and miniaturized, line widths of patterns in the semiconductor devices have been reduced. To form fine patterns, various studies have been conducted to improve resolution and sensitivity of resist patterns formed by photolithography.

### SUMMARY

The present disclosure relates to a resist composition, a method for manufacturing a semiconductor device using the resist composition, and a multilayer structure formed using the resist composition.

A technical problem to be achieved by the present disclosure is to provide a metal oxide-based resist composition usable in ultraviolet and electron beam lithography.

Another technical problem to be achieved by the present disclosure is to provide a method for manufacturing a semiconductor device using the resist composition, and a multilayer structure formed using the resist composition.

The problems to be solved by the present disclosure are not limited to those described above, and other problems not mentioned may be clearly understood by one of ordinary skill in the art from the description of the disclosure below.

In some embodiments, a resist composition may include a tin oxide nanocluster, wherein the tin oxide nanocluster includes a core structure including tin oxide, a counter anion bonded to the core structure, and an organic ligand bonded to the core structure, and the counter anion includes a functional group functioning as a Lewis base.

In some embodiments, a method for manufacturing a semiconductor device may include forming an etch target film on a substrate, forming a photoresist film on the etch target film, performing an exposure process on the photoresist film, and performing a development process to selectively remove an exposed region or an unexposed region of the photoresist film, wherein the photoresist film may include a resist composition including a tin oxide nanocluster, and the tin oxide nanocluster may include a core structure including tin oxide, a counter anion bonded to the core structure, and an organic ligand bonded to the core structure, and the counter anion includes a functional group functioning as a Lewis base.

In some embodiments, a multilayer structure may include a substrate, an etch target film on the substrate, and a photoresist film on the etch target film, wherein the photoresist film may include a resist composition including a tin oxide nanocluster, and the tin oxide nanocluster may include a core structure including tin oxide, a counter anion bonded to the core structure, and an organic ligand bonded to the core structure, and the counter anion may include a functional group functioning as a Lewis base.

By applying a resist composition according to at least one embodiment of the present disclosure, a photoresist film may have higher resolution and/or sensitivity with respect to electron beam and ultraviolet lithography processes. Further, the etch resistance may be increased.

By applying a resist composition according to at least one embodiment of the present disclosure, solubility in a developer in an exposed region of a photoresist film may be adjusted and/or controlled, and a dissolution contrast between the exposed region and an unexposed region of the photoresist film may be increased.

By applying a resist composition according to at least one embodiment of the present disclosure, a distribution of tin oxide nanoclusters in a photoresist film may be maintained more homogeneously, and accordingly, line width roughness during pattern formation may be reduced, so that occurrence of pattern defects may be reduced and/or suppressed.

The effects that may be obtained through the present disclosure are not limited to those described above. Unmentioned technical effects may be clearly understood by those of ordinary skill in the art from the description of the disclosure provided below.

### BRIEF DESCRIPTION OF THE DRAWINGS

FIG. 1a illustrates a ¹H-NMR graph of 8FDESTER synthesized according to Experimental Example 1, and FIG. 1b illustrates a ¹⁹F-NMR graph.

FIG. 2a illustrates a 1H-NMR graph of 10FDESTER synthesized according to Experimental Example 2, and FIG. 2b illustrates a 19F-NMR graph.

FIG. 3a illustrates a 1H-NMR graph of 12FDESTER synthesized according to Experimental Example 3, and FIG. 3b illustrates a 19F-NMR graph.

FIG. 4a illustrates a 1H-NMR graph of 10FDAMIDE synthesized according to Experimental Example 4, and FIG. 4b illustrates a 19F-NMR graph.

FIG. 5a illustrates a 1H-NMR graph of 8FDEBTOC synthesized according to Experimental Example 5, FIG. 5b illustrates a 19F-NMR graph, FIG. 5c illustrates a 119Sn-NMR graph, and FIG. 5d illustrates an FT-IR graph of 8FDEBTOC synthesized according to Experimental Example 5.

FIG. 6a illustrates a 1H-NMR graph of 10FDEBTOC synthesized according to Experimental Example 6, FIG. 6b illustrates a 19F-NMR graph, FIG. 6c illustrates a 119Sn-NMR graph, and FIG. 6d illustrates an FT-IR graph of 10FDEBTOC synthesized according to Experimental Example 6.

FIG. 7a illustrates a 1H-NMR graph of 12FDEBTOC synthesized according to Experimental Example 7, FIG. 7b illustrates a 19F-NMR graph, FIG. 7c illustrates a 119Sn-NMR graph, and FIG. 7d illustrates an FT-IR graph of 12FDEBTOC synthesized according to Experimental Example 7.

FIG. 8a illustrates a 1H-NMR graph of 10FDABTOC synthesized according to Experimental Example 8, FIG. 8b illustrates a 19F-NMR graph, FIG. 8c illustrates a 119Sn-NMR graph, and FIG. 8d illustrates an FT-IR graph of 10FDABTOC synthesized according to Experimental Example 8.

FIG. 9 illustrates solubility characteristics of 8FDEBTOC, 10FDEBTOC, 12FDEBTOC, and 10FDABTOC obtained by performing 254 nm KrF lithography (deep ultraviolet) according to Experimental Example 9.

FIG. 10 illustrates positive patterns of 8FDEBTOC, 10FDEBTOC, and 12FDEBTOC observed through a scanning electron microscope (SEM) after performing electron beam lithography according to Experimental Examples 10 and 11.

FIG. 11a illustrates a 1H-NMR graph of 10FDTHIOESTER synthesized according to Experimental Example 12, and FIG. 11b illustrates a 19F-NMR graph.

FIG. 12a illustrates a 1H-NMR graph of 12FDTHIOESTER synthesized according to Experimental Example 13, and FIG. 12b illustrates a 19F-NMR graph.

FIG. 13a illustrates a 1H-NMR graph of 10FDTBTOC synthesized according to Experimental Example 14, FIG. 13b illustrates a 19F-NMR graph, FIG. 13c illustrates a 119Sn-NMR graph, and FIG. 13d illustrates an FT-IR graph of 10FDTBTOC synthesized according to Experimental Example 14.

FIG. 14a illustrates a 1H-NMR graph of 12FDTBTOC synthesized according to Experimental Example 15, FIG. 14b illustrates a 19F-NMR graph, FIG. 14c illustrates a 119Sn-NMR graph, and FIG. 14d illustrates an FT-IR graph of 12FDTBTOC synthesized according to Experimental Example 15.

FIG. 15 illustrates solubility characteristics of 10FDTBTOC and 12FDTBTOC obtained by performing 254 nm KrF lithography (deep ultraviolet) according to Experimental Example 16.

FIG. 16 illustrates positive patterns of 10FDTBTOC and 12FDTBTOC observed through a scanning electron microscope after performing electron beam lithography according to Experimental Example 17.

FIG. 17 illustrates solubility characteristics of 10FDTBTOC and 12FDTBTOC obtained by performing extreme ultraviolet lithography according to Experimental Example 18.

FIG. 18 illustrates a 1H-NMR graph of 8PESTER synthesized according to Experimental Example 19.

FIG. 19 illustrates a 1H-NMR graph of 10PESTER synthesized according to Experimental Example 20.

FIG. 20 illustrates a 1H-NMR graph of 12PESTER synthesized according to Experimental Example 21.

FIG. 21 illustrates a 1H-NMR graph of 10PAMIDE synthesized according to Experimental Example 22.

FIG. 22 illustrates a 1H-NMR graph of 8DPESTER synthesized according to Experimental Example 23.

FIG. 23 illustrates a 1H-NMR graph of 10DPESTER synthesized according to Experimental Example 24.

FIG. 24 illustrates a 1H-NMR graph of 12DPESTER synthesized according to Experimental Example 25.

FIG. 25 illustrates a 1H-NMR graph of 10DPAMIDE synthesized according to Experimental Example 26.

FIG. 26a illustrates a 1H-NMR graph of 8PEBTOC synthesized according to Experimental Example 27, FIG. 26b illustrates a 119Sn-NMR graph, and FIG. 26c illustrates an FT-IR graph of 8PEBTOC synthesized according to Experimental Example 27.

FIG. 27a illustrates a 1H-NMR graph of 10PEBTOC synthesized according to Experimental Example 28, FIG. 27b illustrates a 119Sn-NMR graph, and FIG. 27c illustrates an FT-IR graph of 10PEBTOC synthesized according to Experimental Example 28.

FIG. 28a illustrates a 1H-NMR graph of 12PEBTOC synthesized according to Experimental Example 29, FIG. 28b illustrates a 119Sn-NMR graph, and FIG. 28c illustrates an FT-IR graph of 12PEBTOC synthesized according to Experimental Example 29.

FIG. 29a illustrates a 1H-NMR graph of 10PABTOC synthesized according to Experimental Example 30, FIG. 29b illustrates a 119Sn-NMR graph, and FIG. 29c illustrates an FT-IR graph of 10PABTOC synthesized according to Experimental Example 30.

FIG. 30a illustrates a 1H-NMR graph of 8DPEBTOC synthesized according to Experimental Example 31, FIG. 30b illustrates a 119Sn-NMR graph, and FIG. 30c illustrates an FT-IR graph of 8DPEBTOC synthesized according to Experimental Example 31.

FIG. 31a illustrates a 1H-NMR graph of 10DPEBTOC synthesized according to Experimental Example 32, FIG. 31b illustrates a 119Sn-NMR graph, and FIG. 31c illustrates an FT-IR graph of 10DPEBTOC synthesized according to Experimental Example 32.

FIG. 32a illustrates a 1H-NMR graph of 12DPEBTOC synthesized according to Experimental Example 33, FIG. 32b illustrates a 119Sn-NMR graph, and FIG. 32c illustrates an FT-IR graph of 12DPEBTOC synthesized according to Experimental Example 33.

FIG. 33a illustrates a 1H-NMR graph of 10DPABTOC synthesized according to Experimental Example 34, FIG. 33b illustrates a 119Sn-NMR graph, and FIG. 33c illustrates an FT-IR graph of 10DPABTOC synthesized according to Experimental Example 34.

FIG. 34a illustrates a 1H-NMR graph of SBTOC synthesized according to Experimental Example 35, FIG. 34b illustrates a 119Sn-NMR graph, and FIG. 34c illustrates an FT-IR graph of SBTOC synthesized according to Experimental Example 35.

FIG. 35 illustrates solubility characteristics of 8PEBTOC, 10PEBTOC, 12PEBTOC, and 10PABTOC obtained by performing 254 nm ultraviolet lithography (deep ultraviolet) according to Experimental Example 36.

FIG. 36 illustrates solubility characteristics of 8DPEBTOC, 10DPEBTOC, and 12DPEBTOC obtained by performing 254 nm ultraviolet lithography (deep ultraviolet) according to Experimental Example 37.

FIG. 37 illustrates positive patterns of 10PEBTOC, 12PEBTOC, 10PABTOC, and 10DPEBTOC observed through a scanning electron microscope after performing electron beam lithography according to Experimental Example 38.

FIG. 38 illustrates a positive pattern confirmed by performing 254 nm ultraviolet lithography (deep ultraviolet) of SBTOC according to Experimental Example 39 using a 2.38% TMAH standard aqueous solution as a developer.

FIGS. 39a and 39b illustrate negative patterns confirmed by performing 254 nm ultraviolet lithography (deep ultraviolet) of 12FDEBTOC according to Experimental Example 40 using cyclohexanone, an organic solvent, as a developer.

FIGS. 40 to 43 illustrate a method for manufacturing a semiconductor device using a resist composition according to embodiments of the present disclosure.

### DETAILED DESCRIPTION

In the present specification, unless otherwise specified, an alkyl group includes a linear, branched, or cyclic monovalent saturated hydrocarbon group.

In the present specification, a hydrocarbon ring includes an aliphatic hydrocarbon ring and an aromatic hydrocarbon ring. The hydrocarbon ring may be monocyclic or polycyclic. The number of carbon atoms in the aromatic hydrocarbon ring is not particularly limited, but may be 5 to 30. In the present specification, an aromatic ring may include an aromatic hydrocarbon ring. A hetero ring includes an aliphatic hetero ring and an aromatic hetero ring. The hetero ring may be monocyclic or polycyclic.

In the present specification, “substituted or unsubstituted” may mean substituted or unsubstituted with one or more substituents selected from the group consisting of a hydrogen atom, a deuterium atom, a halogen atom, a hydroxy group, an alkoxy group, an ether group, a halogenated alkyl group, a halogenated alkoxy group, a halogenated ether group, an alkyl group, an alkenyl group, an aryl group, a hydrocarbon ring group, and a hetero ring group. In addition, each of the exemplified substituents may be substituted or unsubstituted. For example, a halogenated alkoxy group may be interpreted as an alkoxy group.

In the present specification, unless otherwise defined, when a chemical bond is not drawn at a position where a chemical bond should be drawn, it may mean that a hydrogen atom is bonded to the position.

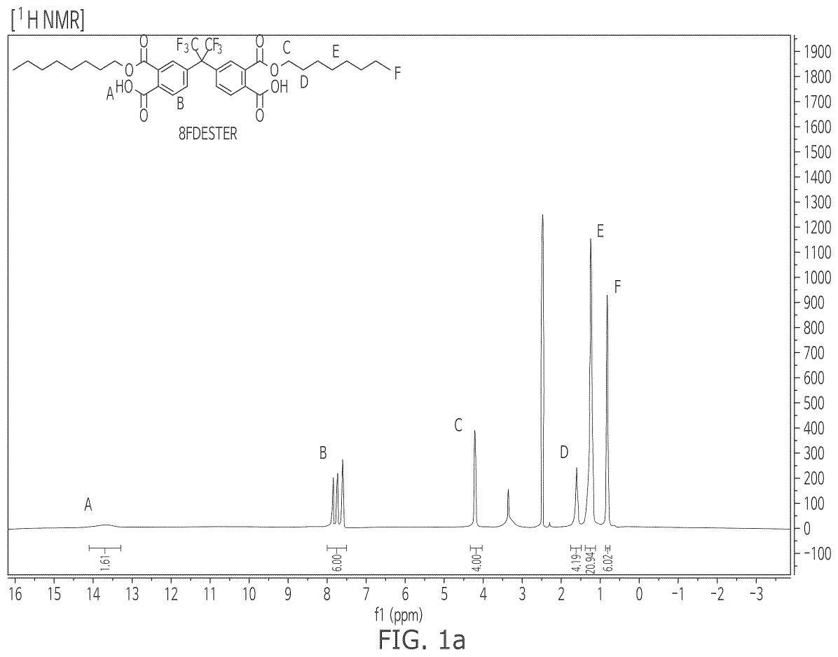

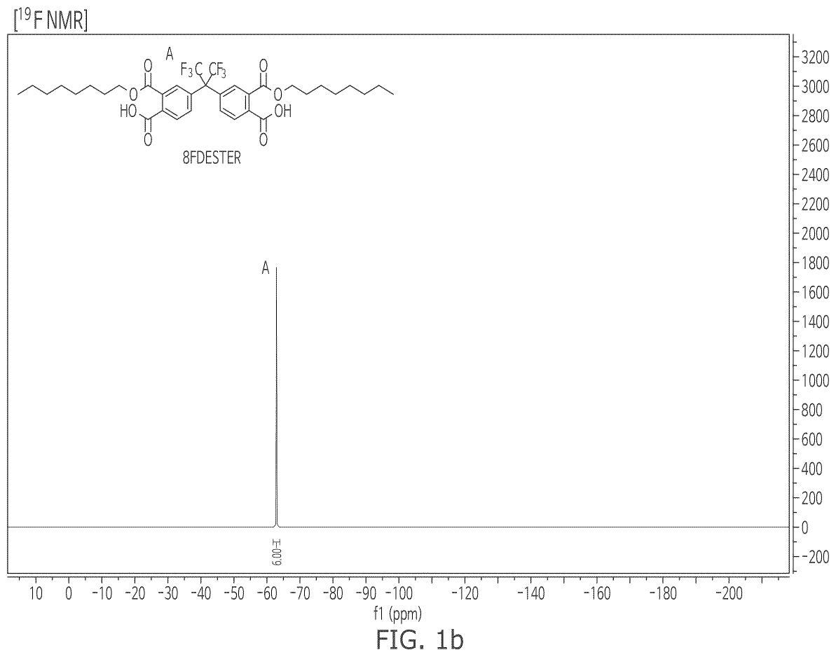

Hereinafter, various embodiments of the present disclosure will be described with reference to FIGS. 1a to 43. Throughout the specification, the same reference numerals may refer to the same components.

A resist composition according to some embodiments of the present disclosure is described.

A resist composition according to some embodiments of the present disclosure may be used in manufacturing a semiconductor device, and may be used in a photolithography process for manufacturing a semiconductor device. For example, the resist composition may be used in an ultraviolet or electron beam (e-beam) lithography process. The ultraviolet may be extreme ultraviolet or deep ultraviolet. The extreme ultraviolet may mean ultraviolet having a wavelength of 10 nm to 124 nm, a wavelength of 13.0 nm to 13.9 nm, and/or a wavelength of 13.4 nm to 13.6 nm. The deep ultraviolet may mean ultraviolet having a wavelength of 190 nm to 300 nm, a wavelength of 247 nm to 249 nm, and/or a wavelength of 192 nm to 194 nm.

In at least one embodiment, a resist composition may include a tin oxide nanocluster, and the tin oxide nanocluster may include a core structure including tin oxide, a counter anion bonded to the core structure, and an organic ligand bonded to the core structure. The tin oxide nanocluster may be represented by the following Chemical Formula 1.

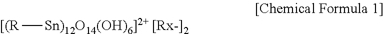

In Chemical Formula 1, R is the organic ligand, and Rx- is the counter anion.

The tin oxide nanocluster represented by Chemical Formula 1 may include a material represented by the following Structural Formula 1.

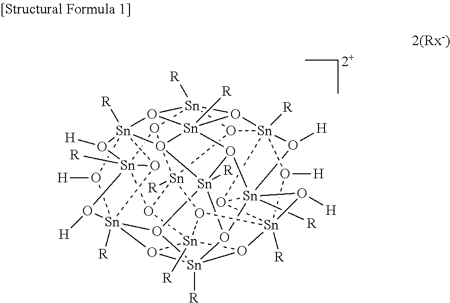

In the structural formula, R is the organic ligand, and Rx- is the counter anion. In Chemical Formula 1 and Structural Formula 1, R may be an alkyl group bonded to the core structure, and Rx- may be the counter anion bonded to the core structure.

In at least one embodiment, a tin oxide nanocluster may include a counter anion ionically bonded to a core structure including tin oxide. The counter anion may include a functional group functioning as a Lewis base. As the functional group functioning as a Lewis base exists in a state ionically bonded to the core structure rather than existing in a form of a separate compound, a single material may be constituted. Accordingly, compared to a case where a core structure including tin oxide and a separate compound including a Lewis basic functional group are constituted in a mixture form, a distribution of the resist composition may be maintained more homogeneously, and as a result, line width roughness during pattern formation may be reduced, and occurrence of pattern defects may be reduced and/or suppressed.

A counter anion bonded to a core structure may include a functional group functioning as a Lewis base. For example, the functional group included in the counter anion may be a functional group having a non-shared electron pair. The functional group having a non-shared electron pair may include, for example, a hydroxyl group, a phenol group, a thiol group, an amine group, a carboxylic acid group, an ester group, a carbonyl group, an amide group, a carbamate group, a urea group, a sulfoxy group, a sulfonyl group, a sulfone ester group, a cyanide group, an isocyanide group, a combination thereof, and/or the like.

A counter anion bonded to a core structure may correspond to a conjugate base of an organic acid. In at least one embodiment, the counter anion may include at least one conjugate base of organic acids, for example, at least one of carboxylic acid, sulfonic acid, and/or sulfonamide. For example, the counter anion may include a carboxylate anion, a sulfonate anion, a sulfonamidate anion, or a combination thereof. The carboxylate anion may include, for example, a pentanoate anion, a pentenoate anion, a methacrylate anion, a benzoate anion, a p-toluate anion, an acetate anion, an isobutyrate anion, a malonate anion, a combination thereof, and/or the like. The sulfonate anion may include, for example, a benzene sulfonate anion, a methane sulfonate anion, and a camphor-10-sulfonate anion, a combination thereof, and/or the like. However, the present disclosure is not limited thereto, and a different anion corresponding to a conjugate base of an organic acid and including a functional group functioning as a Lewis base may be applied.

The counter anion may include, for example, at least one conjugate base of an organic acid having chemical structures of the following Structural Formulas 2 to 4.

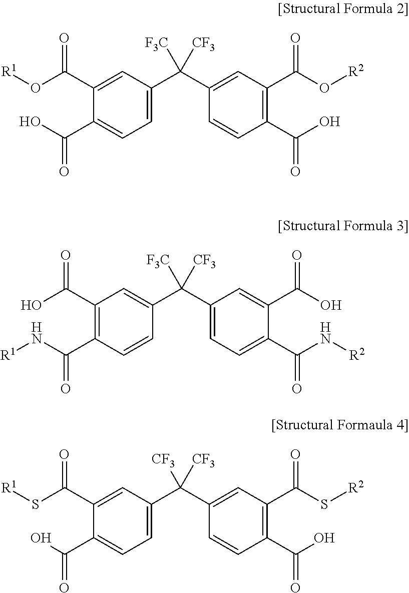

In Structural Formulas 2 to 4, R1 and R2 are alkyl groups having 6 to 18 carbon atoms.

The counter anion may include, for example, at least one conjugate base of an organic acid having a chemical structure of one of the following Structural Formulas 5 to 7.

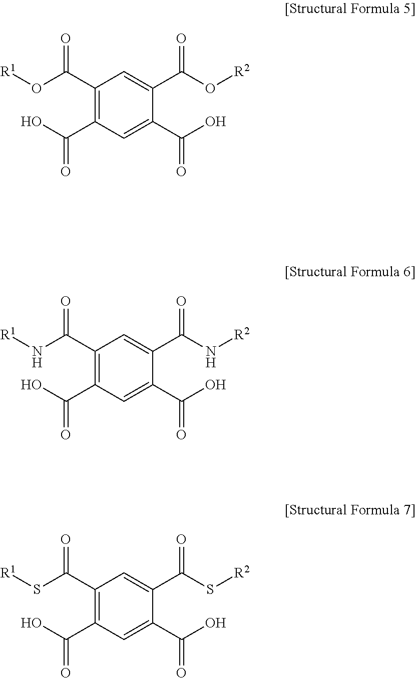

In Structural Formulas 5 to 7, R1 and R2 are alkyl groups having 6 to 18 carbon atoms.

The counter anion may include, for example, at least one conjugate base of an organic acid having chemical structures of the following Structural Formulas 8 to 10.

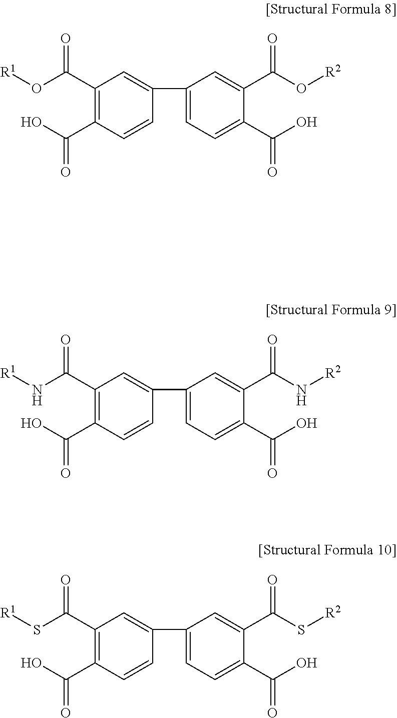

In Structural Formulas 8 to 10, R1 and R2 are alkyl groups having 6 to 18 carbon atoms.

The counter anion may include, for example, at least one conjugate base of an organic acid having chemical structures of the following Structural Formula 11. The organic acid having the chemical structure of the following Structural Formula 11 may correspond to saccharin.

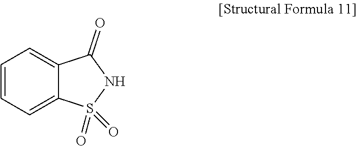 [SMILES: O=C1NS(=O)(=O)c2ccccc21]

A tin oxide nanocluster included in a resist composition may include an organic ligand (R) bonded to a core structure. For example, the organic ligand may be bonded to a tin element included in the core structure. For example, the organic ligand may be an alkyl group having 1 to 20 carbon atoms. In at least one embodiment, the organic ligand bonded to the core structure may be a butyl group.

When an electron beam or ultraviolet is irradiated onto a resist composition, an organic ligand may be detached from a tin oxide nanocluster by the electron beam or ultraviolet photons. For example, the organic ligand bonded to a core structure of the tin oxide nanocluster may be detached by the electron beam or ultraviolet photons, and accordingly, the core structure of the tin oxide nanocluster may have Lewis acidity. A counter anion bonded to a core structure of a tin oxide nanocluster has a functional group functioning as a Lewis base, and the functional group functioning as a Lewis base may be bonded to a tin atom that has lost the organic ligand through acid-base interaction. Accordingly, solubility of a resist composition in a developer may be adjusted and/or controlled, and a dissolution contrast between an exposed region and an unexposed region of a photoresist film formed of the resist composition may be increased.

In at least one embodiment, a resist composition may be a non-chemically amplified positive resist composition. As the resist composition includes a counter anion having a functional group functioning as a Lewis base, after irradiation with an electron beam or ultraviolet, the resist composition may have solubility in a basic (or alkali) developer. For example, after irradiation with the electron beam or ultraviolet, the functional group of the counter anion may bond to a core structure of a tin oxide nanocluster having Lewis acidity, thereby preventing (e.g., stopping, hindering, and/or mitigating) the core structure from mutually bonding and reducing solubility in the basic developer. Accordingly, an exposed region of a photoresist film formed of the resist composition may be removed by the basic developer, and a dissolution contrast between the exposed region and an unexposed region of the photoresist film may be increased.

In at least one embodiment, a resist composition may be a non-chemically amplified negative resist composition. As the resist composition includes an organic ligand bonded to a core structure including tin oxide, after irradiation with an electron beam or ultraviolet, solubility of the resist composition in an organic developer may be reduced. For example, after irradiation with the electron beam or ultraviolet, a core structure of a tin oxide nanocluster from which the organic ligand is detached may have Lewis acidity, and accordingly, at least some of core structures of the tin oxide nanocluster may be mutually bonded. For example, some of the core structures may interact with a functional group included in a counter anion, and some of the core structures may be mutually bonded. Accordingly, solubility of the resist composition in the organic developer may be reduced, an exposed region of a photoresist film formed of the resist composition may not be removed by the organic developer, and an unexposed region may be removed by the organic developer.

As a resist composition includes a tin oxide nanocluster according to at least one embodiment of the present disclosure, a photoresist film formed of the resist composition may have higher resolution and/or sensitivity with respect to electron beam and ultraviolet lithography processes. In addition, as the resist composition includes the tin oxide nanocluster according to at least one embodiment of the present disclosure, etch resistance of the photoresist film may be increased.

### [Experimental Example 1] Synthesis of 8FDESTER (Structural Formula 2, Reaction Scheme 1)

To a 100 cm³ round bottom flask (RBF), 6FDA (3.0 g, 6.8 mmol), octanol (2.67 cm³, 16.9 mmol), pyridine (1.75 cm³, 8.10 mmol), and 4-Dimethylaminopyridine (“DMAP”) (0.08 g, 0.68 mmol) were added, and toluene (20 cm³) was used as a solvent to stir at a temperature of 100 degrees (Celsius) for 2 hours. After completion of the reaction, a reaction solution was quenched using a 6N HCl aqueous solution (25 cm³) and diluted with toluene. Then, an organic solvent layer was washed three times with water, basified using a 20% Na₂CO₃ aqueous solution (50 cm³), and an aqueous solution layer including salt was separated. Then, the solution was diluted with toluene, and a HCl aqueous solution was slowly added dropwise to separate an organic layer and an aqueous solution layer. Thereafter, the organic solvent layer was washed with water. Thereafter, moisture included in the organic solvent layer was removed using anhydrous MgSO₄, and the solution was concentrated under reduced pressure. After freeze-drying, 8FDESTER (3.38 g, 71%), which is a viscous fluid, was obtained.

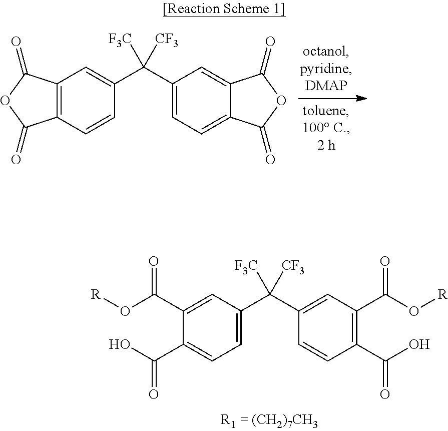

FIG. 1a illustrates a 1H-NMR (Nuclear Magnetic Resonance) graph of 8FDESTER synthesized according to Experimental Example 1, and FIG. 1b illustrates a 19F-NMR graph. (1H-NMR (400 MHz, DMSO, ppm): δ=13.62 (s, 2H, 2xOH), 7.92-7.63 (m, 6H, 6xCH), 4.23 (dd, J=15.0, 6.5 Hz, 4H, 2xCH2), 1.64 (dt, J=20.0, 6.5 Hz, 4H, 2xCH2), 1.30 (t, J=33.0 Hz, 20H, 10xCH2), 0.85 (dd, J=6.5, 5.0 Hz, 6H, 2xCH3), 19F-NMR (377 MHz, DMSO): δ=−63.14 (s, 6F, 2xCF3))

Referring to FIGS. 1a and 1b, it can be confirmed that 8FDESTER, which is a 4,4′-(Hexafluoroisopropylidene)diphthalic Anhydride (“6FDA”)-based diester compound having an octyl chain, was synthesized according to Experimental Example 1.

### [Experimental Example 2] Synthesis of 10FDESTER (Structural Formula 2, Reaction Scheme 2)

To a 100 cm³ RBF, 6FDA (3.0 g, 6.8 mmol), decanol (3.22 cm3, 16.9 mmol), pyridine (1.75 cm³, 8.10 mmol), and DMAP (0.08 g, 0.68 mmol) were added, and toluene (20 cm3) was used as a solvent to stir at a temperature of 100 degrees (Celsius) for 2 hours. After completion of the reaction, a reaction solution was quenched using a 6N HCl aqueous solution (25 cm³) and diluted with toluene. Then, an organic solvent layer was washed three times with water, basified using a 20% Na₂CO₃ aqueous solution (50 cm³), and an aqueous solution layer including salt was separated. Then, the solution was diluted with toluene, and a HCl aqueous solution was slowly added dropwise to separate an organic layer and an aqueous solution layer. Thereafter, the organic solvent layer was washed with water. Thereafter, moisture included in the organic solvent layer was removed using anhydrous MgSO₄, and the solution was concentrated under reduced pressure. After freeze-drying, 10FDESTER (3.70 g, 72%), which is a viscous fluid, was obtained.

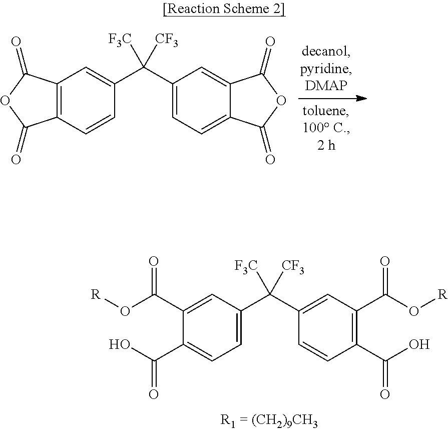

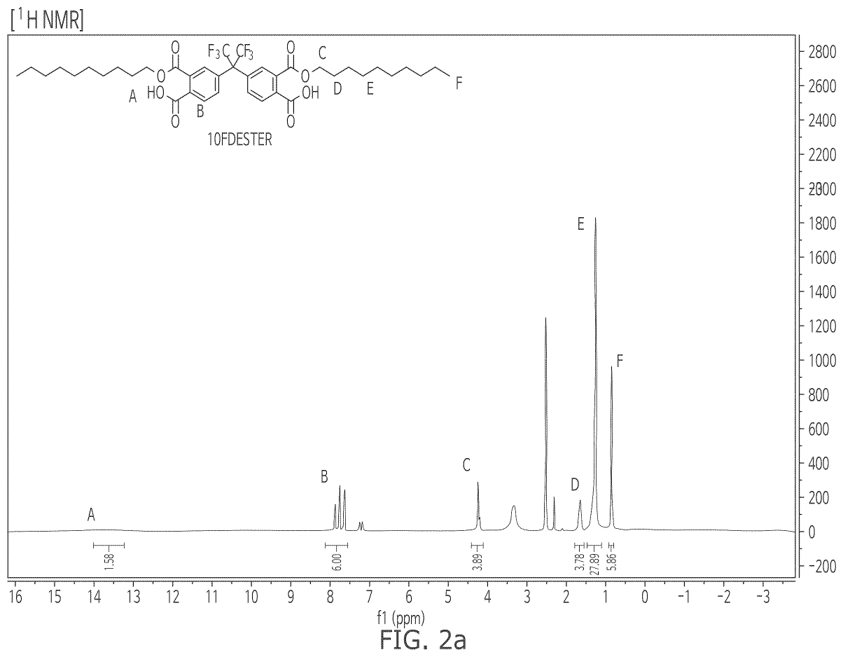

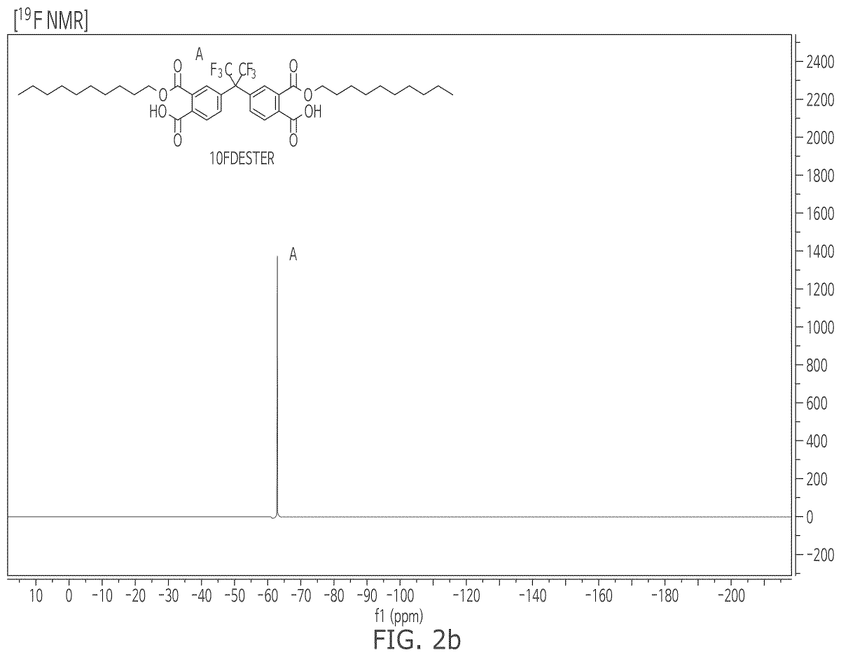

FIG. 2a illustrates a 1H-NMR graph of 10FDESTER synthesized according to Experimental Example 2, and FIG. 2b illustrates a 19F-NMR graph. (1H-NMR (400 MHz, DMSO, ppm): δ=13.62 (s, 2H, 2xOH), 7.97-7.56 (m, 6H, 6xCH), 4.31-4.11 (m, 4H, 2xCH2), 1.63 (dt, J=13.5, 7.0 Hz, 4H, 2xCH2), 1.22 (s, 28H, 14xCH2), 0.83 (t, J=6.5 Hz, 6H, 2xCH3), 19F-NMR (377 MHz, DMSO): δ=−63.15 (s, 6F, 2xCF3))

Referring to FIGS. 2a and 2b, it can be confirmed that 10FDESTER, which is a 4,4′-(Hexafluoroisopropylidene)diphthalic Anhydride(6FDA)-based diester compound having a decanyl chain, was synthesized according to Experimental Example 2.

### [Experimental Example 3] Synthesis of 12FDESTER (Structural Formula 2, Reaction Scheme 3)

To a 100 cm³ RBF, 6FDA (3.0 g, 6.8 mmol), decanol (3.79 cm³, 16.9 mmol), pyridine (1.75 cm³, 8.10 mmol), and DMAP (0.08 g, 0.68 mmol) were added, and toluene (20 cm³) was used as a solvent to stir at a temperature of 100 degrees (Celsius) for 2 hours. After completion of the reaction, a reaction solution was quenched using a 6N HCl aqueous solution (25 cm³) and diluted with toluene. Then, an organic solvent layer was washed three times with water, basified using a 20% Na2CO3 aqueous solution (50 cm³), and an aqueous solution layer including salt was separated. Then, the solution was diluted with toluene, and a HCl aqueous solution was slowly added dropwise to separate an organic layer and an aqueous solution layer. Thereafter, the organic solvent layer was washed with water. Thereafter, moisture included in the organic solvent layer was removed using anhydrous MgSO4, and the solution was concentrated under reduced pressure. After freeze-drying, 12FDESTER (4.08 g, 74%), which is a viscous fluid, was obtained.

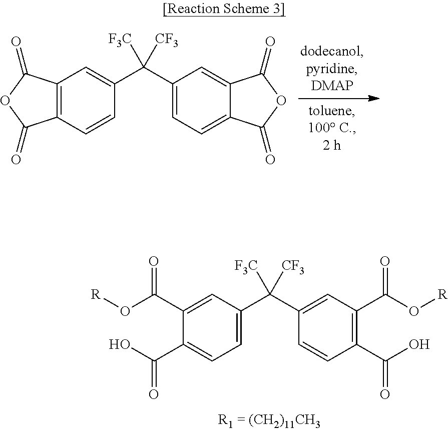

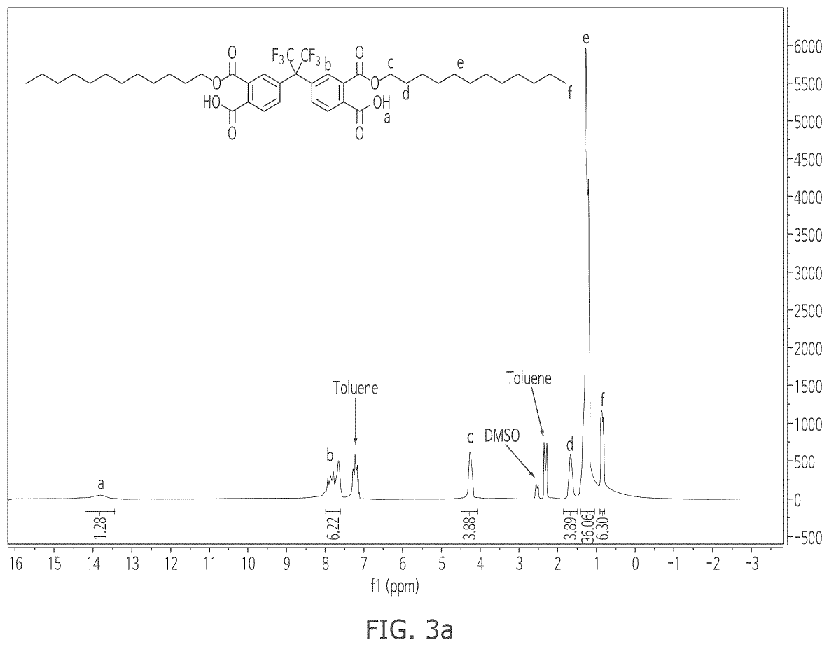

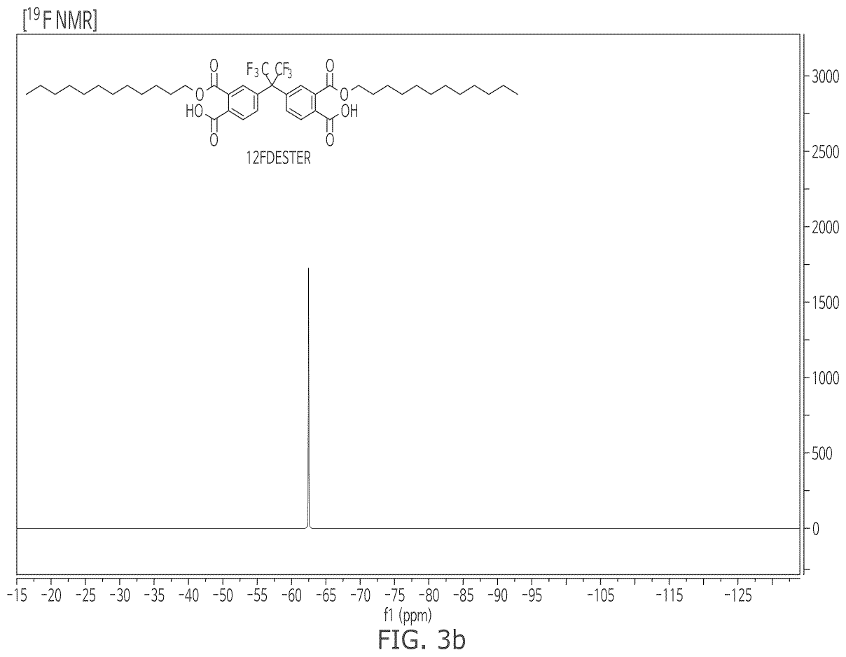

FIG. 3a illustrates a 1H-NMR graph of 12FDESTER synthesized according to Experimental Example 3, and FIG. 3b illustrates a 19F-NMR graph. (1H-NMR (400 MHz, DMSO, ppm): δ=13.65 (s, 2H, 2xOH), 7.76 (ddd, J=53.5, 48.5, 8.0 Hz, 6H, 6xCH), 4.38-4.09 (m, 4H, CH2), 1.64 (dt, J=12.9, 6.6 Hz, 4H, CH2), 1.23 (s, 36H, 18xCH2), 0.83 (t, J=6.0 Hz, 6H, 2xCH3), 19F-NMR (377 MHz, DMSO): δ=−63.21 (s, 6F, 2xCF3))

Referring to FIGS. 3a and 3b, it can be confirmed that 12FDESTER, which is a 4,4′-(Hexafluoroisopropylidene)diphthalic Anhydride(6FDA)-based diester compound having a dodecanyl chain, was synthesized according to Experimental Example 3.

### [Experimental Example 4] Synthesis of 10FDAMIDE (Structural Formula 3, Reaction Scheme 4)

To a 100 cm³ RBF, 6FDA (2 g, 4.50 mmol) and DMAc (75 cm³) were added and dissolved. 1-aminodecane (2.66 g, 16.88 mmol) was added and stirred at room temperature for 2 h. Thereafter, the solution was diluted with ethyl acetate, and water was slowly added dropwise to separate an organic layer and an aqueous solution layer. Moisture was removed using anhydrous MgSO4, and the solution was concentrated under reduced pressure. Thereafter, precipitation was performed in hexane to obtain a product (1.2 g, 35%).

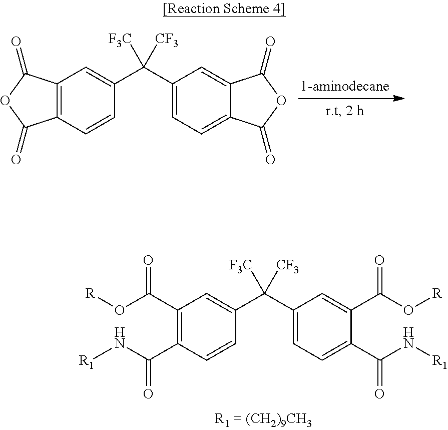

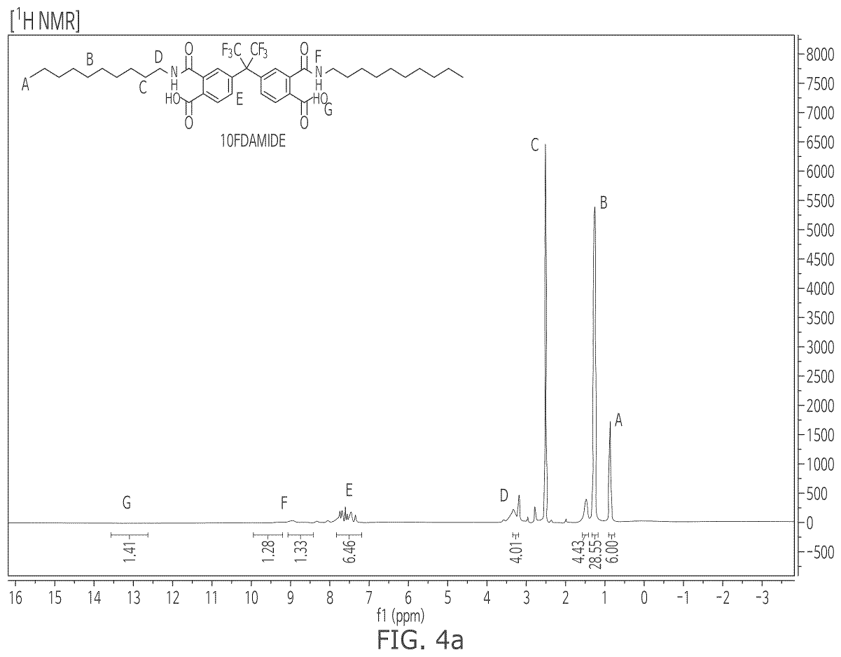

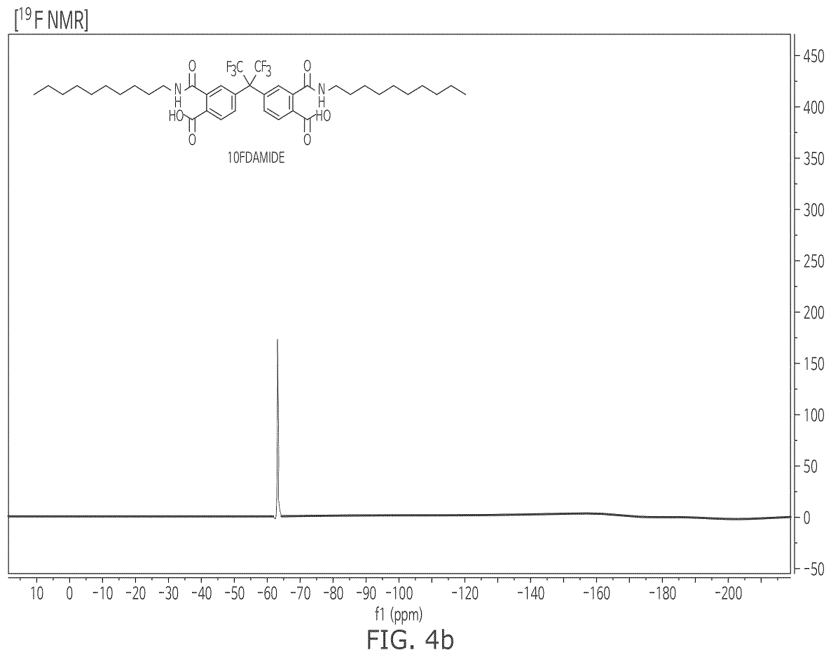

FIG. 4a illustrates a 1H-NMR graph of 10FDAMIDE synthesized according to Experimental Example 4, and FIG. 4b illustrates a 19F-NMR graph. (1H-NMR (400 MHz, DMSO): δ=13.76-12.61 (m, 2H, 2xOH), 9.42 (s, 1H, NH), 8.96 (s, 1H, NH), 7.85-7.29 (m, 6H, 6xCH), 3.17 (dt, J=14.3, 7.2 Hz, 4H, 2xCH2), 1.49 (dt, J=21.3, 7.1 Hz, 4H, CH2), 1.36-1.17 (m, 28H, 14xCH2), 0.86 (t, J=6.5 Hz, 6H, 2xCH3), 19F-NMR (377 MHz, DMSO): δ=−63.02 (t, J=36.7 Hz, 6F, 2xCF3))

Referring to FIGS. 4a and 4b, it can be confirmed that 10FDAMIDE, which is a 4,4′-(Hexafluoroisopropylidene)diphthalic Anhydride(6FDA)-based diamide compound having a decanyl chain, was synthesized according to Experimental Example 4.

### [Experimental Example 5] Synthesis of a Tin Oxide Nanocluster Including a Conjugate Base of 8FDESTER as a Counter Anion (8FDEBTOC, Structural Formula 1) (Reaction Scheme 5)

A solution was prepared by adding tetramethylammonium hydroxide pentahydrate (5.89 g, 31.9 mmol) and deionized water (DI water, 64 cm³) to a 70 cm³ vial, and then butyltin trichloride (3.0 g, 10.6 mmol) was added. A reaction solution was vigorously stirred at room temperature for 2 hours, and then an obtained product was filtered while being washed several times with DI water. After vacuum drying, a tin oxide nanocluster (BTOC, 1.9 g) in a white solid form was obtained. The synthesized BTOC (1.0 g, 0.4 mmol) was dissolved in tetrahydrofuran (THF, 8 cm³) in a 20 cm³ vial, and excess 8FDESTER was added. The reaction solution was stirred at a temperature of 50° C. for 40 minutes and then concentrated under reduced pressure. The concentrated material was precipitated in hexane (200 cm³), filtered, and dried to obtain 8FDEBTOC (0.58 g), which is a white solid.

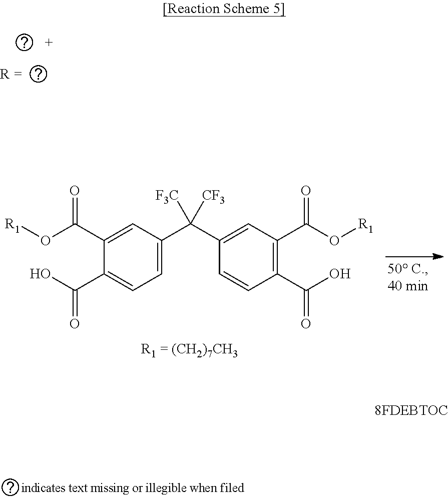

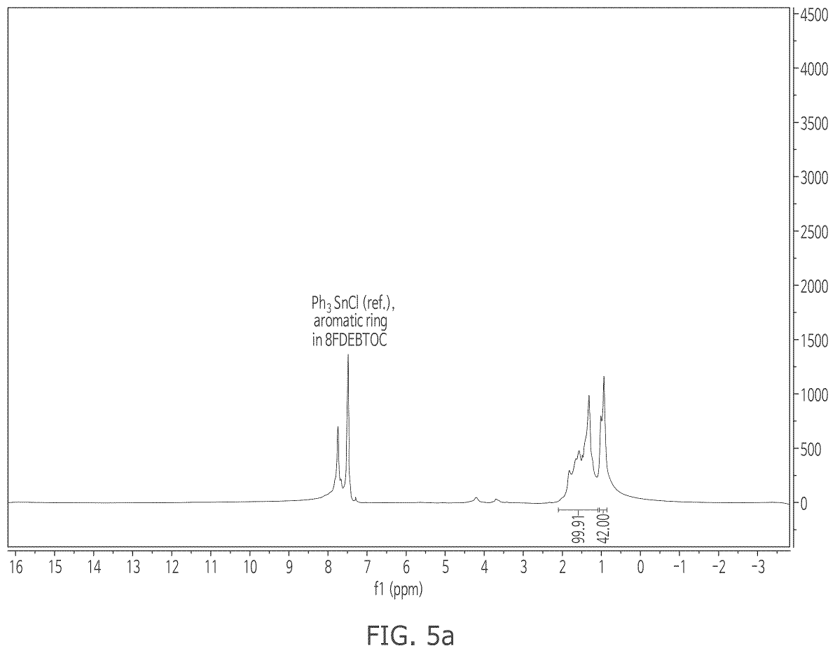

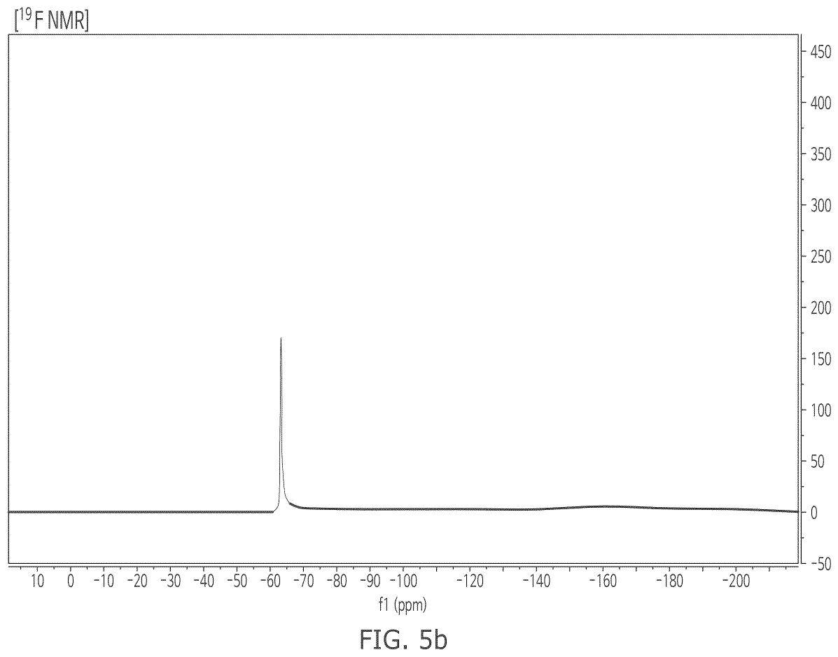

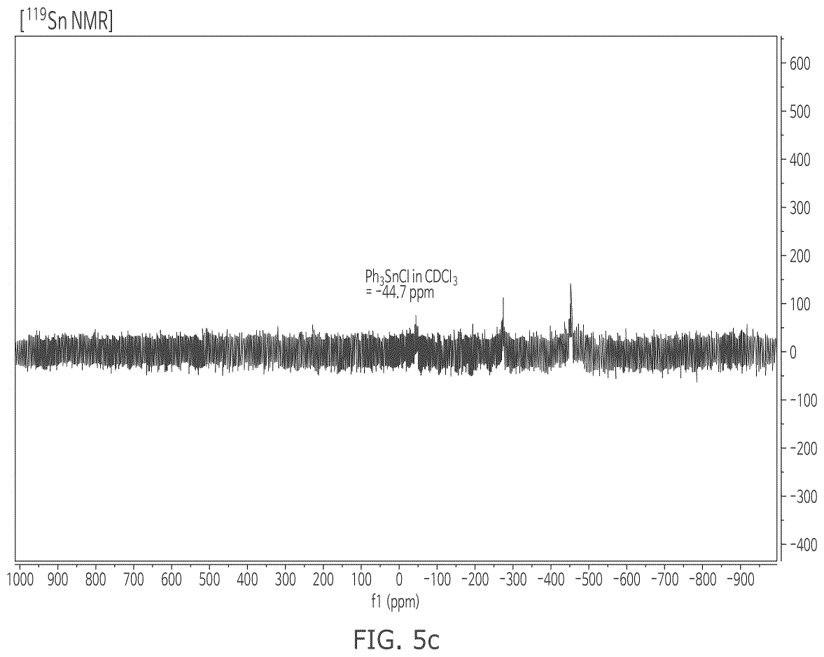

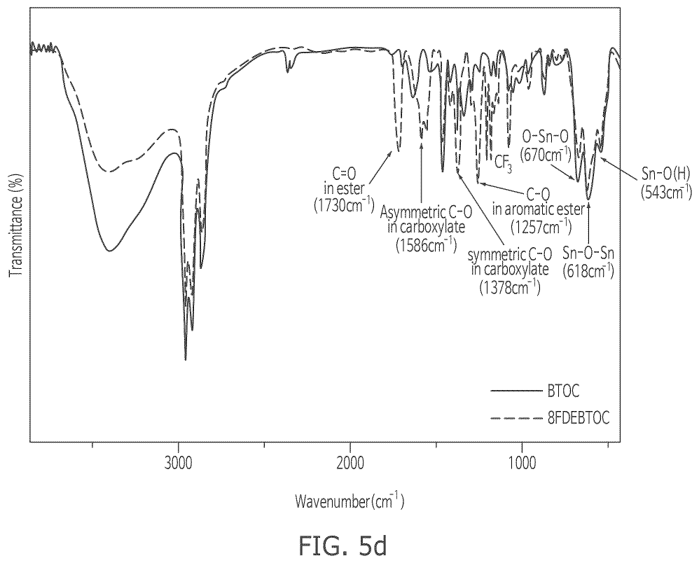

FIG. 5a illustrates a 1H-NMR graph of 8FDEBTOC synthesized according to Experimental Example 5, FIG. 5b illustrates a 19F-NMR graph, FIG. 5c illustrates a 119Sn-NMR graph, and FIG. 5d illustrates an FT-IR (Fourier Transform Infrared) graph of 8FDEBTOC synthesized according to Experimental Example 5. (1H-NMR (400 MHz, CD, ppm): δ=1.44 (dt, J=161.0, 80.0 Hz, 100H, 50xCH2), 0.93 (d, J=33.5 Hz, 42H, 24xCH3), 19F-NMR (377 MHz, CDCl3): δ=−63.40 (t, J=70.5 Hz, 6F, 2xCF3), 119Sn-NMR (149 MHz, CDCl3): δ=−270.02-−28.67 (m), −444.93-−457.94 (m); IR [(KBr): vmax, (cm-1)]1730, 1586, 1378, 1257, 1214, 1185, 670, 618, 543)

Referring to FIGS. 5a to 5d, it can be confirmed that a tin oxide nanocluster (8FDEBTOC) including a conjugate base of 8DESTER as a counter anion was synthesized according to Experimental Example 5.

### [Experimental Example 6] Synthesis of a Tin Oxide Nanocluster Including a Conjugate Base of 10FDESTER as a Counter Anion (10FDEBTOC, Structural Formula 1) (Reaction Scheme 6)

A solution was prepared by adding tetramethylammonium hydroxide pentahydrate (5.89 g, 31.9 mmol) and deionized water (DI water, 64 cm³) to a 70 cm³ vial, and then butyltin trichloride (3.0 g, 10.6 mmol) was added. A reaction solution was vigorously stirred at room temperature for 2 hours, and then an obtained product was filtered while being washed several times with DI water. After vacuum drying, a tin oxide nanocluster (BTOC, 1.9 g) in a white solid form was obtained. The synthesized BTOC (1.0 g, 0.4 mmol) was dissolved in tetrahydrofuran (THF, 8 cm³) in a 20 cm³ vial, and excess 10FDESTER was added. The reaction solution was stirred at a temperature of 50° C. for 40 minutes and then concentrated under reduced pressure. The concentrated material was precipitated in hexane (200 cm³), filtered, and dried to obtain 10FDEBTOC (1.13 g), which is a white solid.

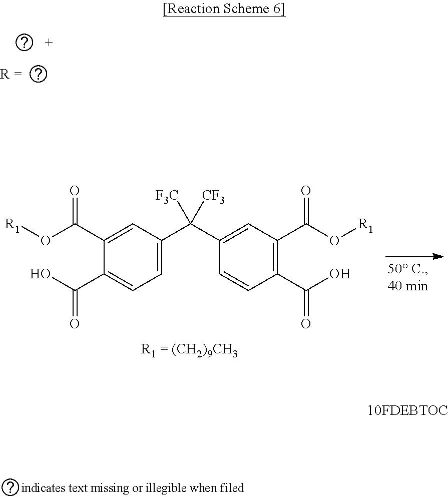

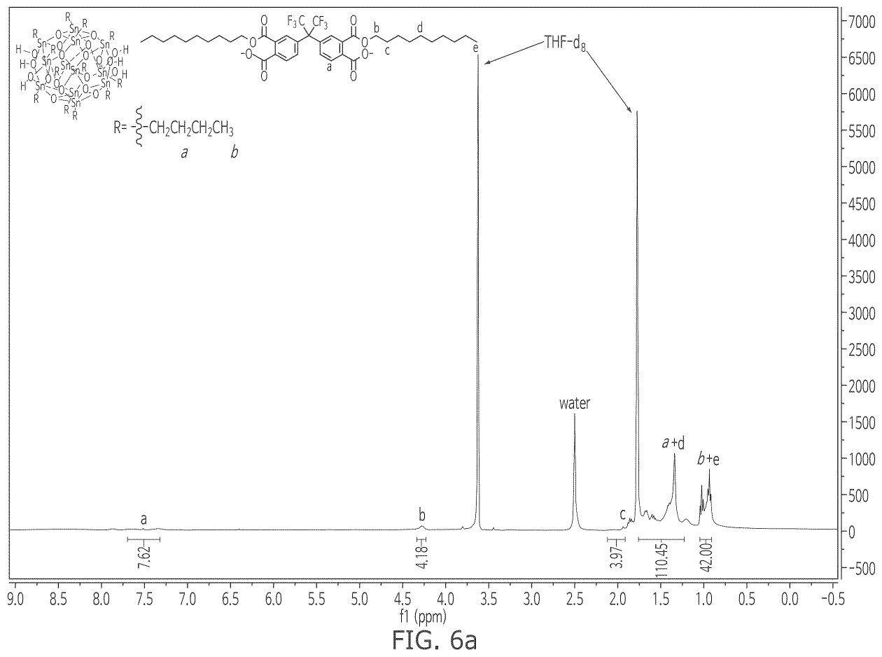

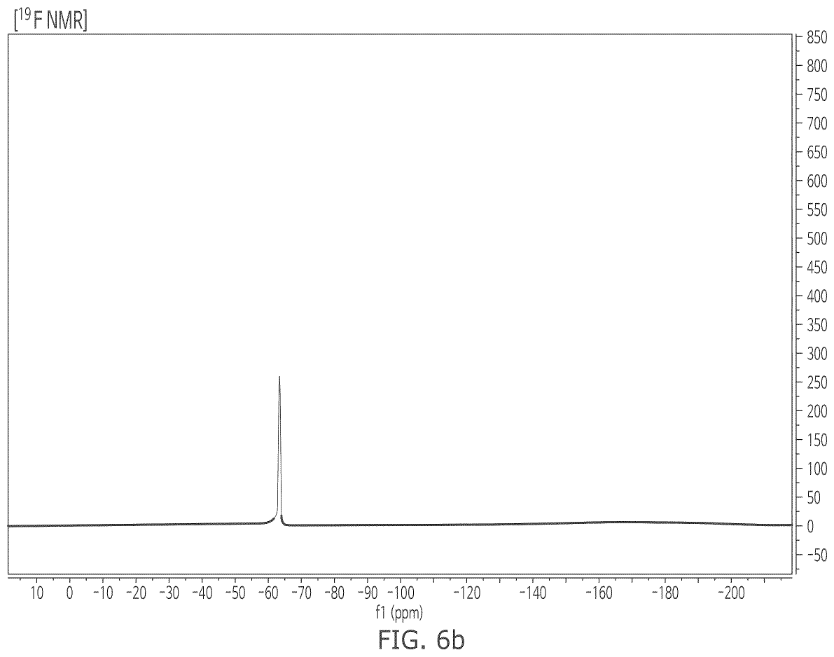

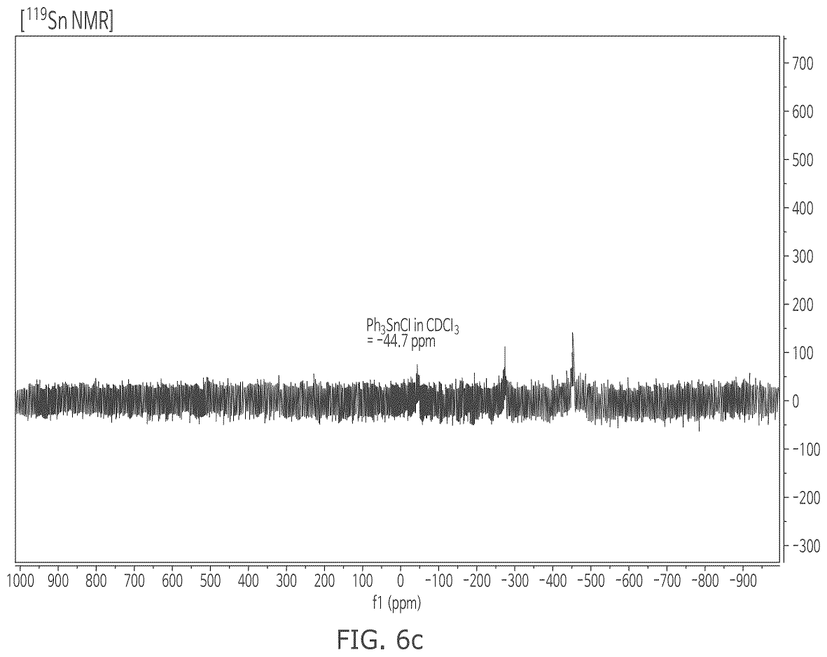

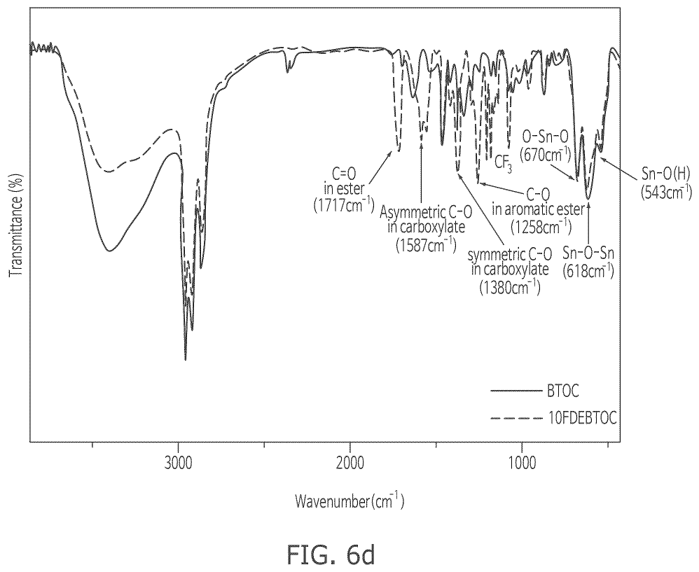

FIG. 6a illustrates a 1H-NMR graph of 10FDEBTOC synthesized according to Experimental Example 6, FIG. 6b illustrates a 19F-NMR graph, FIG. 6c illustrates a 119Sn-NMR graph, and FIG. 6d illustrates an FT-JR graph of 10FDEBTOC synthesized according to Experimental Example 6. (1H-NMR (400 MHz, THF-d8, δ, ppm): 7.95-7.26 (m, 6H, 6xAr-H), 4.32-4.22 (m, 4H, 2x-OCH2-), 2.12-1.21 (m, 104H, 52xCH2), 1.06-0.84 (m, 42H, 14xCH3), 19F-NMR (377 MHz, CDCl3): δ=−63.38 (t, J=81.0 Hz 6F, 2xCF3), 119Sn-NMR (149 MHz, CDCl3): δ=−278.58 (s), −456.78 (s); IR [(KBr): vmax, (cm-1)]1717, 1587, 1380, 1258, 1212, 1185, 670, 618, 543)

Referring to FIGS. 6a to 6d, it can be confirmed that a tin oxide nanocluster (10FDEBTOC) including a conjugate base of 10FDESTER as a counter anion was synthesized according to Experimental Example 6.

### [Experimental Example 7] Synthesis of a Tin Oxide Nanocluster Including a Conjugate Base of 12FDESTER as a Counter Anion (12FDEBTOC, Structural Formula 1) (Reaction Scheme 7)

A solution was prepared by adding tetramethylammonium hydroxide pentahydrate (5.89 g, 31.9 mmol) and deionized water (DI water, 64 cm³) to a 70 cm³ vial, and then butyltin trichloride (3.0 g, 10.6 mmol) was added. A reaction solution was vigorously stirred at room temperature for 2 hours, and then an obtained product was filtered while being washed several times with DI water. After vacuum drying, a tin oxide nanocluster (BTOC, 1.9 g) in a white solid form was obtained. The synthesized BTOC (1.0 g, 0.4 mmol) was dissolved in tetrahydrofuran (THF, 8 cm³) in a 20 cm³ vial, and excess 12FDESTER was added. The reaction solution was stirred at a temperature of 50° C. for 40 minutes and then concentrated under reduced pressure. The concentrated material was precipitated in hexane (200 cm³), filtered, and dried to obtain 12FDEBTOC (0.9 g), which is a white solid.

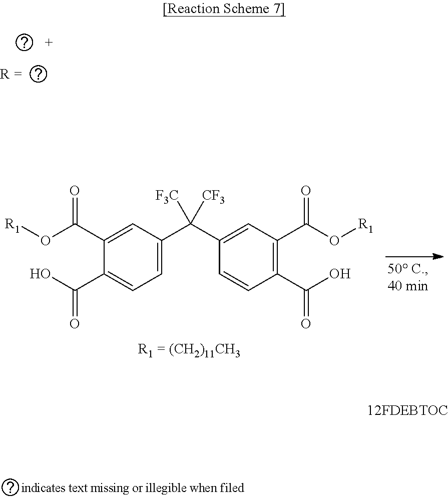

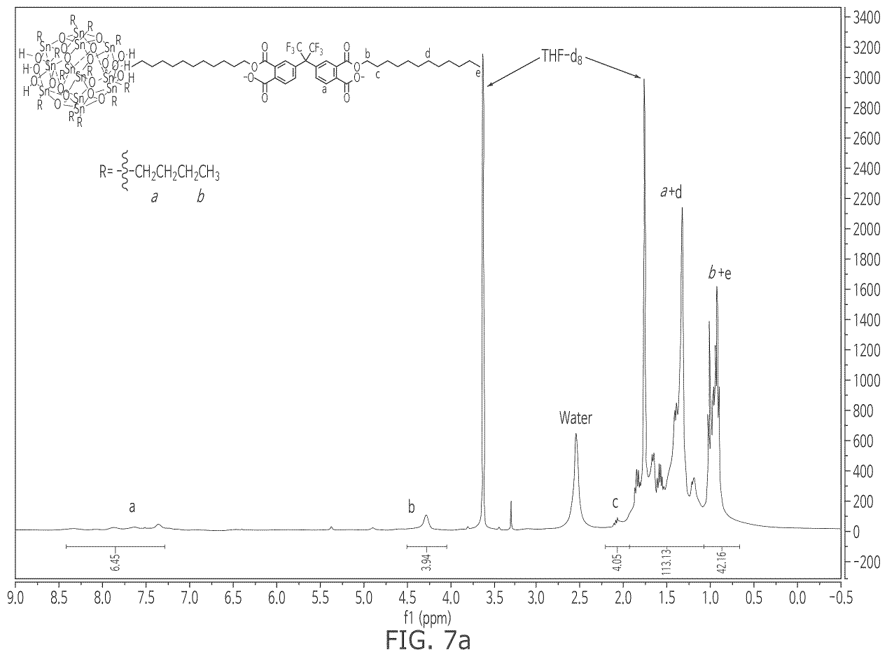

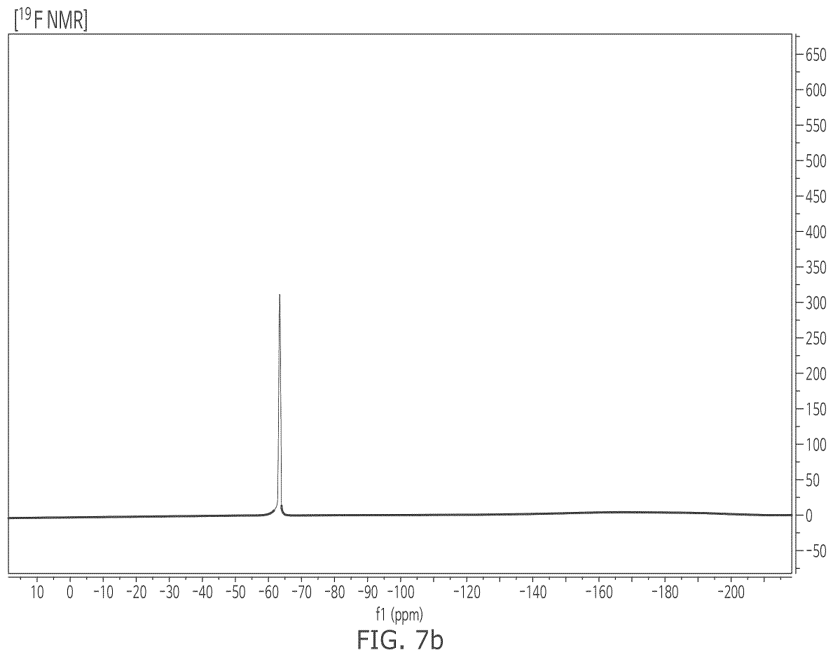

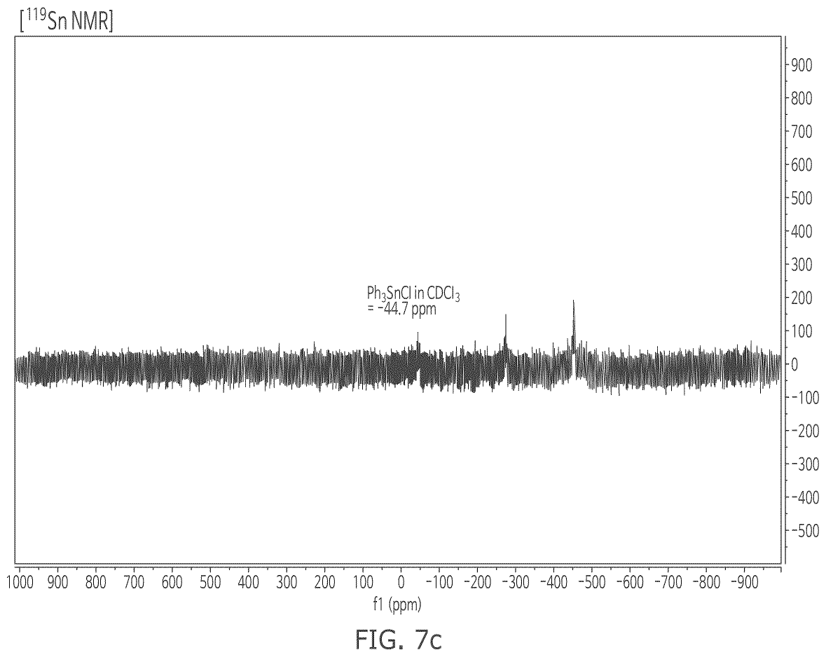

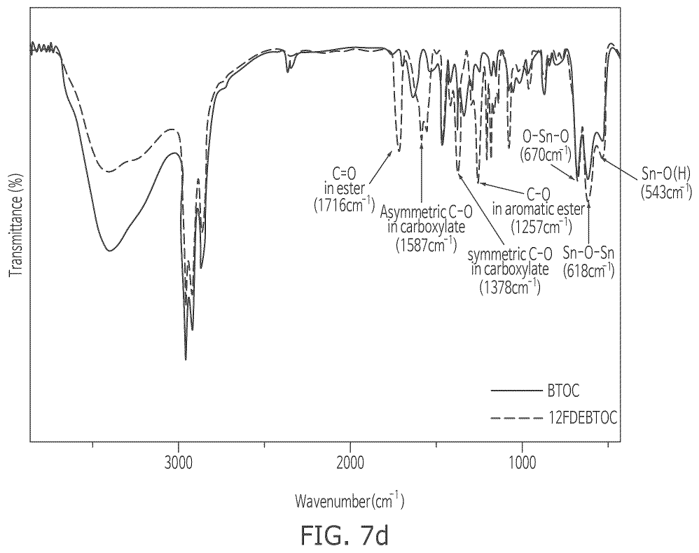

FIG. 7a illustrates a 1H-NMR graph of 12FDEBTOC synthesized according to Experimental Example 7, FIG. 7b illustrates a 19F-NMR graph, FIG. 7c illustrates a 119Sn-NMR graph, and FIG. 7d illustrates an FT-IR graph of 12FDEBTOC synthesized according to Experimental Example 7. (1H-NMR (400 MHz, THF-d8, δ, ppm): 8.41-7.28 (m, 6H, 6xAr-H), 4.39-4.19 (m, 4H, 2x-OCH2-), 2.22-1.09 (m, 112H, 56xCH2), 1.08-0.69 (m, 42H, 14xCH3), 19F-NMR (377 MHz, CDCl3): δ=−63.40 (t, J=80.0 Hz 6F, 2xCF3), 119Sn-NMR (149 MHz, CDCl3): δ=−279.14 (s), −456.69 (s); IR [(KBr): vmax, (cm-1)]1716, 1587, 1378, 1257, 1212, 1185, 670, 618, 543)

Referring to FIGS. 7a to 7d, it can be confirmed that a tin oxide nanocluster (12FDEBTOC) including a conjugate base of 12FDESTER as a counter anion was synthesized according to Experimental Example 7.

### [Experimental Example 8] Synthesis of a Tin Oxide Nanocluster Including a Conjugate Base of 10FDAMIDE as a Counter Anion (10FDABTOC, Structural Formula 1) (Reaction Scheme 8)

A solution was prepared by adding tetramethylammonium hydroxide pentahydrate (5.89 g, 31.9 mmol) and deionized water (DI water, 64 cm³) to a 70 cm³ vial, and then butyltin trichloride (3.0 g, 10.6 mmol) was added. A reaction solution was vigorously stirred at room temperature for 2 hours, and then an obtained product was filtered while being washed several times with DI water. After vacuum drying, a tin oxide nanocluster (BTOC, 1.9 g) in a white solid form was obtained. BTOC (lg, 0.41 mmol) and THF (24 cm³) were added to a 70 cm³ vial and dissolved. 10FDAMIDE (0.31 g, 0.41 mmol) was diluted with THF (6 cm³) in a 20 cm³ vial. Thereafter, the diluted 10FDAMIDE was slowly added dropwise to the 70 cm³ vial in which BTOC was dissolved, and then stirred at 50 degrees (Celsius) for 40 minutes. After concentration under reduced pressure, precipitation was performed in hexane to obtain 10FDABTOC (0.94 g).

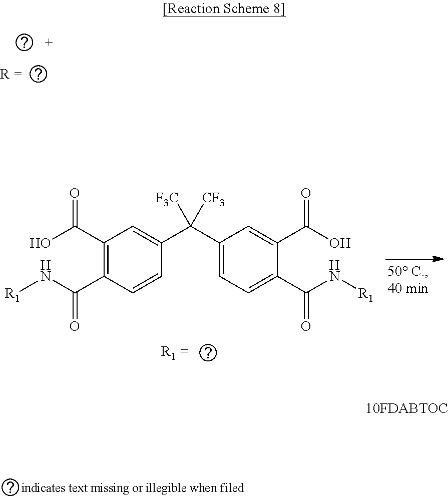

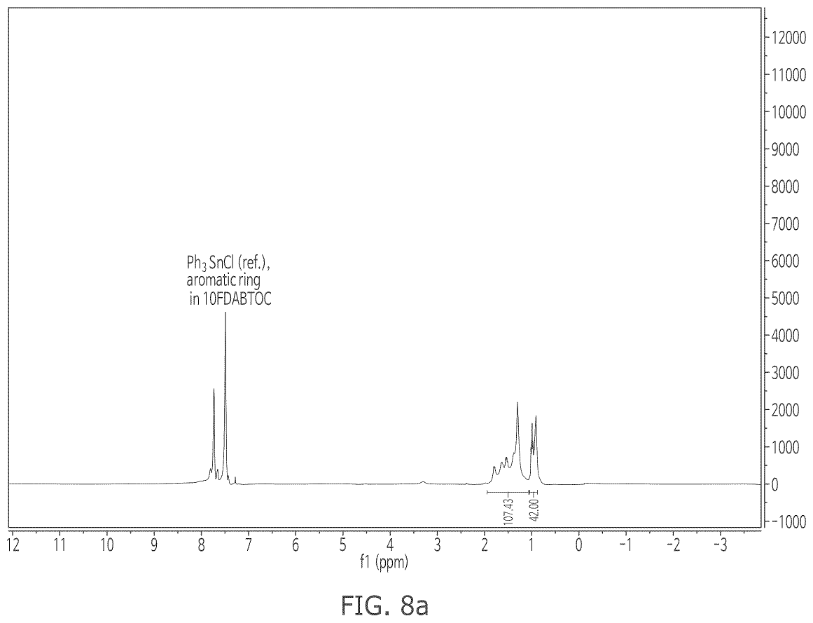

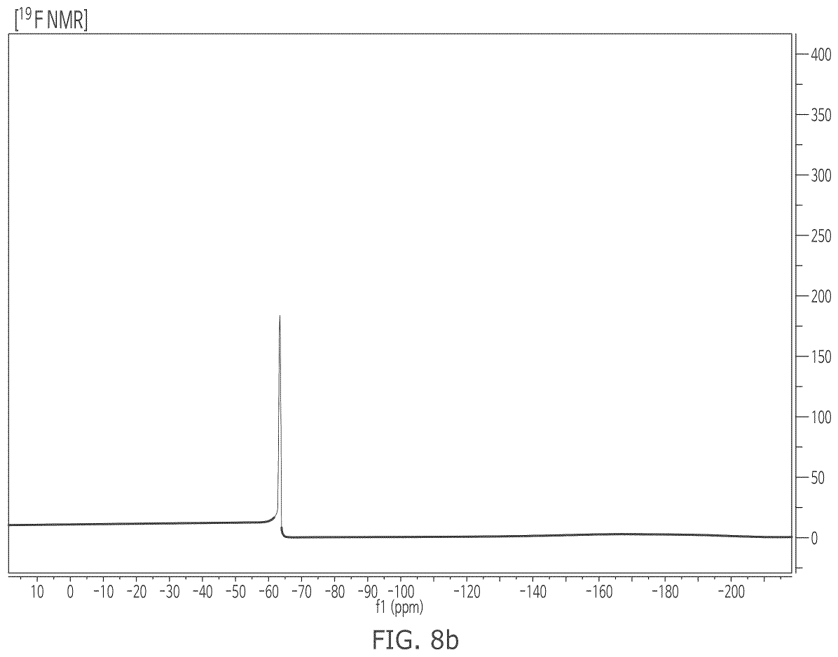

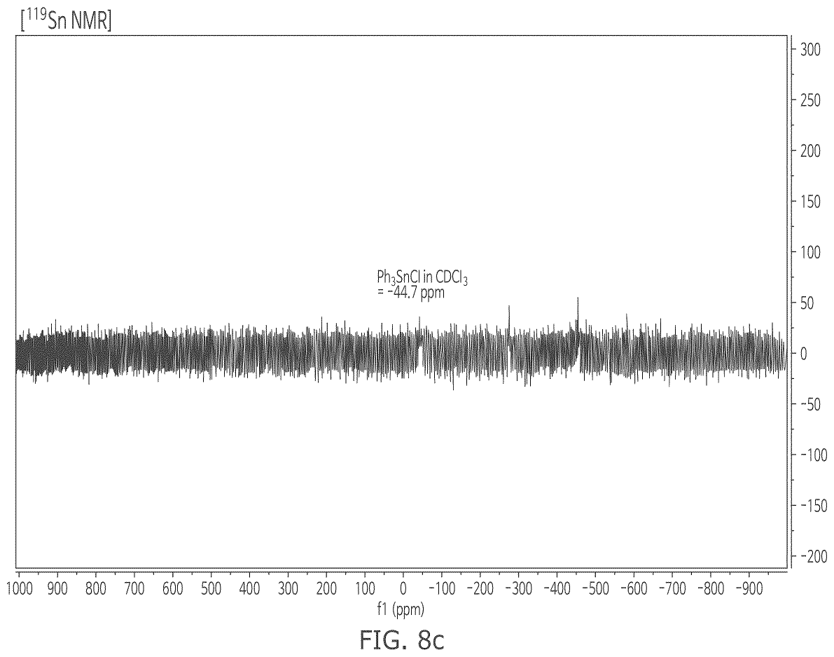

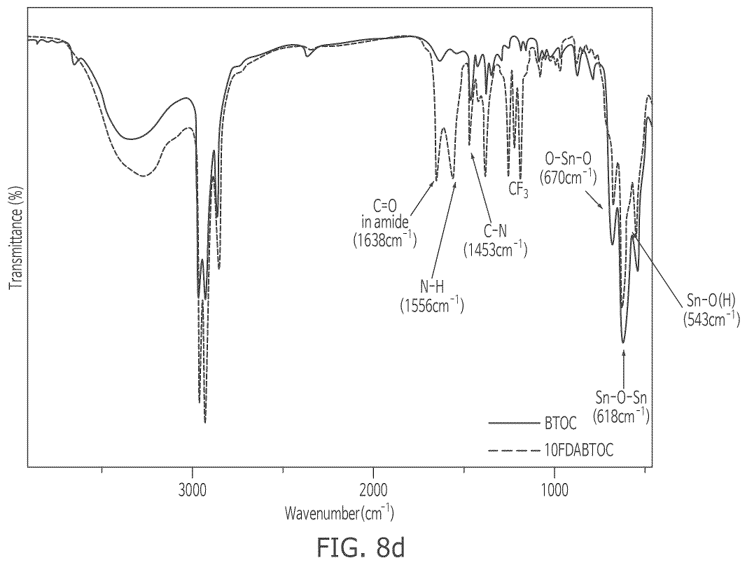

FIG. 8a illustrates a 1H-NMR graph of 10FDABTOC synthesized according to Experimental Example 8, FIG. 8b illustrates a 19F-NMR graph, FIG. 8c illustrates a 119Sn-NMR graph, and FIG. 8d illustrates an FT-IR graph of 10FDABTOC synthesized according to Experimental Example 8. (1H-NMR (400 MHz, CDCl3): δ=1.99-1.04 (m, 108H, 54xCH2), 0.95 (m, 42H, 14xCH3), 19F-NMR (377 MHz, CDCl3): δ=−63.38 (s, 6H, 2xCF3), 119Sn-NMR (149 MHz, CDCl3): δ=−272.61-−280.33 (m), —448.03-−463.40 (m) IR [(KBr): vmax, (cm-1)]1638, 1556, 1453, 1253, 1212, 1183, 670, 618, 543)

Referring to FIGS. 8a to 8d, it can be confirmed that a tin oxide nanocluster (10FDABTOC) including a conjugate base of 10FDAMIDE as a counter anion was synthesized according to Experimental Example 8.

### [Experimental Example 9] Evaluation of 254 nm Ultraviolet Lithography for 8FDEBTOC (Experimental Example 5), 10FDEBTOC (Experimental Example 6), 12FDEBTOC (Experimental Example 7), and 10FDABTOC (Experimental Example 8)

8FDEBTOC was dissolved in a mixed solvent of 2-Butanone (MEK) and n-butyl acetate (nBA) in a volume ratio of 4:1 to prepare a resist solution with a concentration of 3 wt/vol %. 10FDEBTOC, 12FDEBTOC, and 10FDABTOC were dissolved in a cyclohexanone solvent to prepare resist solutions with a concentration of 5 wt/vol %. A solution (20 wt %) in which hexamethyldisilazane (HMDS) was dissolved in PGMEA was spin-coated on a Si wafer at 3000 rpm for 30 seconds, and then a substrate was heated at 110° C. for 1 minute. The resist solutions of 8FDEBTOC, 10FDEBTOC, 12FDEBTOC, and 10FDABTOC were spin-coated on the substrate pretreated (primed) with HMDS at 2000 rpm, 1200 rpm, 1000 rpm, and 800 rpm for 60 seconds, respectively, and then heated at 80° C. for 1 minute to form a thin film with an approximate thickness of 100 nm. Thereafter, irradiation was performed with an exposure dose of 25 to 400 mJ/cm² using a 254 nm ultraviolet exposure machine, and then a development process was performed for 60 seconds on the 8FDEBTOC, 10FDEBTOC, 12FDEBTOC, and 10FDABTOC thin films using mixed solutions of a 2.38% Tetramethylammonium hydroxide (TMAH) standard aqueous solution and distilled (DI) water in volume ratios of 30:1, 3:1, 1:1, and 1:1, respectively, and washed with DI water for 10 seconds to confirm formation of a positive pattern. Thereafter, thickness was measured using an Alpha-step® D-300 stylus profiler manufactured by Kla-Tencor to evaluate solubility characteristics.

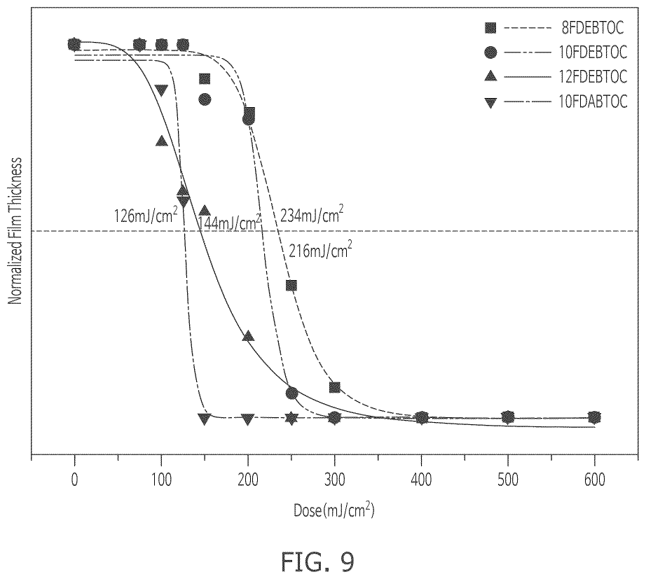

FIG. 9 illustrates solubility characteristics of 8FDEBTOC, 10FDEBTOC, 12FDEBTOC, and 10FDABTOC obtained by performing 254 nm KrF lithography (deep ultraviolet) according to Experimental Example 9.

Referring to FIG. 9, it can be confirmed that when ultraviolet of 234 mJ/cm², 216 mJ/cm², 144 mJ/cm², and 126 mJ/cm² is irradiated onto a resist thin film with a thickness of 100 nm formed according to Experimental Example 9, about 50% of the resist thin film thickness can be maintained. In addition, when the ultraviolet irradiation dose is low, solubility of the resist thin film in a basic developer (TMAH) does not increase, and when the ultraviolet irradiation dose increases above a certain amount, solubility of the resist thin film in the basic developer (TMAH) increases.

### [Experimental Example 10] Electron Beam Lithography of 8FDEBTOC (Experimental Example 5)

8FDEBTOC was dissolved in a mixed solvent of 2-Butanone (MEK) and n-butyl acetate (nBA) in a volume ratio of 4:1 to prepare a resist solution with a concentration of 3 wt/vol %. A solution (20 wt %) in which hexamethyldisilazane (HIMDS) was dissolved in PGMEA was spin-coated on a Si wafer at 3000 rpm for 30 seconds, and then a substrate was heated at 110° C. for 1 minute. The resist solution was spin-coated on the substrate treated with HMDS at 2000 rpm for 60 seconds, and then heated at 80° C. for 1 minute to form a thin film with an approximate thickness of 100 nm. An electron beam of 50 to 1,500 μC/cm² was irradiated onto the resist thin film under an acceleration voltage of 80 keV. A development process was performed for 60 seconds using a mixed solution (volume ratio) of a 2.38% TMAH standard aqueous solution and DI water in a ratio of 30:1, and washed with DI water for 10 seconds to fabricate a positive resist pattern.

### [Experimental Example 11] Electron Beam Lithography of 10FDEBTOC (Experimental Example 6) and 12FDEBTOC (Experimental Example 7)

10FDEBTOC and 12FDEBTOC were dissolved in a cyclohexanone solvent to prepare resist composition solutions with concentrations of 5 wt/vol % and 5.5 wt/vol %, respectively. A solution (20 wt %) in which hexamethyldisilazane (HMDS) was dissolved in PGMEA was spin-coated on a Si wafer at 3000 rpm for 30 seconds, and then a substrate was heated at 110° C. for 1 minute. The resist composition solution was spin-coated on the substrate treated with HAMDS at 1200 rpm for 60 seconds, and then heated at 80° C. for 1 minute to form a thin film with an approximate thickness of 100 nm. An electron beam of 50 to 1,500 μC/cm² was irradiated onto the resist thin film under an acceleration voltage of 80 keV. A development process was performed for 60 seconds on each of the 10FDEBTOC and 12FDEBTOC thin films using mixed solutions of a 2.38% TMAH standard aqueous solution and DI water in volume ratios of 3:1 and 1:1, respectively, and then washed with DI water for 10 seconds to fabricate a positive resist pattern.

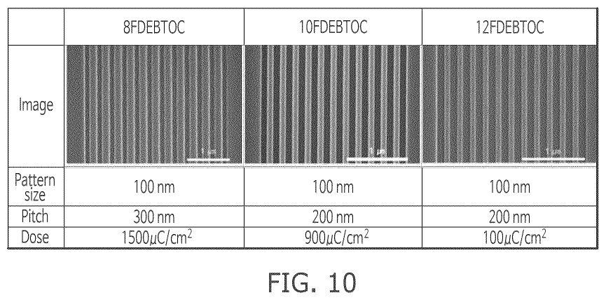

FIG. 10 illustrates positive patterns of 8FDEBTOC, 10FDEBTOC, and 12FDEBTOC observed through a scanning electron microscope (SEM) after performing electron beam lithography according to Experimental Examples 10 and 11.

Referring to FIG. 10, after patterning a resist pattern by irradiating an electron beam of 1500 μC/cm² onto an 8FDEBTOC resist thin film formed according to Experimental Example 10, a development process was performed using a basic developer (TMAH), and as a result, a positive resist pattern of 100 nm was formed. After patterning resist patterns by irradiating electron beams of 900 μC/cm² and 100 μC/cm² onto 10FDEBTOC and 12FDEBTOC resist thin films formed according to Experimental Example 11, respectively, a development process was performed using a basic developer (TMAH), and as a result, positive resist patterns of 100 nm were formed.

Referring to FIGS. 9 and 10, it can be confirmed that positive resist patterns are formed using resist compositions of 8FDEBTOC, 10FDEBTOC, 12FDEBTOC, and 10FDABTOC. As ultraviolet or an electron beam is irradiated onto a resist thin film formed of the resist composition, an organic ligand (butyl group) of a tin oxide nanocluster (8FDEBTOC, 10FDEBTOC, 12FDEBTOC, 10FDABTOC) may be detached in an exposed region of the resist thin film, and accordingly, a core structure of the tin oxide nanocluster may have Lewis acidity. In the exposed region of the resist thin film, a functional group functioning as a Lewis base of a counter anion bonded to the core structure of the tin oxide nanocluster may bond to a tin atom that has lost the organic ligand. Accordingly, solubility of an exposed region of the resist thin film in a basic developer (TMAH) may be adjusted and/or controlled, and a dissolution contrast between the exposed region and an unexposed region of the resist thin film may be increased. Thereafter, the exposed region of the resist thin film may be selectively removed by a development process using the basic developer (TMAH), and accordingly, a positive resist pattern may be formed.

### [Experimental Example 12] Synthesis of 10FDTHIOESTER (Structural Formula 4, Reaction Scheme 9)

To a 100 cm³ RBF, 6FDA (3.0 g, 6.8 mmol), 1-decanethiol (3.0 cm³, 14.9 mmol), and triethylamine (1.9 cm³, 13.5 mmol) were added, and THF (30 cm³) was used as a solvent to stir at room temperature for 3 hours. After completion of the reaction, a reaction solution was quenched using a 6N HCl aqueous solution (30 cm³) and diluted with dichloromethane. Then, an organic solvent layer was washed three times with water, and an aqueous solution layer including salt was separated. Thereafter, moisture included in the organic solvent layer was removed using anhydrous MgSO4, and the solution was concentrated under reduced pressure. After vacuum drying, 10FDTHIOESTER (98%, 5.23 g), which is a viscous fluid, was obtained.

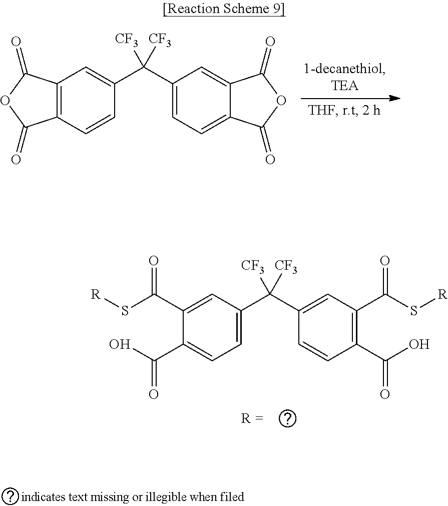

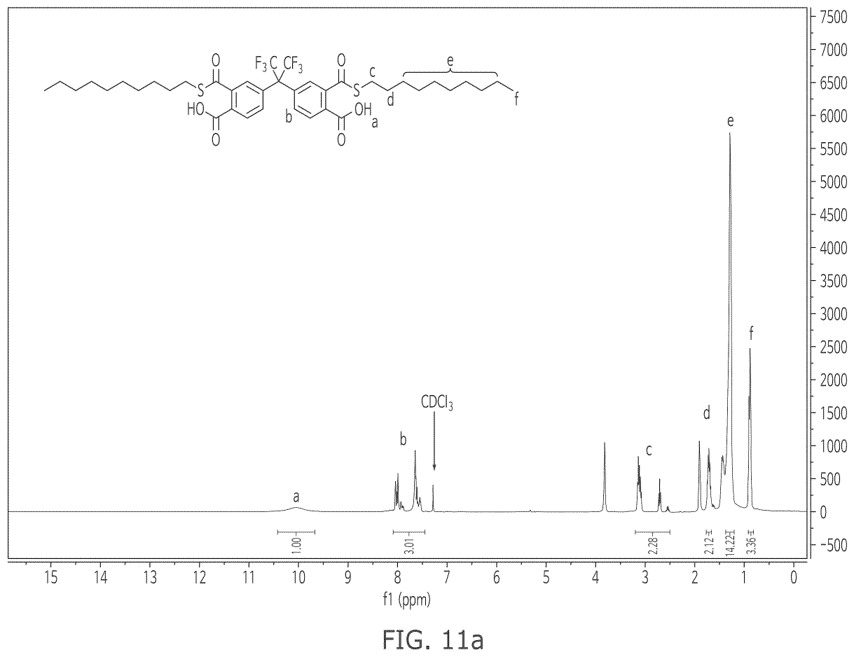

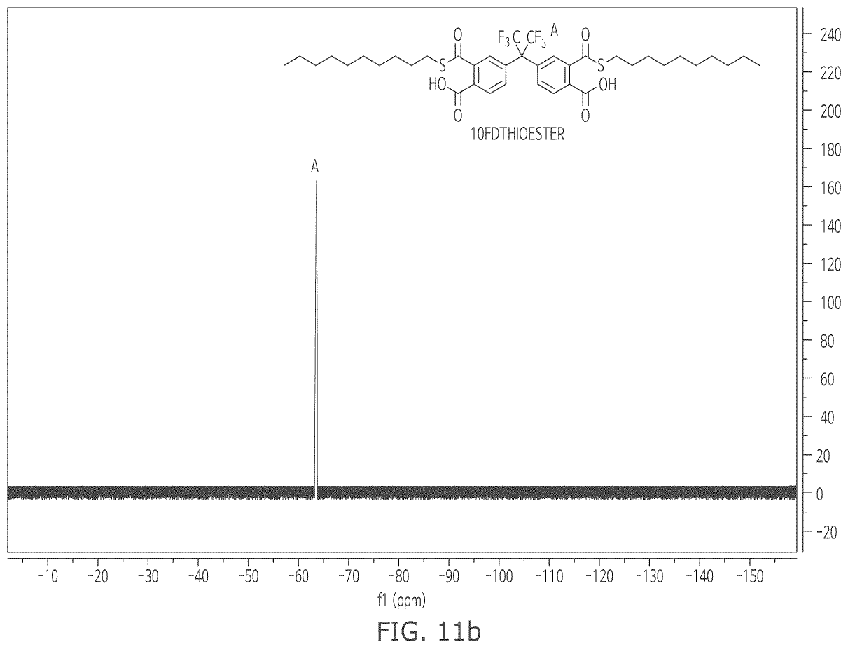

FIG. 11a illustrates a 1H-NMR graph of 10FDTHIOESTER synthesized according to Experimental Example 12, and FIG. 11b illustrates a 19F-NMR graph. (1H-NMR (400 MHz, CDCl3, δ, ppm): 13.62 (s, 2H, 2 x OH), 7.96-7.49 (m, 6H, aromatic CH), 3.01 (t, J=6.8 Hz, 4H, 2 x CH2), 1.79-1.66 (m, 4H, 2 x CH2), 1.37-1.19 (m, 28H, 14 x CH2), 0.84 (t, J=6.8 Hz, 6H, 2 x CH3), 19F-NMR (377 MHz, CDCl3, δ, ppm): −62.83 (s, 6F, 2 x CF3))

Referring to FIGS. 11a and 11b, it can be confirmed that 10FDTHIOESTER, which is a 4,4′-(Hexafluoroisopropylidene)diphthalic Anhydride(6FDA)-based dithioester compound having a decanyl chain, was synthesized according to Experimental Example 12.

### [Experimental Example 13] Synthesis of 12FDTHIOESTER (Structural Formula 2, Reaction Scheme 10)

To a 100 cm³ RBF, 6FDA (1.0 g, 2.25 mmol), 1-dodecanethiol (1.2 cm³, 4.95 mmol), and triethylamine (0.63 cm³, 4.5 mmol) were added, and THF (10 cm³) was used as a solvent to stir at room temperature for 3 hours. After completion of the reaction, a reaction solution was quenched using a 6N HCl aqueous solution (10 cm³) and diluted with dichloromethane. Then, an organic solvent layer was washed three times with water, and an aqueous solution layer including salt was separated. Thereafter, moisture included in the organic solvent layer was removed using anhydrous MgSO₄, and the solution was concentrated under reduced pressure. After vacuum drying, 12FDTHIOESTER (99%, 1.9 g), which is a viscous fluid, was obtained. 1H-NMR (400 MHz, DMSO-d6, δ, ppm): 13.73 (s, 2H, 2 x OH), 7.96-7.47 (m, 6H, aromatic CH), 3.05 (t, J=6.8 Hz, 4H, 2 x CH2), 1.69-1.53 (m, 4H, 2 x CH2), 1.47-1.12 (m, 36H, 18 x CH2), 0.84 (t, J=5.6 Hz, 6H, 2 x CH3), 19F-NMR (377 MHz, DMSO-d6, δ, ppm): −63.15 (s, 6F, 2 x CF3)

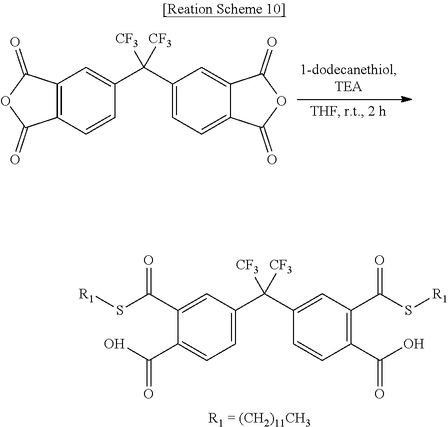

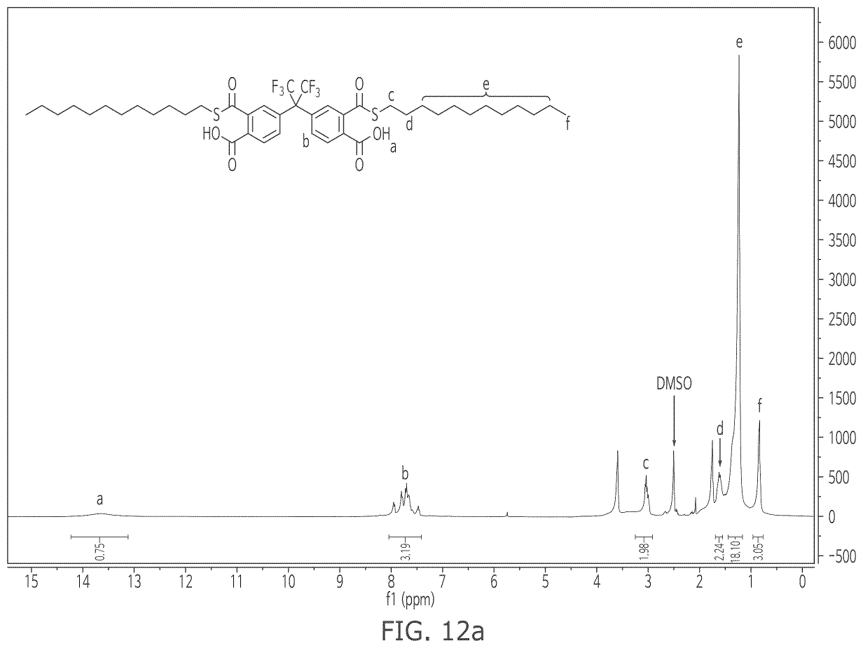

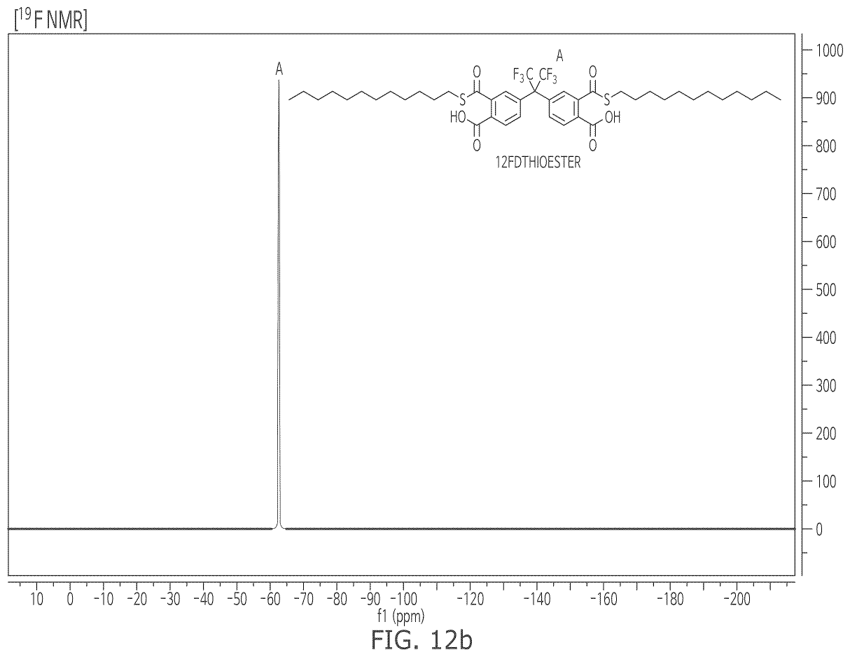

FIG. 12a illustrates a 1H-NMR graph of 12FDTHIOESTER synthesized according to Experimental Example 13, and FIG. 12b illustrates a 19F-NMR graph. (1H-NMR (400 MHz, DMSO-d6, δ, ppm): 13.73 (s, 2H, 2 x OH), 7.96-7.47 (m, 6H, aromatic CH), 3.05 (t, J=6.8 Hz, 4H, 2 x CH2), 1.69-1.53 (m, 4H, 2 x CH2), 1.47-1.12 (m, 36H, 18 x CH2), 0.84 (t, J=5.6 Hz, 6H, 2 x CH3), 19F-NMR (377 MHz, DMSO-d6, δ, ppm): −63.15 (s, 6F, 2 x CF3))

Referring to FIGS. 12a and 12b, it can be confirmed that 12FDTHIOESTER, which is a 4,4′-(Hexafluoroisopropylidene)diphthalic Anhydride(6FDA)-based dithioester compound having a dodecanyl chain, was synthesized according to Experimental Example 13.

### [Experimental Example 14] Synthesis of a Tin Oxide Nanocluster Including a Conjugate Base of 10FDTHIOESTER as a Counter Anion (10FDTBTOC, Structural Formula 1) (Reaction Scheme 11)

A solution was prepared by adding tetramethylammonium hydroxide pentahydrate (3.93 g, 21.3 mmol) and deionized water (DI water, 42.5 cm³) to a 70 cm³ vial, and then butyltin trichloride (2.0 g, 7.09 mmol) was added. A reaction solution was vigorously stirred at room temperature for 2 hours, and then an obtained product was filtered several times with DI water. After vacuum drying, a tin oxide cluster (BTOC, 76%, 1.52 g) in a white solid form was obtained. The synthesized BTOC (1.0 g, 0.4 mmol) was dissolved in tetrahydrofuran (THF, 8 cm³) in a 20 cm³ vial, 10FDTHIOESTER (0.32 g, 0.4 mmol) was dissolved in tetrahydrofuran (THF, 2 cm³) in a 4 cm³ vial, and then slowly added dropwise. The reaction solution was stirred at a temperature of 50 degrees (Celsius) for 40 minutes, concentrated under reduced pressure, and then precipitated in hexane to obtain 10FDTBTOC (0.892 g).

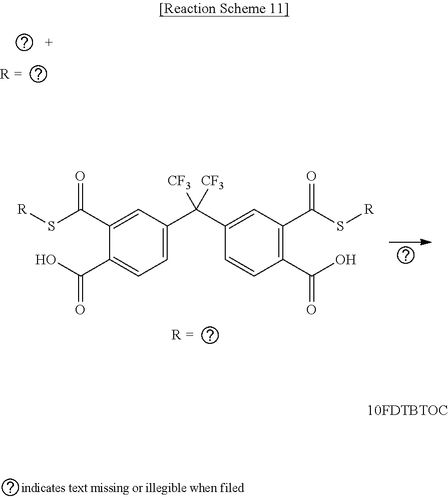

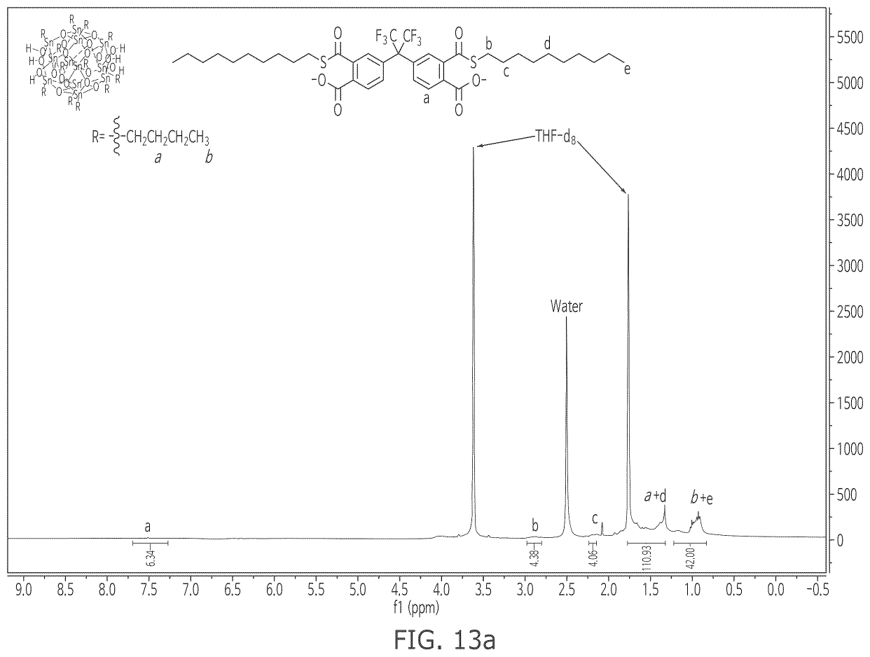

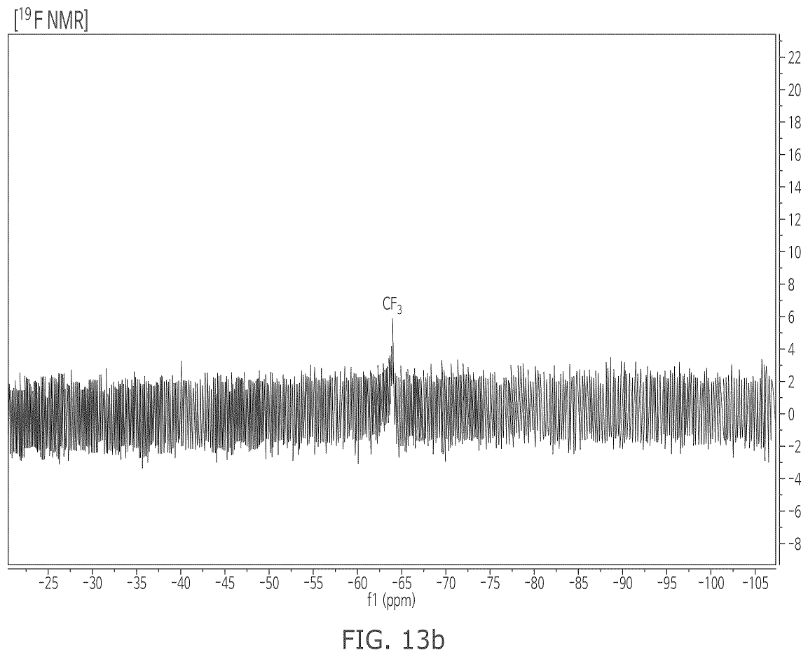

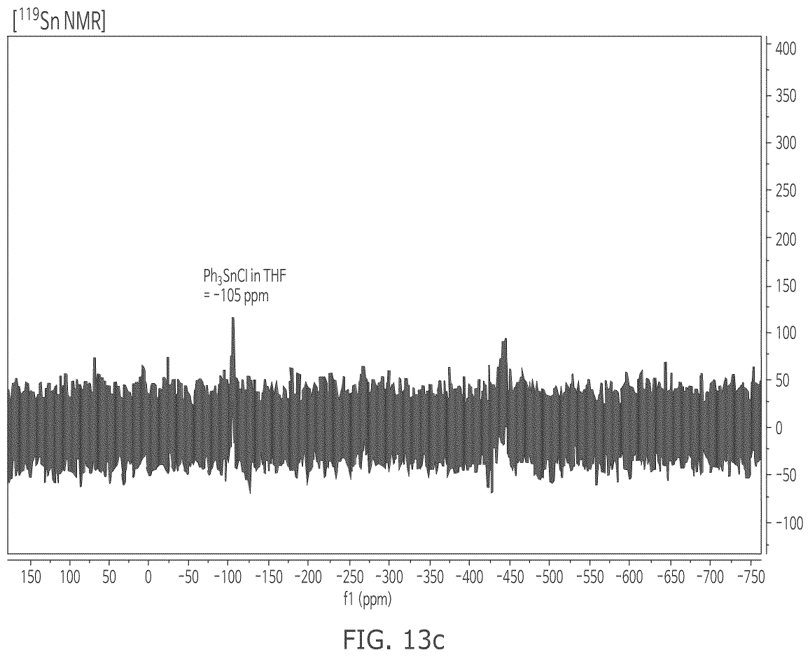

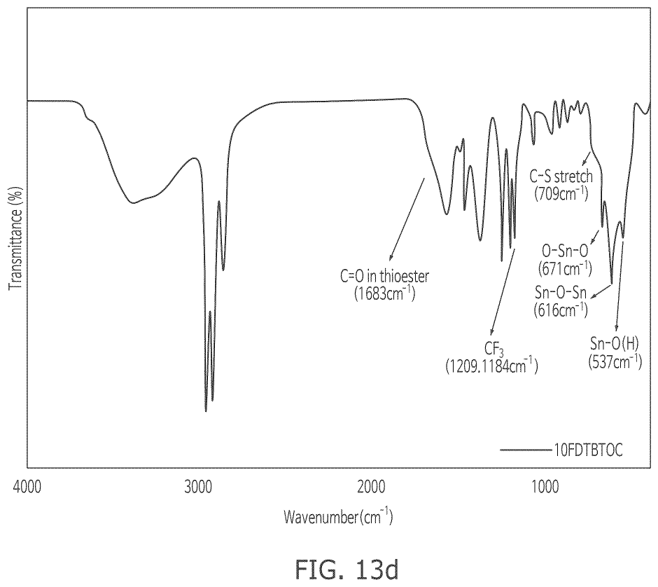

FIG. 13a illustrates a 1H-NMR graph of 10FDTBTOC synthesized according to Experimental Example 14, FIG. 13b illustrates a 19F-NMR graph, FIG. 13c illustrates a 119Sn-NMR graph, and FIG. 13d illustrates an FT-IR graph of 10FDTBTOC synthesized according to Experimental Example 14. (1H-NMR (400 MHz, THF-d8, δ, ppm): 8.41-7.28 (m, 6H, 6xAr-H), 3.05-2.78 (m, 4H, 2x-SCH2-), 2.22-1.24 (m, 104H, 52xCH2), 1.17-0.81 (m, 42H, 14xCH3), 19F-NMR (377 MHz, THF-d8, δ, ppm): −63.78 (s, 6F, 2 x CF3), 119Sn-NMR (149 MHz, THF-d8, δ, ppm): −254.08 (s), —444.91 (s) IR [(KBr): vmax, (cm-1)]1683, 1209, 1184, 709, 671, 537)

Referring to FIGS. 13a to 13d, it can be confirmed that a tin oxide nanocluster (10FDTBTOC) including a conjugate base of 10FDTHIOESTER as a counter anion was synthesized according to Experimental Example 14.

### [Experimental Example 15] Synthesis of a Tin Oxide Nanocluster Including a Conjugate Base of 12FDTHIOESTER as a Counter Anion (12FDTBTOC, Structural Formula 1) (Reaction Scheme 12)

A solution was prepared by adding tetramethylammonium hydroxide pentahydrate (3.93 g, 21.3 mmol) and deionized water (DI water, 42.5 cm³) to a 70 cm³ vial, and then butyltin trichloride (2.0 g, 7.09 mmol) was added. A reaction solution was vigorously stirred at room temperature for 2 hours, and then an obtained product was filtered several times with DI water. After vacuum drying, a tin oxide nanocluster (BTOC, 76%, 1.52 g) in a white solid form was obtained. The synthesized BTOC (0.5 g, 0.2 mmol) was dissolved in tetrahydrofuran (THF, 3 cm³) in a 20 cm³ vial, 12FDTHIOESTER (0.16 g, 0.2 mmol) was dissolved in tetrahydrofuran (THF, 2 cm³) in a 4 cm³ vial, and then slowly added dropwise. The reaction solution was stirred at a temperature of 50 degrees (Celsius) for 40 minutes, concentrated under reduced pressure, and then precipitated in hexane to obtain 12FDTBTOC (0.37 g).

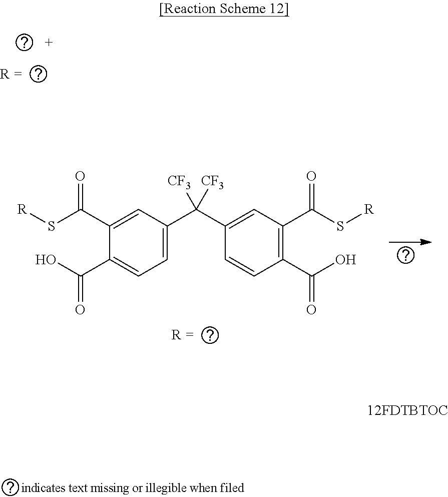

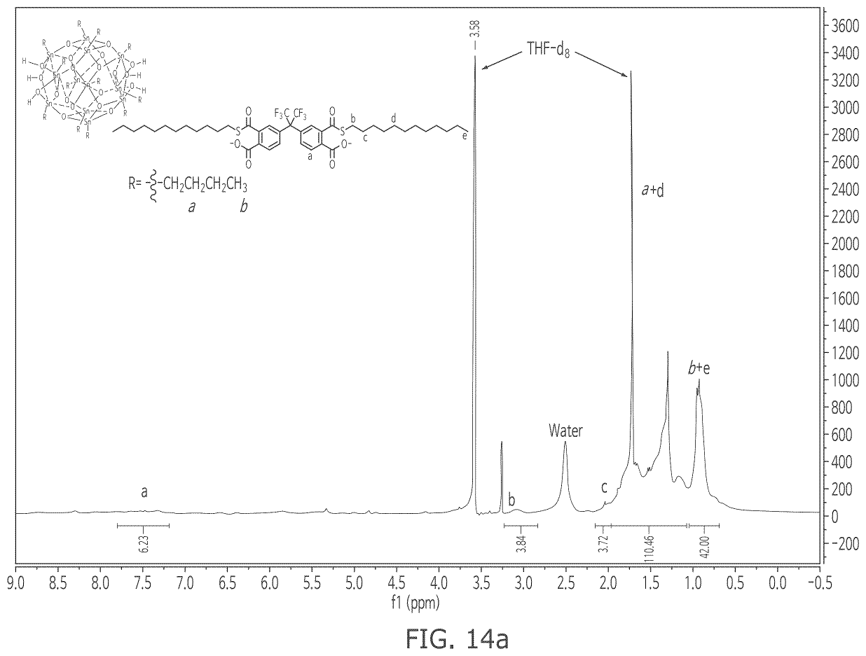

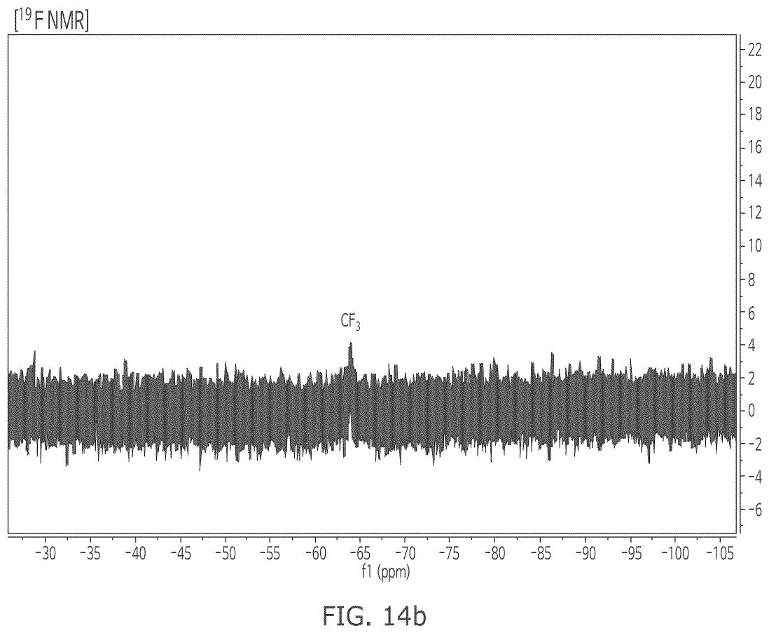

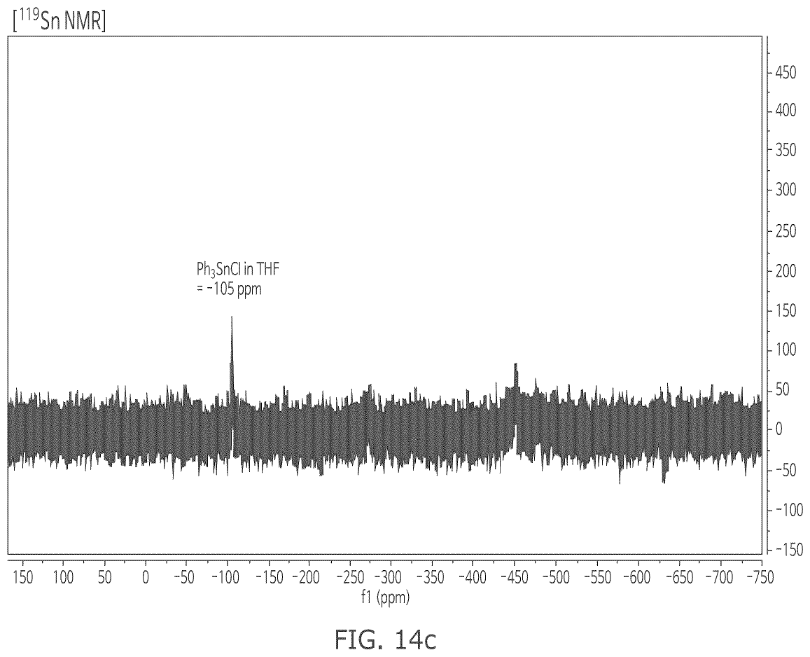

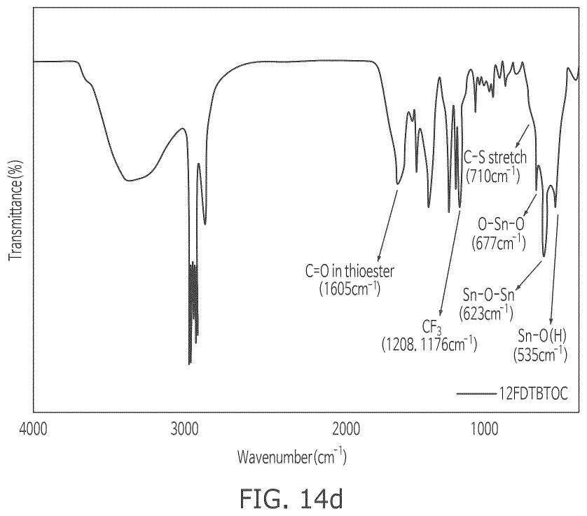

FIG. 14a illustrates a 1H-NMR graph of 12FDTBTOC synthesized according to Experimental Example 15, FIG. 14b illustrates a 19F-NMR graph, FIG. 14c illustrates a 119Sn-NMR graph, and FIG. 14d illustrates an FT-IR graph of 12FDTBTOC synthesized according to Experimental Example 15. (1H-NMR (400 MHz, THF-d8, δ, ppm): 8.41-7.28 (m, 6H, 6xAr-H), 3.22-2.89 (m, 4H, 2x-SCH2-), 2.16-1.07 (m, 112H, 56xCH2), 1.05-0.69 (m, 42H, 14xCH3), 19F-NMR (377 MHz, THF-d8, δ, ppm): −63.64 (s, 6F, 2 x CF3), 119Sn-NMR (149 MHz, THF-d8, δ, ppm): −271.01 (s), —448.7 (s) IR [(KBr): vmax, (cm-1)]1605, 1208, 1176, 710, 677, 623, 535)

Referring to FIGS. 14a to 14d, it can be confirmed that a tin oxide nanocluster (12FDTBTOC) including a conjugate base of 12FDTHIOESTER as a counter anion was synthesized according to Experimental Example 15.

### [Experimental Example 16] Evaluation of 254 nm Ultraviolet Lithography for 10FDTBTOC (Experimental Example 14) and 12FDEBTOC (Experimental Example 7)

10FDTBTOC was dissolved in a mixed solvent of MEK:nBA=9:1 to prepare a resist composition solution with a concentration of 4 wt/vol %. 12FDTBTOC was dissolved in a mixed solvent of MEK:2-Heptanone=4:1 to prepare a resist composition solution with a concentration of 3.5 wt/vol %. A solution (20 wt %) in which hexamethyldisilazane (HMDS) was dissolved in PGMEA was spin-coated on a Si wafer at 3000 rotations per minute (rpm) for 30 seconds, and then a substrate was heated at 110 degrees (Celsius) for 1 minute. The resist composition solutions of 10FDTBTOC and 12FDTBTOC were spin-coated on the substrate treated with HAMDS at 1000 rpm and 3000 rpm for 60 seconds, respectively, and then heated at 80 degrees (Celsius) for 1 minute to form a thin film with an approximate thickness of 100 nm. Thereafter, irradiation was performed with an exposure dose of 300 to 5300 mJ/cm² using a 254 nm ultraviolet exposure machine, a development process was performed for 60 seconds using a 2.38% TMAH standard aqueous solution, and washed with DI water to confirm formation of a positive pattern. Thereafter, thickness was measured using an Alpha-step® D-300 stylus profiler manufactured by Kla-Tencor to evaluate solubility characteristics.

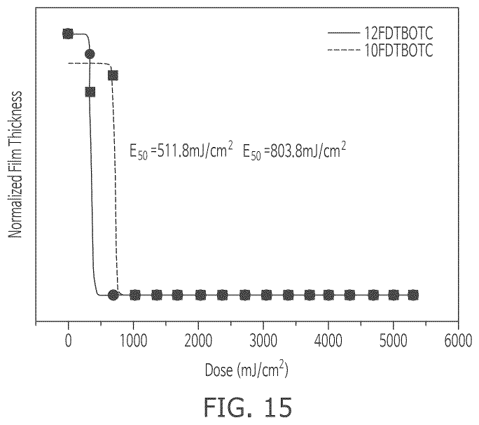

FIG. 15 illustrates solubility characteristics of 10FDTBTOC and 12FDTBTOC obtained by performing 254 nm KrF lithography (deep ultraviolet) according to Experimental Example 16.

Referring to FIG. 15, it can be confirmed that when ultraviolet of 512 mJ/cm² and 804 mJ/cm² is respectively irradiated onto a resist thin film with a thickness of 100 nm formed according to Experimental Example 16, about 50% of the resist thin film thickness can be maintained. In addition, when the ultraviolet irradiation dose is low, solubility of the resist thin film in a basic developer (TMAH) does not increase, and when the ultraviolet irradiation dose increases above a certain amount, solubility of the resist thin film in the basic developer (TMAH) increases.

### [Experimental Example 17] Electron Beam Lithography of 10FDTBTOC (Experimental Example 14) and 12FDEBTOC (Experimental Example 7)

10FDTBTOC was dissolved in a mixed solvent of MEK:nBA=9:1, and 12FDTBTOC was dissolved in a mixed solvent of MEK:2-Heptanone=4:1 to prepare resist composition solutions with concentrations of 4 wt/vol % and 3.5 wt/vol %, respectively. A solution (20 wt %) in which hexamethyldisilazane (HMDS) was dissolved in PGMEA was spin-coated on a Si wafer at 3000 rpm for 30 seconds, and then a substrate was heated at 110 degrees (Celsius) for 1 minute. The resist composition solution was spin-coated on the substrate treated with HMDS at 1000 rpm for 60 seconds, and then heated at 80 degrees (Celsius) for 1 minute to form a thin film with an approximate thickness of 80 nm. An electron beam of 100 to 2,500 μC/cm² was irradiated onto the resist composition thin film under an acceleration voltage of 80 keV. A development process was performed for 60 seconds using a 2.38% TMAH standard aqueous solution, and washed with DI water to fabricate a positive resist pattern.

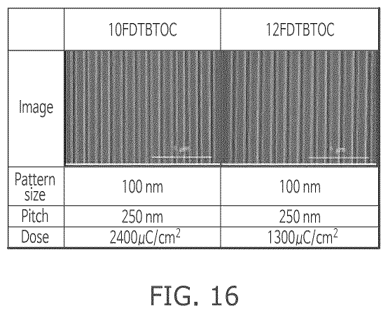

FIG. 16 illustrates positive patterns of 10FDTBTOC and 12FDTBTOC observed through a scanning electron microscope after performing electron beam lithography according to Experimental Example 17.

Referring to FIG. 16, after patterning a resist pattern by irradiating an electron beam of 2400 μC/cm² onto a 10FDTBTOC resist thin film formed according to Experimental Example 17, a development process was performed using a basic developer (TMAH), and as a result, a positive resist pattern of 100 nm was formed. After patterning a resist pattern by irradiating an electron beam of 1300 μC/cm² onto each of 12FDTBTOC resist thin films formed according to Experimental Example 17, a development process was performed using a basic developer (TMAH), and as a result, a positive resist pattern of 100 nm was formed.

### [Experimental Example 18] Extreme Ultraviolet Lithography of 10FDTBTOC (Experimental Example 14) and 12FDEBTOC (Experimental Example 7)

10FDTBTOC was dissolved in a mixed solvent of MEK:nBA=9:1 to prepare a resist composition solution with a concentration of 3.5 wt/vol %, and 12FDTBTOC was dissolved in a mixed solvent of MEK:Cyclohexanone=4:1 to prepare a resist composition solution with a concentration of 2.5 wt/vol %. A solution (20 wt %) in which hexamethyldisilazane (HMDS) was dissolved in PGMEA was spin-coated on a Si wafer at 3000 rpm for 30 seconds, and then a substrate was heated at 110 degrees (Celsius) for 1 minute. The resist composition solutions were spin-coated on the substrate treated with HMDS at 800 rpm and 3000 rpm for 60 seconds, respectively, and then heated at 80 degrees (Celsius) for 1 minute to form a thin film with an approximate thickness of 100 nanometers (nm). Extreme ultraviolet of 5 to 125 mJ/cm² was irradiated onto the resist composition thin film. For 10FDTBTOC, a development process was performed for 50 seconds using a 2.38% TMAH standard aqueous solution, and for 12FDTBTOC, a development process was performed for 30 seconds using a mixed solution of a 2.38% TMAH standard aqueous solution and DI water in a ratio of 8:1, and washed with DI water to fabricate a positive resist pattern.

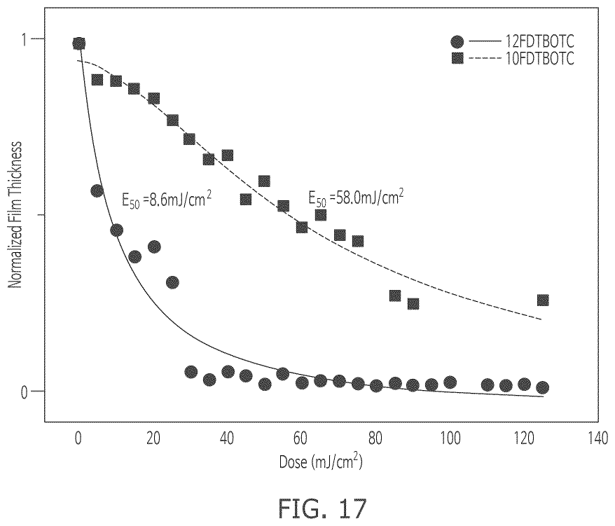

FIG. 17 illustrates solubility characteristics of 10FDTBTOC and 12FDTBTOC obtained by performing extreme ultraviolet lithography according to Experimental Example 18.

Referring to FIG. 17, it can be confirmed that when ultraviolet of 8.6 mJ/cm² and 58.0 mJ/cm² is irradiated onto a resist thin film with a thickness of 100 nm formed according to Experimental Example 18, about 50% of the resist thin film thickness can be maintained.

Referring to FIGS. 15 to 17, it can be confirmed that positive resist patterns are formed using resist compositions of 10FDTBTOC and 12FDEBTOC. As ultraviolet or an electron beam is irradiated onto a resist thin film formed of the resist composition, an organic ligand (butyl group) of a tin oxide nanocluster (10FDTBTOC, 12FDEBTOC) may be detached in an exposed region of the resist thin film, and accordingly, a core structure of the tin oxide nanocluster may have Lewis acidity. In the exposed region of the resist thin film, a functional group functioning as a Lewis base of a counter anion bonded to the core structure of the tin oxide nanocluster may bond to a tin atom that has lost the organic ligand. Accordingly, solubility of an exposed region of the resist thin film in a basic developer (TMAH) may be adjusted and/or controlled, and a dissolution contrast between the exposed region and an unexposed region of the resist thin film may be increased. Thereafter, the exposed region of the resist thin film may be selectively removed by a development process using the basic developer (TMAH), and accordingly, a positive resist pattern may be formed.

### [Experimental Example 19] Synthesis of 8PESTER (Structural Formula 5, Reaction Scheme 13)

To a 100 cm³ round bottom flask (RBF), PMDA (3.0 g, 13.8 mmol), 1-octanol (5.12 cm³, 34.4 mmol), pyridine (3.50 cm³, 16.5 mmol), and DMAP (0.17 g, 1.38 mmol) were added, toluene (75 cm³) was added, and then stirred at 100° C. for 2 hours. To terminate the reaction, a 6N HCl aqueous solution was slowly added dropwise to a reactant. A separated organic solvent layer was washed with water, basified using a 20% Na2CO3 aqueous solution, and an aqueous solution layer including salt was separated. Then, the solution was diluted with toluene, and a HCl aqueous solution was slowly added dropwise to separate an organic layer and an aqueous solution layer. Thereafter, the organic solvent layer was washed with water. Moisture was removed using anhydrous MgSO₄, and the solution was concentrated under reduced pressure. 8PESTER (2.86 g, 43%) was obtained.

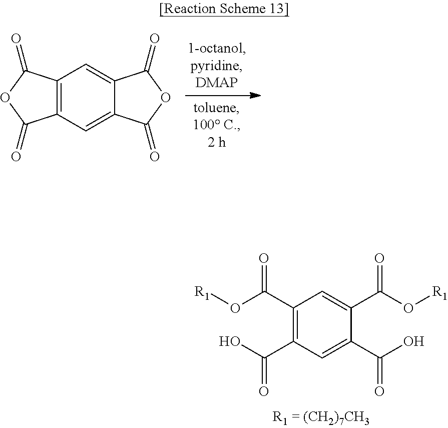

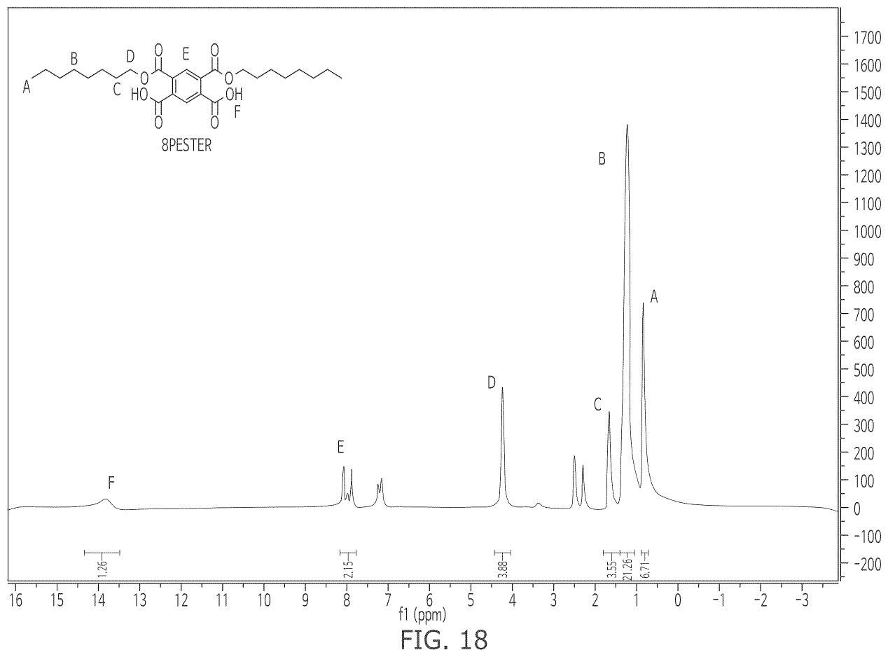

FIG. 18 illustrates a 1H-NMR graph of 8PESTER synthesized according to Experimental Example 19. (1H-NMR (400 MHz, DMSO, ppm): δ=13.80 (s, 2H, 2xOH), 8.17-7.78 (m, 2H, 2xCH), 4.24 (t, J=5.6 Hz, 4H, 2xCH2), 1.66 (t, J=6.4 Hz, 4H, 2xCH2), 1.39-1.08 (m, 20H, 10xCH2), 0.83 (t, J=6.0 Hz, 6H, 2xCH3))

Referring to FIG. 18, it can be confirmed that 8PESTER, which is a Pyromellitic dianhydride(PMDA)-based diester compound having an octyl chain, was synthesized.

### [Experimental Example 20] Synthesis of 10PESTER (Structural Formula 5, Reaction Scheme 14)

To a 250 cm³ RBF, PMDA (3.0 g, 13.8 mmol), 1-decanol (6.55 cm³, 34.4 mmol), and Et3N (1.67 g, 16.50 mmol) were added, CH2Cl2 (75 cm³) was added, and then stirred at room temperature for 2 hours. Thereafter, the solution was diluted with CH2Cl2, and water was slowly added dropwise to separate an organic layer and an aqueous solution layer. Moisture was removed using anhydrous MgSO₄, and the solution was concentrated under reduced pressure to obtain 10PESTER (4.24 g, 58%).

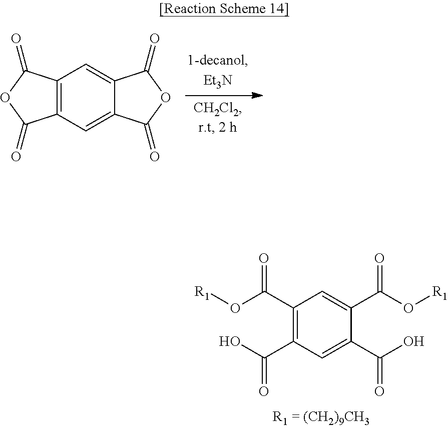

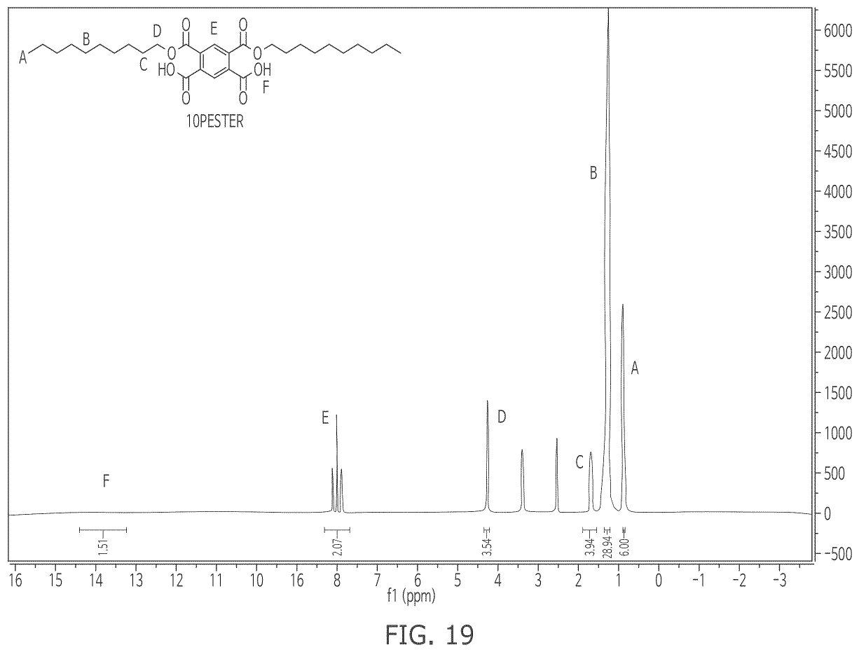

FIG. 19 illustrates a 1H-NMR graph of 10PESTER synthesized according to Experimental Example 20. (1H-NMR (400 MHz, DMSO, ppm): δ=13.68 (s, 2H, 2xOH), 8.31-7.67 (m, 2H, 2xCH), 4.25 (t, J=6.5 Hz, 4H, 2xCH2), 1.83-1.51 (m, 4H, 2xCH2), 1.31-1.18 (m, 28H, 14xCH2), 0.84 (t, J=5.8 Hz, 6H, 2xCH3))

Referring to FIG. 19, it can be confirmed that 10PESTER, which is a Pyromellitic dianhydride(PMDA)-based diester compound having a decanyl chain, was synthesized.

### [Experimental Example 21] Synthesis of 12PESTER (Structural Formula 5, Reaction Scheme 15)

To a 250 cm³ RBF, PMDA (3.0 g, 13.8 mmol), 1-dodecanol (7.70 cm³, 34.4 mmol), and Et3N (1.67 g, 16.50 mmol) were added, CH2Cl2 (75 cm³) was added, and then stirred at room temperature for 2 hours. Thereafter, the solution was diluted with CH2Cl2, and water was slowly added dropwise to separate an organic layer and an aqueous solution layer. Moisture was removed using anhydrous MgSO₄, and the solution was concentrated under reduced pressure to obtain 12PESTER (4.18 g, 51%).

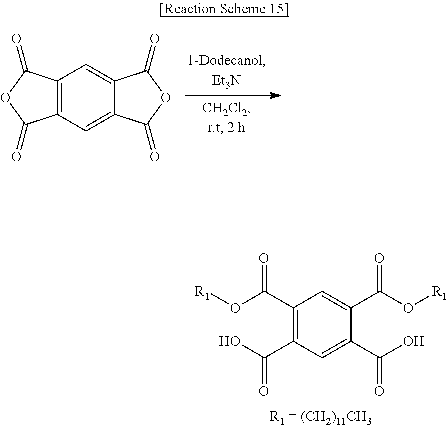

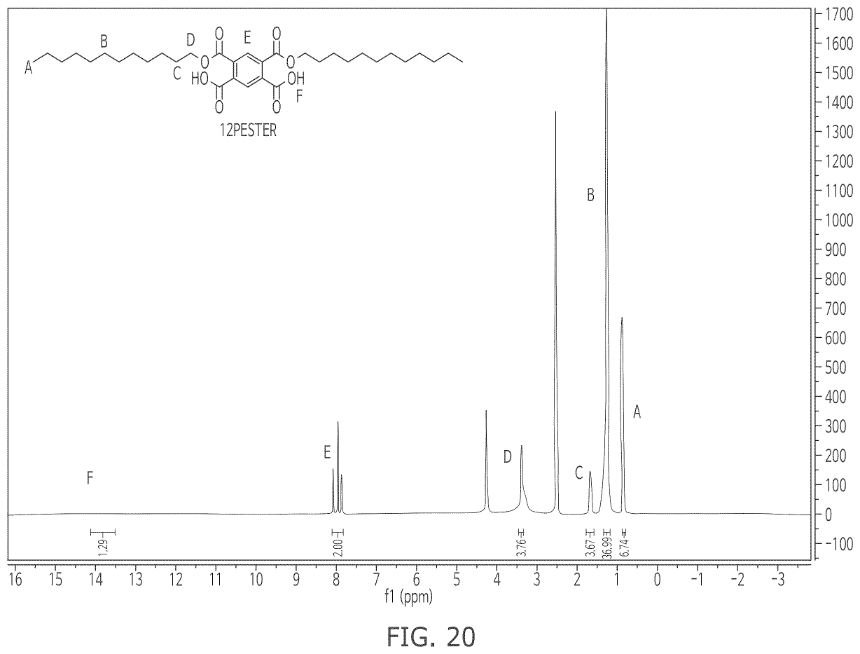

FIG. 20 illustrates a 1H-NMR graph of 12PESTER synthesized according to Experimental Example 21. (1H-NMR (400 MHz, DMSO, ppm): δ=13.82 (s, 2H, 2xOH), 7.96 (t, J=40.4 Hz, 6H, 6xCH), 3.37 (t, J=6.5 Hz, 4H, CH2), 1.76-1.59 (m, 4H, CH2), 1.42-1.15 (m, 36H, 18xCH2), 0.86 (td, J=6.7, 4.2 Hz, 6H, 2xCH3))

Referring to FIG. 20, it can be confirmed that 12PESTER, which is a Pyromellitic dianhydride(PMDA)-based diester compound having a dodecanyl chain, was synthesized.

### [Experimental Example 22] Synthesis of 10PAMIDE (Structural Formula 6, Reaction Scheme 16)

To a 250 cm³ RBF, PMDA (2.0 g, 9.17 mmol) and aminodecane (4.58 cm³, 22.9 mmol) were added, THF (30 cm³) was added, and then stirred at room temperature for 2 hours. After concentration under reduced pressure, precipitation was performed in hexane to recover a product (4.8 g, 98%).

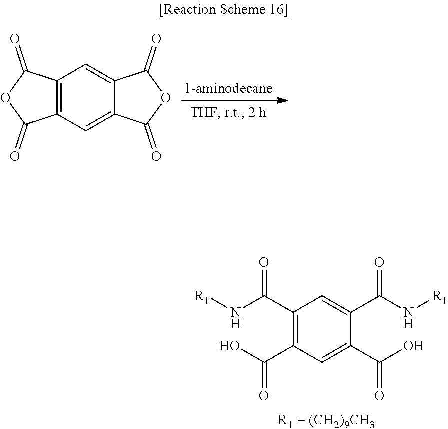

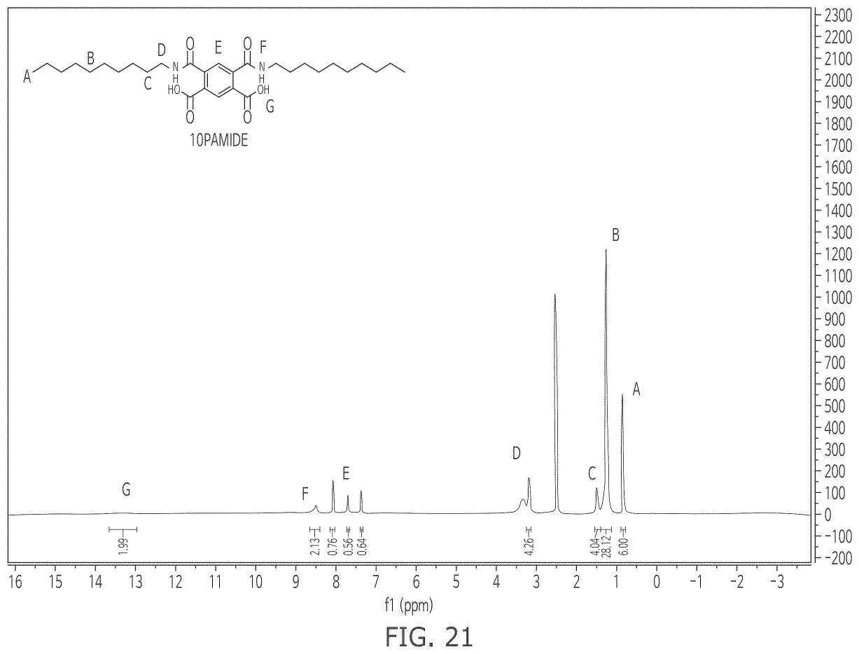

FIG. 21 illustrates a 1H-NMR graph of 10PAMIDE synthesized according to Experimental Example 22. (1H-NMR (400 MHz, DMSO): δ=13.30 (s, 2H, 2xOH), 8.49 (s, 2H, 2xNH), 8.10-7.31 (m, 2H, 2xCH), 3.19 (dd, J=12.7, 6.7 Hz, 4H, 2xCH2), 1.49 (dd, J=6.4, 5.2 Hz, 4H, CH2), 1.38-1.14 (m, 28H, 14xCH2), 0.87 (t, J=6.7 Hz, 6H, 2xCH3))

Referring to FIG. 21, it can be confirmed that 10PAMIDE, which is a Pyromellitic dianhydride(PMDA)-based diamide compound having a decanyl chain, was synthesized.

### [Experimental Example 23] Synthesis of 8DPESTER (Structural Formula 8, Reaction Scheme 17)

To a 250 cm³ RBF, BPDA (3.0 g, 10.20 mmol), 1-octanol (4.03 cm³, 3.32 mmol), and Et3N (1.24 g, 12.24 mmol) were added, CH2Cl2 (75 cm³) was added, and then stirred at room temperature for 2 hours. Thereafter, the solution was diluted with CH2Cl2, and water was slowly added dropwise to separate an organic layer and an aqueous solution layer. Moisture was removed using anhydrous MgSO₄, and the solution was concentrated under reduced pressure to obtain 8DPESTER (3.50 g, 62%).

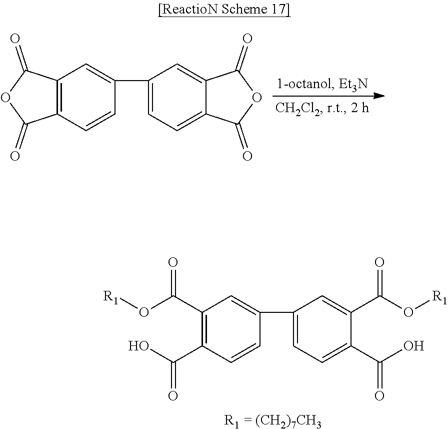

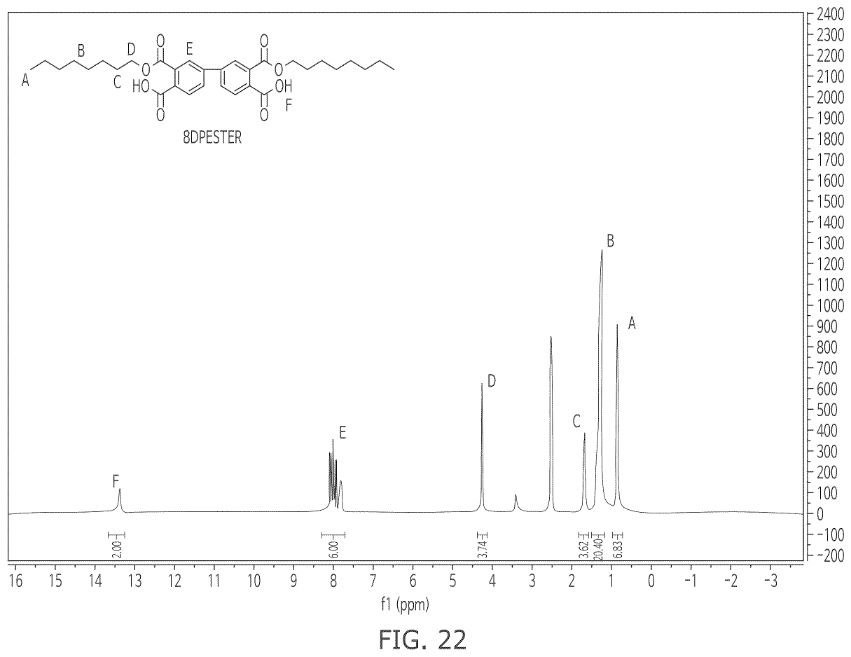

FIG. 22 illustrates a 1H-NMR graph of 8DPESTER synthesized according to Experimental Example 23. (1H-NMR (400 MHz, DMSO, ppm): δ=13.36 (s, 2H, 2xOH), 8.29-7.70 (m, 6H, 6xCH), 4.24 (t, J=6.5 Hz, 4H, 2xCH2), 1.67 (dd, J=14.0, 6.9 Hz, 4H, 2xCH2), 1.49-1.16 (m, 20H, 10xCH2), 0.83 (t, J=7.2 Hz, 6H, 2xCH3))

Referring to FIG. 22, it can be confirmed that 8DPESTER, which is a 4,4′-Biphthalic Anhydride(BPDA)-based diester compound having an octyl chain, was synthesized.

### [Experimental Example 24] Synthesis of 10DPESTER (Structural Formula 8, Reaction Scheme 18)

To a 250 cm³ RBF, BPDA (3.0 g, 10.20 mmol), 1-decanol (4.86 cm³, 3.32 mmol), and Et3N (1.24 g, 12.24 mmol) were added, CH2Cl2 (75 cm³) was added, and then stirred at room temperature for 2 hours. Thereafter, the solution was diluted with CH2Cl2, and water was slowly added dropwise to separate an organic layer and an aqueous solution layer. Moisture was removed using anhydrous MgSO₄, and the solution was concentrated under reduced pressure to obtain 10DPESTER (2.42 g, 62%).

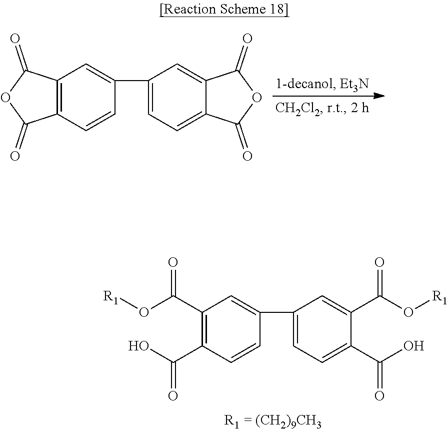

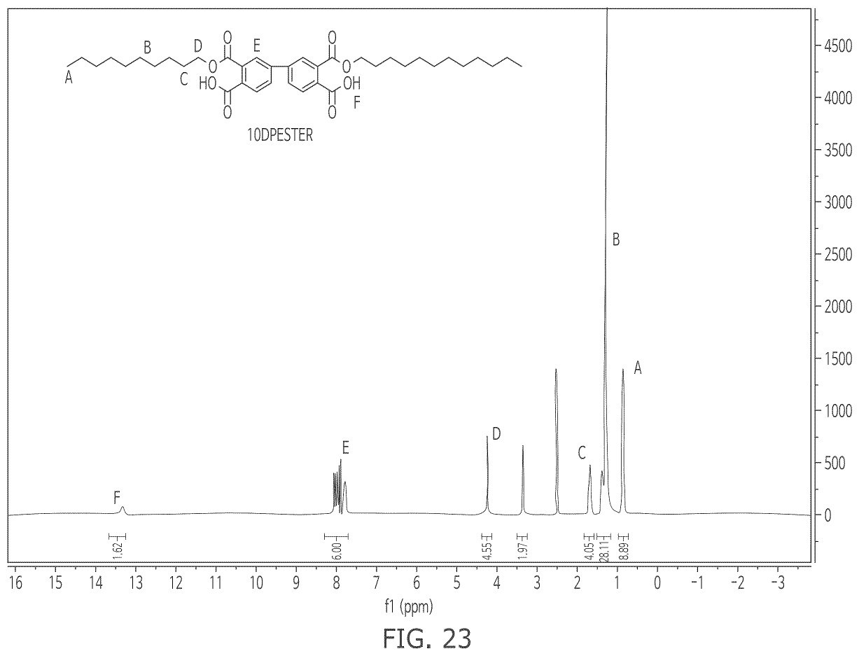

FIG. 23 illustrates a 1H-NMR graph of 10DPESTER synthesized according to Experimental Example 24. (1H-NMR (400 MHz, DMSO, ppm): δ=13.41 (s, 2H, 2xOH), 8.18-7.70 (m, 6H, 6xCH), 4.24 (t, J=5.9 Hz, 4H, 2xCH2), 1.72-1.62 (m, 4H, 2xCH2), 1.42-1.19 (m, 28H, 14xCH2), 0.84 (q, J=6.8 Hz, 6H, 2xCH3))

Referring to FIG. 23, it can be confirmed that 10DPESTER, which is a 4,4′-Biphthalic Anhydride(BPDA)-based diester compound having a decanyl chain, was synthesized.

### [Experimental Example 25] Synthesis of 12DPESTER (Structural Formula 8, Reaction Scheme 19)

To a 250 cm³ RBF, BPDA (3.0 g, 10.20 mmol), 1-dodecanol (5.72 cm³, 3.32 mmol), and Et3N (1.24 g, 12.24 mmol) were added, CH2Cl2 (75 cm³) was added, and then stirred at room temperature for 2 hours. Thereafter, the solution was diluted with CH2Cl2, and water was slowly added dropwise to separate an organic layer and an aqueous solution layer. Moisture was removed using anhydrous MgSO₄, and the solution was concentrated under reduced pressure to obtain 12DPESTER (4.01 g, 95%).

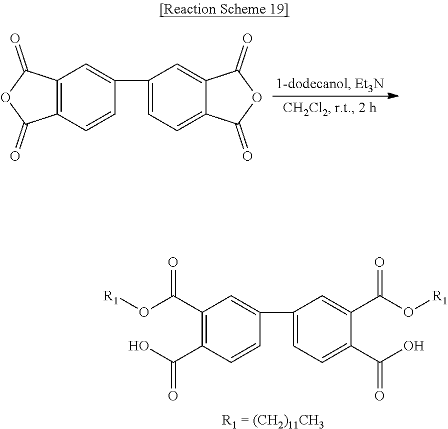

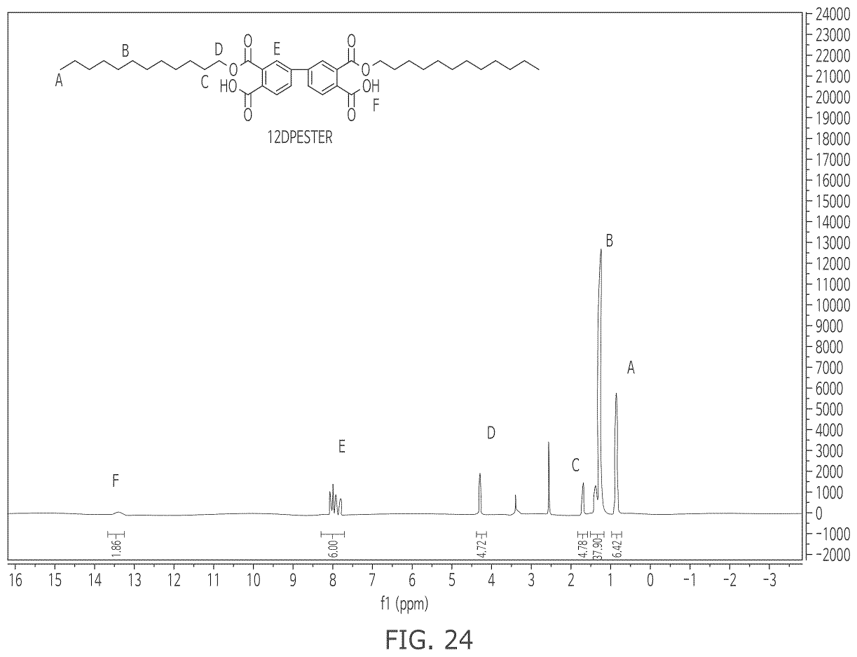

FIG. 24 illustrates a 1H-NMR graph of 12DPESTER synthesized according to Experimental Example 25. (1H-NMR (400 MHz, DMSO, ppm): δ=13.35 (s, 2H, 2xOH), 8.09-7.68 (m, 6H, 6xCH), 4.24 (t, J=6.5 Hz, 4H, CH2), 1.75-1.61 (m, 4H, CH2), 1.24-1.18 (m, 36H, 18xCH2), 0.81 (d, J=7.0 Hz, 6H, 2xCH3))

Referring to FIG. 24, it can be confirmed that 12DPESTER, which is a 4,4′-Biphthalic Anhydride(BPDA)-based diester compound having a dodecanyl chain, was synthesized.

### [Experimental Example 26] Synthesis of 10DPAMIDE (Structural Formula 9, Reaction Scheme 20)

To a 250 cm³ RBF, BPDA (2.0 g, 6.80 mmol) and aminodecane (3.39 cm³, 16.9 mmol) were added, THF (30 cm³) was added, and then stirred at room temperature for 2 hours. After concentration under reduced pressure, precipitation was performed in hexane to obtain a product (4.1 g, 99%).

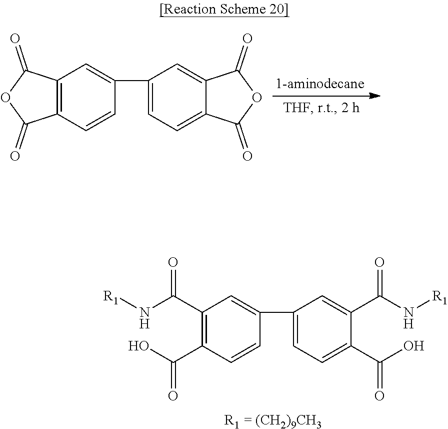

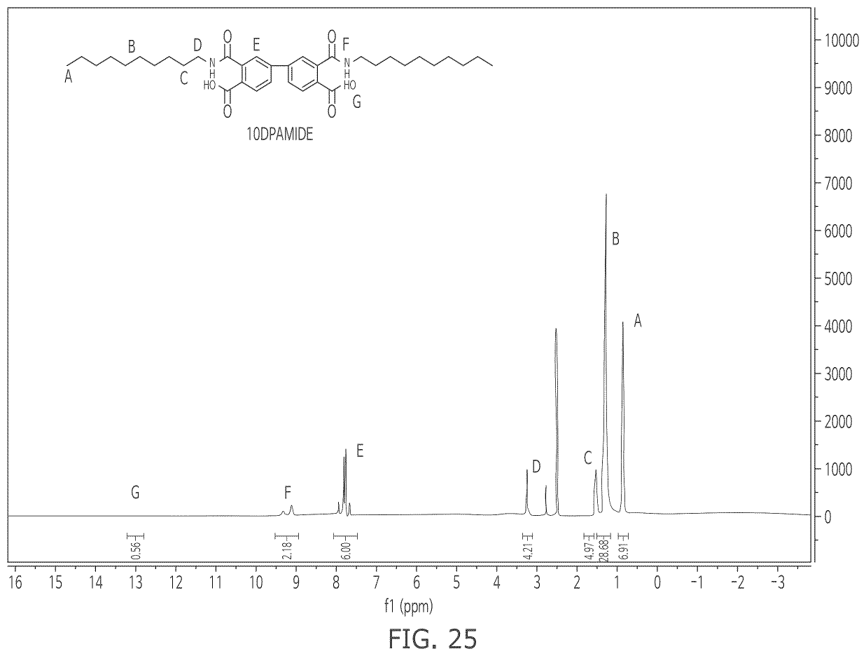

FIG. 25 illustrates a 1H-NMR graph of 10DPAMIDE synthesized according to Experimental Example 26. (1H-NMR (400 MHz, DMSO): δ=13.76 (s, 2H, 2xOH), 9.21 (d, J=83.5 Hz, 2H, 2xNH), 7.94-7.58 (m, 6H, 6xCH), 3.32-3.10 (m, 4H, 2xCH2), 1.57-1.46 (m, 4H, CH2), 1.31-1.21 (m, 28H, 7xCH2), 0.89-0.83 m, 6H, 2xCH3))

Referring to FIG. 25, it can be confirmed that 10DPAMIDE, which is a 4,4′-Biphthalic Anhydride(BPDA)-based diamide compound having a decanyl chain, was synthesized.

### [Experimental Example 27] Synthesis of a Tin Oxide Nanocluster Including a Conjugate Base of 8PESTER as a Counter Anion (8PEBTOC, Structural Formula 1) (Reaction Scheme 21)

A solution was prepared by adding tetramethylammonium hydroxide pentahydrate (TMAH, 5.89 g, 31.9 mmol) and deionized water (DI water, 64 cm³) to a 70 cm³ vial, and then butyltin trichloride (3.0 g, 10.6 mmol) was added. A reaction solution was vigorously stirred at room temperature for 2 hours, and then an obtained product was filtered while being washed several times with DI water. After vacuum drying, a tin oxide nanocluster (BTOC, 1.9 g) in a white solid form was obtained. BTOC (lg, 0.41 mmol) and THF (24 cm³) were added to a 70 cm³ vial and dissolved. 8PESTER (0.19 g, 0.41 mmol) was diluted with THF (6 cm³) in a 20 cm³ vial. Thereafter, the diluted 8PESTER was slowly added dropwise to the 70 cm³ vial in which BTOC was dissolved, and then stirred at 50° C. for 40 minutes. After concentration under reduced pressure, precipitation was performed in hexane to obtain 8PEBTOC (1.05 g, 88%).

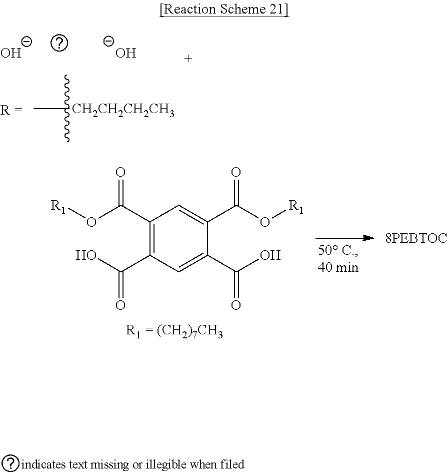

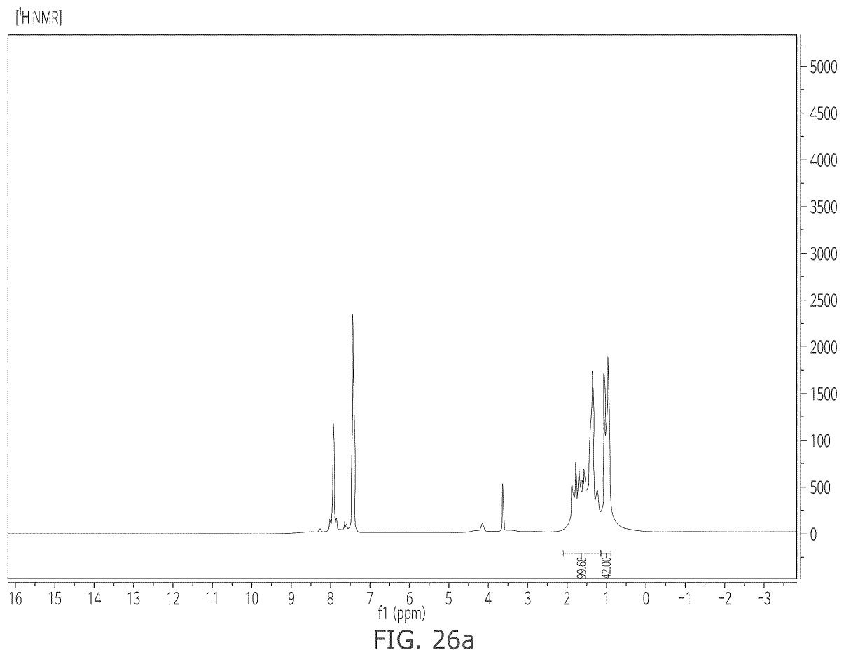

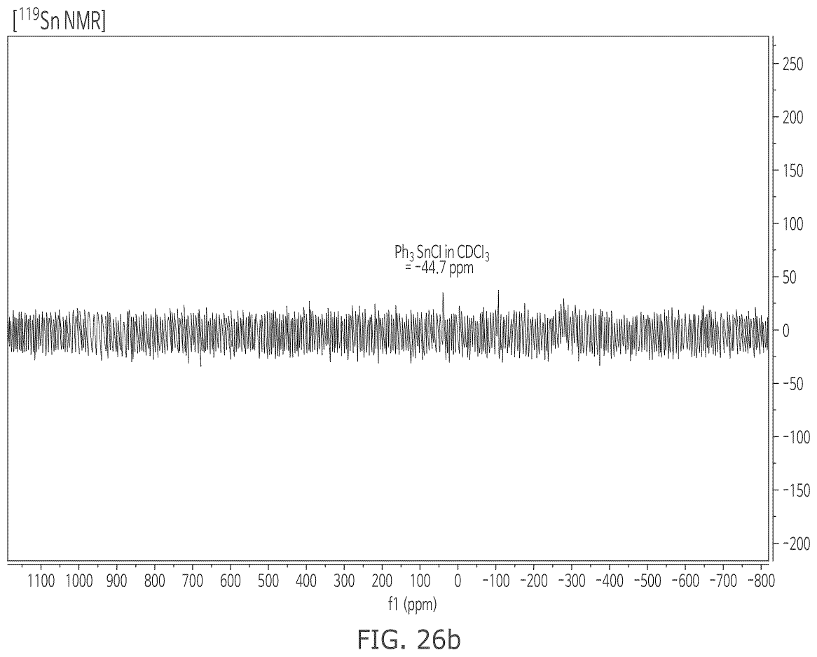

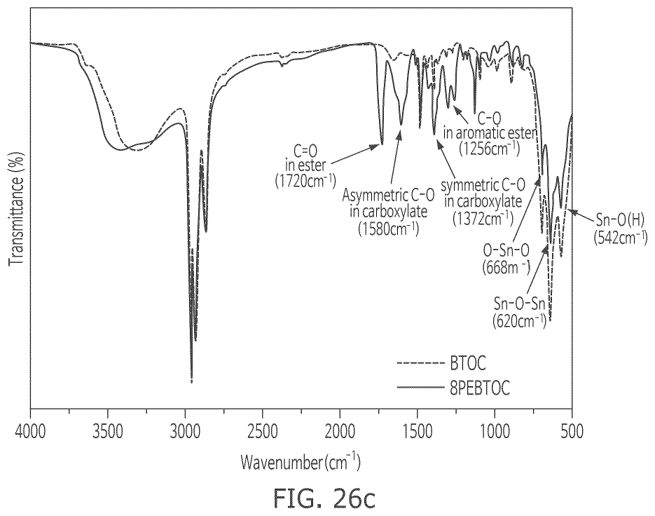

FIG. 26a illustrates a 1H-NMR graph of 8PEBTOC synthesized according to Experimental Example 27, FIG. 26b illustrates a 119Sn-NMR graph, and FIG. 26c illustrates an FT-IR graph of 8PEBTOC synthesized according to Experimental Example 27. (1H-NMR (400 MHz, CDCl3, ppm): δ=3.06-1.08 (m, 100H, 50xCH2), 0.98 (ddd, J=14.0, 12.7, 7.1 Hz, 42H, 24xCH3), 119Sn-NMR (149 MHz, CDCl3): δ=−189.41-−199.57 (m), —354.40-−380.42 (m); IR [(KBr): vmax, (cm-1)]1720, 1580, 1372, 1256, 668, 620, 542)

Referring to FIGS. 26a to 26c, it can be confirmed that a tin oxide nanocluster (8PEBTOC) including a conjugate base of 8PESTER as a counter anion was synthesized according to Experimental Example 27.

### [Experimental Example 28] Synthesis of a Tin Oxide Nanocluster Including a Conjugate Base of 10PESTER as a Counter Anion (10PEBTOC, Structural Formula 1) (Reaction Scheme 22)

A solution was prepared by adding TMAH (5.89 g, 31.9 mmol) and DI water (64 cm³) to a 70 cm³ vial, and then butyltin trichloride (3.0 g, 10.6 mmol) was added. A reaction solution was vigorously stirred at room temperature for 2 hours, and then an obtained product was filtered while being washed several times with DI water. After vacuum drying, a tin oxide nanocluster (BTOC, 1.9 g) in a white solid form was obtained. BTOC (lg, 0.41 mmol) and THF (24 cm³) were added to a 70 cm³ vial and dissolved. 10PESTER (0.22 g, 0.41 mmol) was diluted with THF (6 cm³) in a 20 cm³ vial. Thereafter, the diluted 10PESTER was slowly added dropwise to the 70 cm³ vial in which BTOC was dissolved, and then stirred at 50° C. for 40 minutes. After concentration under reduced pressure, precipitation was performed in hexane to obtain 10PEBTOC (1.05 g, 76%).

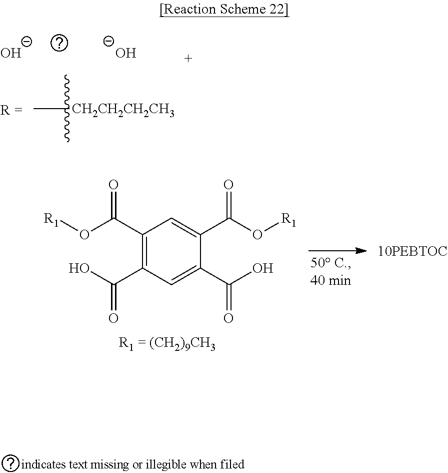

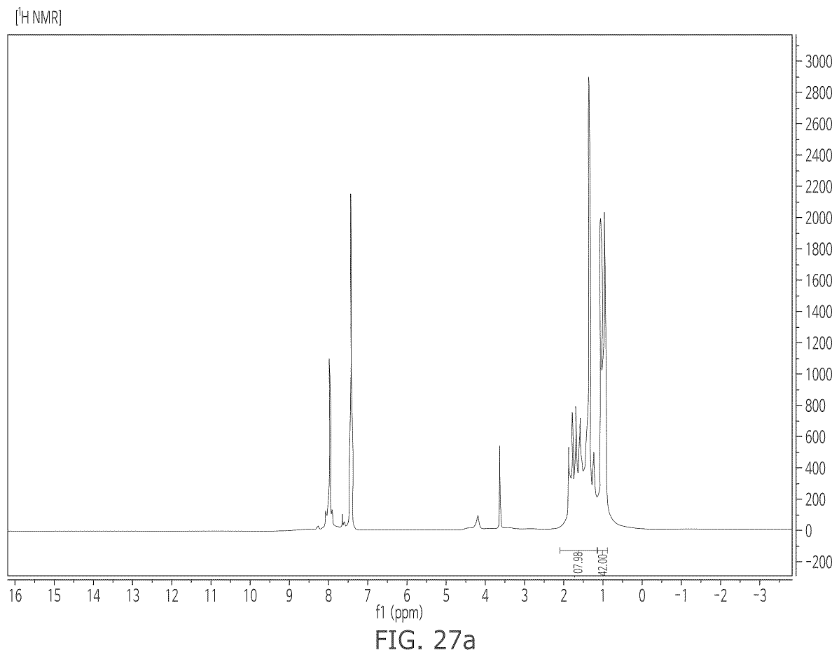

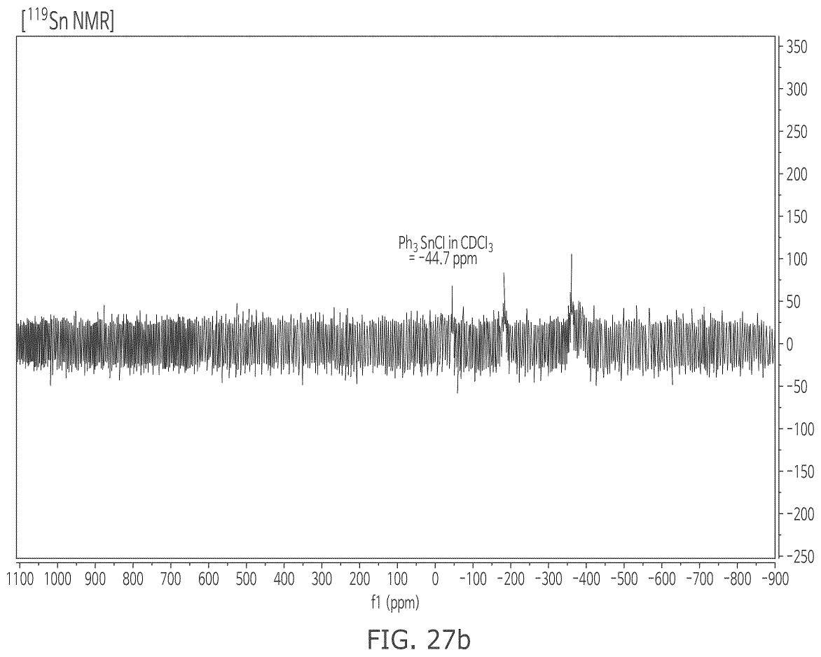

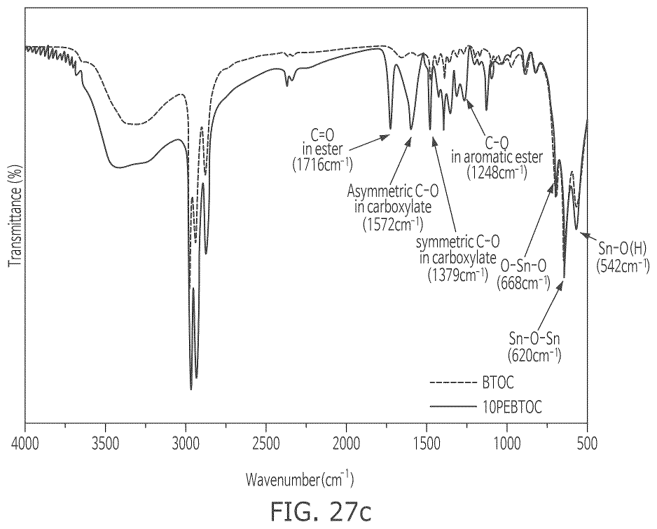

FIG. 27a illustrates a 1H-NMR graph of 10PEBTOC synthesized according to Experimental Example 28, FIG. 27b illustrates a 119Sn-NMR graph, and FIG. 27c illustrates an FT-IR graph of 10PEBTOC synthesized according to Experimental Example 28. (1H-NMR (400 MHz, CDCl3, ppm): δ=2.14-1.08 (m, 108H, 54xCH2), 0.98 (ddd, J=14.2, 12.7, 7.1 Hz, 42H, 24xCH3), 119Sn-NMR (149 MHz, CDCl3): δ=−176.07-−188.13 (m)-353.12-−367.08 (m); IR [(KBr): vmax, (cm-1)]1716, 1572, 1379, 1248, 668, 620, 542)

Referring to FIGS. 27a to 27c, it can be confirmed that a tin oxide nanocluster (10PEBTOC) including a conjugate base of 10PESTER as a counter anion was synthesized according to Experimental Example 28.

### [Experimental Example 29] Synthesis of a Tin Oxide Nanocluster Including a Conjugate Base of 12PESTER as a Counter Anion (12PEBTOC, Structural Formula 1) (Reaction Scheme 23)

A solution was prepared by adding TMAH (5.89 g, 31.9 mmol) and DI water (64 cm³) to a 70 cm³ vial, and then butyltin trichloride (3.0 g, 10.6 mmol) was added. A reaction solution was vigorously stirred at room temperature for 2 hours, and then an obtained product was filtered while being washed several times with DI water. After vacuum drying, a tin oxide nanocluster (BTOC, 1.9 g) in a white solid form was obtained. BTOC (lg, 0.41 mmol) and THF (24 cm³) were added to a 70 cm³ vial and dissolved. 12PESTER (0.24 g, 0.41 mmol) was diluted with THF (6 cm³) in a 20 cm³ vial. Thereafter, the diluted 12PESTER was slowly added dropwise to the 70 cm³ vial in which BTOC was dissolved, and then stirred at 50° C. for 40 minutes. After concentration under reduced pressure, precipitation was performed in hexane to obtain 12PEBTOC (0.91 g, 74%).

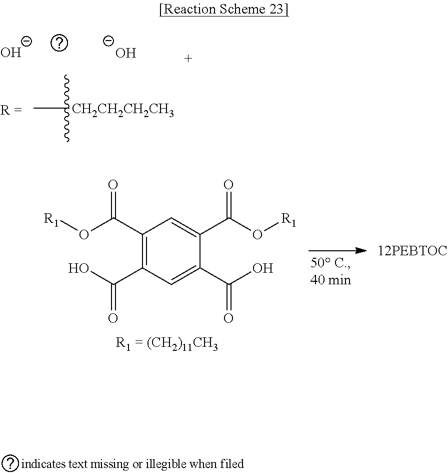

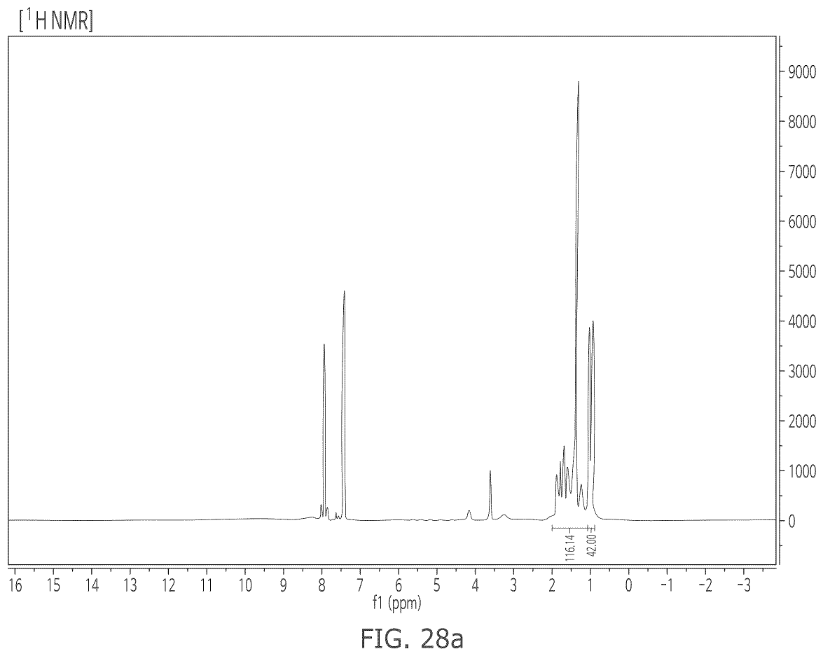

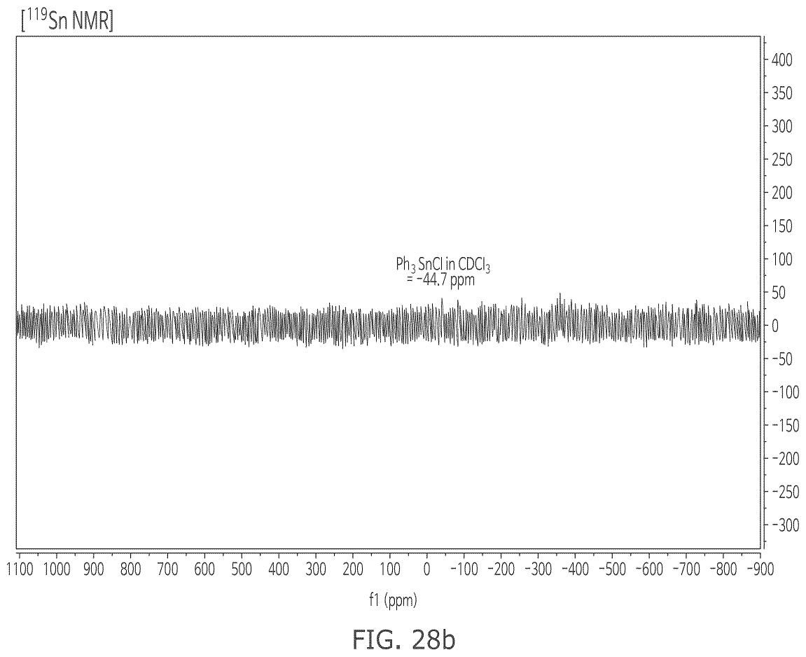

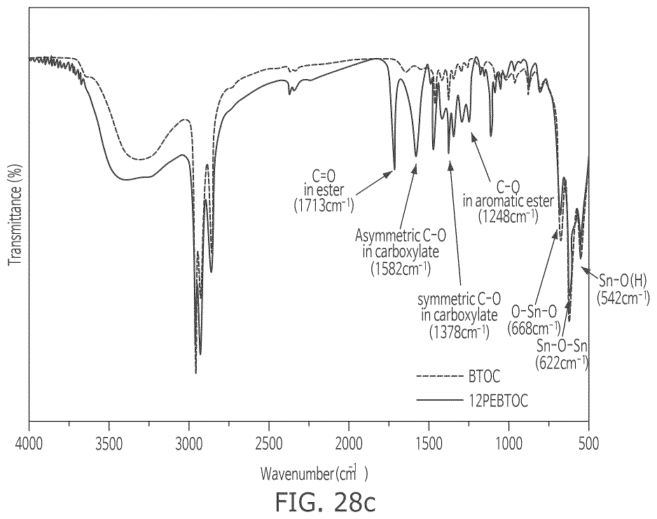

FIG. 28a illustrates a 1H-NMR graph of 12PEBTOC synthesized according to Experimental Example 29, FIG. 28b illustrates a 119Sn-NMR graph, and FIG. 28c illustrates an FT-IR graph of 12PEBTOC synthesized according to Experimental Example 29. (1H-NMR (400 MHz, CDCl3, ppm): δ=1.95-1.04 (m, 116H, 58xCH2), 1.03-0.86 (m, 42H, 24xCH3), 119Sn-NMR (149 MHz, CDCl3): δ=−93.62-−110.76 (m), —272.60-−285.93 (m); IR [(KBr): vmax, (cm-1)]1713, 1582, 1378, 1248, 668, 620, 542)

Referring to FIGS. 28a to 28c, it can be confirmed that a tin oxide nanocluster (12PEBTOC) including a conjugate base of 12PESTER as a counter anion was synthesized according to Experimental Example 29.

### [Experimental Example 30] Synthesis of a Tin Oxide Nanocluster Including a Conjugate Base of 10PAMIDE as a Counter Anion (10PABTOC, Structural Formula 1) (Reaction Scheme 24)

A solution was prepared by adding TMAH (5.89 g, 31.9 mmol) and DI water (64 cm³) to a 70 cm³ vial, and then butyltin trichloride (3.0 g, 10.6 mmol) was added. A reaction solution was vigorously stirred at room temperature for 2 hours, and then an obtained product was filtered while being washed several times with DI water. After vacuum drying, a tin oxide nanocluster (BTOC, 1.9 g) in a white solid form was obtained. BTOC (lg, 0.41 mmol) and THF (24 cm³) were added to a 70 cm³ vial and dissolved. 10PAMIDE (0.22 g, 0.41 mmol) was diluted with THF (6 cm³) in a 20 cm³ vial. Thereafter, the diluted 10PAMIDE was slowly added dropwise to the 70 cm³ vial in which BTOC was dissolved, and then stirred at 50° C. for 40 minutes. After concentration under reduced pressure, precipitation was performed in hexane to obtain 10PABTOC (0.83 g, 68%).

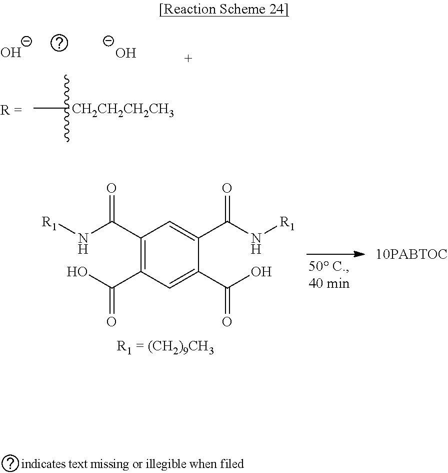

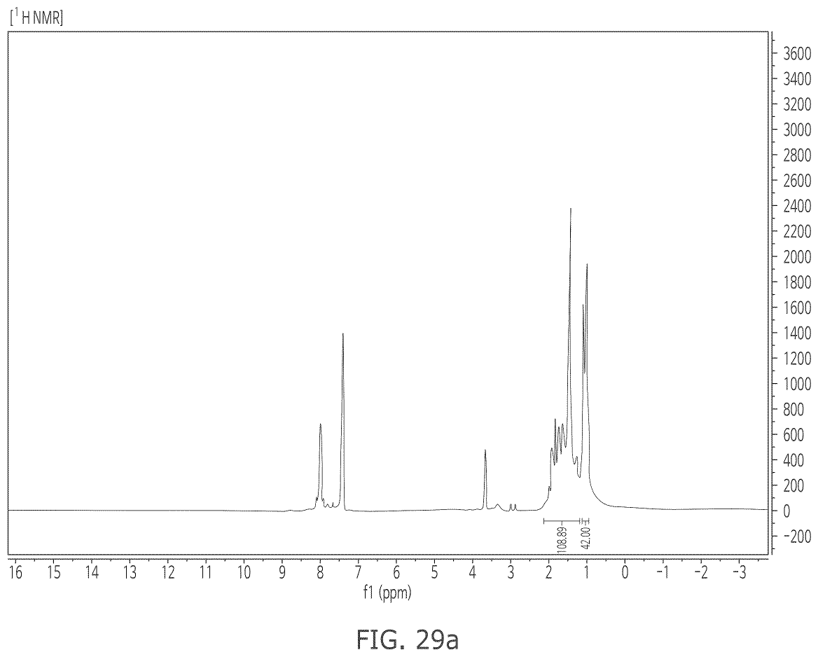

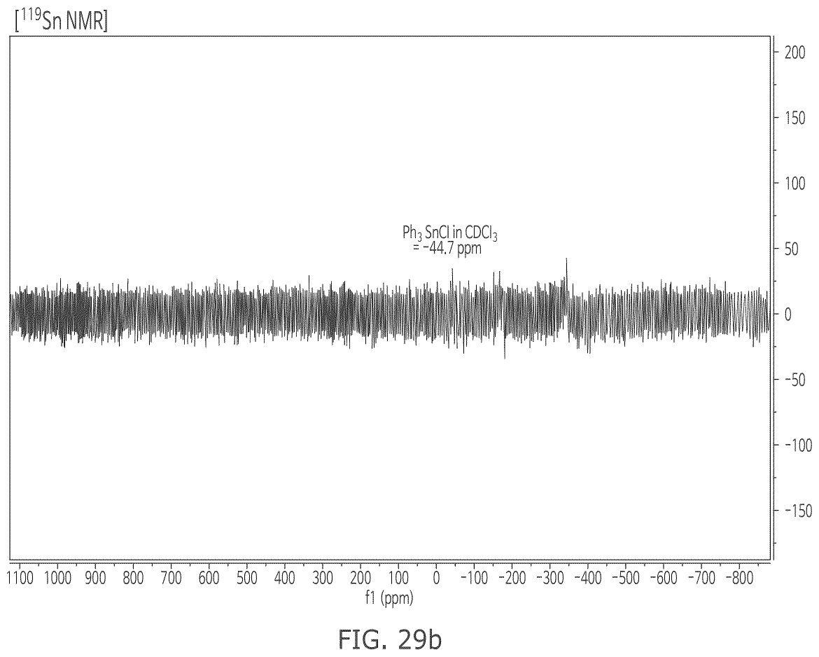

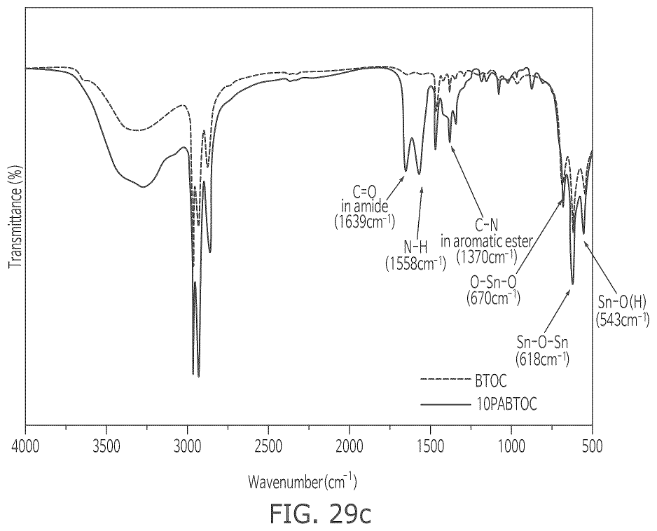

FIG. 29a illustrates a 1H-NMR graph of 10PABTOC synthesized according to Experimental Example 30, FIG. 29b illustrates a 119Sn-NMVR graph, and FIG. 29c illustrates an FT-IR graph of 10PABTOC synthesized according to Experimental Example 30. (1H-NMVR (400 MHz, CDCl3): δ=2.04-1.04 (m, 108H, 54xCH2), 1.00-0.84 (m, 42H, 14xCH3), 119Sn-NMR (149 MHz, CDCl3): δ=−157.03-−175.44 (m), —332.21-−352.51 (m); IR [(KBr): vmax, (cm-1)]1639, 1558, 1370, 670, 618, 543)

Referring to FIGS. 29a to 29c, it can be confirmed that a tin oxide nanocluster (10PABTOC) including a conjugate base of 10PAMIDE as a counter anion was synthesized according to Experimental Example 30.

### [Experimental Example 31] Synthesis of a Tin Oxide Nanocluster Including a Conjugate Base of 8DPESTER as a Counter Anion (8DPEBTOC, Structural Formula 1) (Reaction Scheme 25)

A solution was prepared by adding TMAH (5.89 g, 31.9 mmol) and DI water (64 cm³) to a 70 cm³ vial, and then butyltin trichloride (3.0 g, 10.6 mmol) was added. A reaction solution was vigorously stirred at room temperature for 2 hours, and then an obtained product was filtered while being washed several times with DI water. After vacuum drying, a tin oxide nanocluster (BTOC, 1.9 g) in a white solid form was obtained. BTOC (lg, 0.41 mmol) and THF (24 cm³) were added to a 70 cm³ vial and dissolved. 8DPESTER (0.22 g, 0.41 mmol) was diluted with THF (6 cm³) in a 20 cm³ vial. Thereafter, the diluted 8DPESTER was slowly added dropwise to the 70 cm³ vial in which BTOC was dissolved, and then stirred at 50° C. for 40 minutes. After concentration under reduced pressure, precipitation was performed in hexane to obtain 8DPEBTOC (1.05 g, 86%).

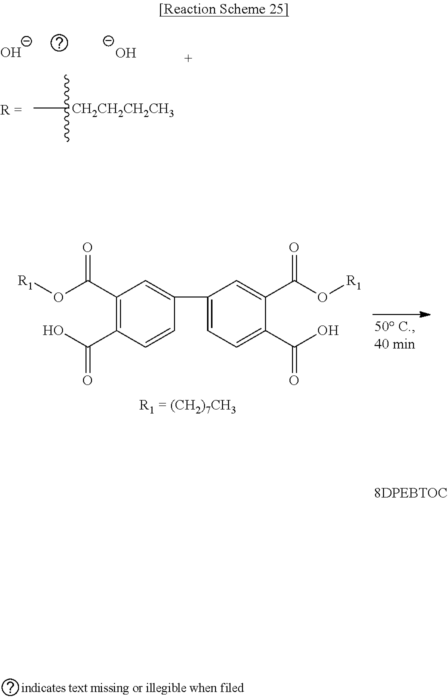

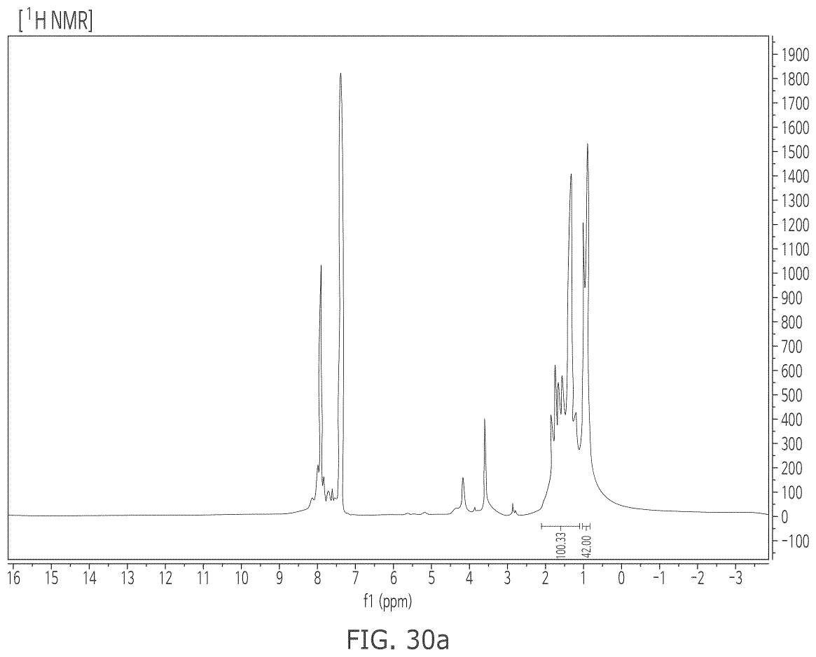

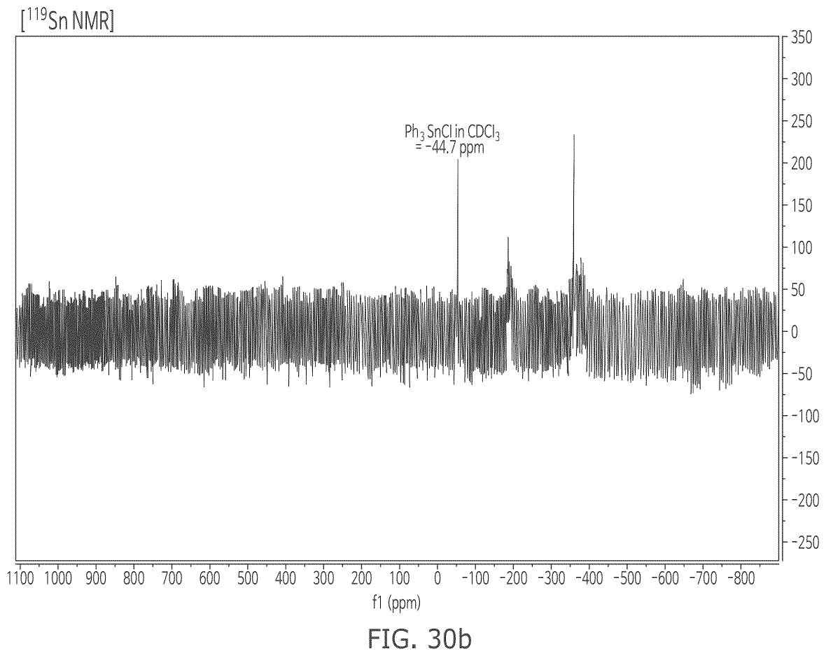

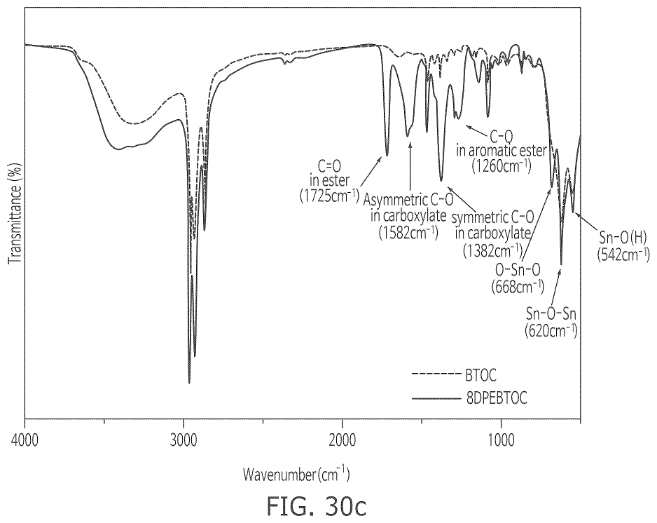

FIG. 30a illustrates a 1H-NMsR graph of 8DPEBTOC synthesized according to Experimental Example 31, FIG. 30b illustrates a 119Sn-NMVR graph, and FIG. 30c illustrates an FT-IR graph of 8DPEBTOC synthesized according to Experimental Example 31. (1H-NMR (400 MHz, CDCl3, ppm): δ=2.08-1.08 (in, 1001-1, 50xCH2), 1.02-0.82 (in, 4211, 24xCH3), 119Sn-NMR (149 MHz, CDCl3): δ=−178.00-−200.21 (in), —360.76 (s); IR [(KBr): vmax, (cm-1)]1725, 1582, 1382, 1260, 668, 620, 542)

Referring to FIGS. 30a to 30c, it can be confirmed that a tin oxide nanocluster (8DPEBTOC) including a conjugate base of 8DPESTER as a counter anion was synthesized according to Experimental Example 31.

### [Experimental Example 32] Synthesis of a Tin Oxide Nanocluster Including a Conjugate Base of 10DPESTER as a Counter Anion (10DPEBTOC, Structural Formula 1) (Reaction Scheme 26)

A solution was prepared by adding TMAH (5.89 g, 31.9 mmol) and DI water (64 cm³) to a 70 cm³ vial, and then butyltin trichloride (3.0 g, 10.6 mmol) was added. A reaction solution was vigorously stirred at room temperature for 2 hours, and then an obtained product was filtered while being washed several times with DI water. After vacuum drying, a tin oxide nanocluster (BTOC, 1.9 g) in a white solid form was obtained. BTOC (lg, 0.41 mmol) and THF (24 cm³) were added to a 70 cm³ vial and dissolved. 10DPESTER (0.25 g, 0.41 mmol) was diluted with THF (6 cm³) in a 20 cm³ vial. Thereafter, the diluted 10DPESTER was slowly added dropwise to the 70 cm³ vial in which BTOC was dissolved, and then stirred at 50° C. for 40 minutes. After concentration under reduced pressure, precipitation was performed in hexane to obtain 10DPEBTOC (0.97 g, 78%).

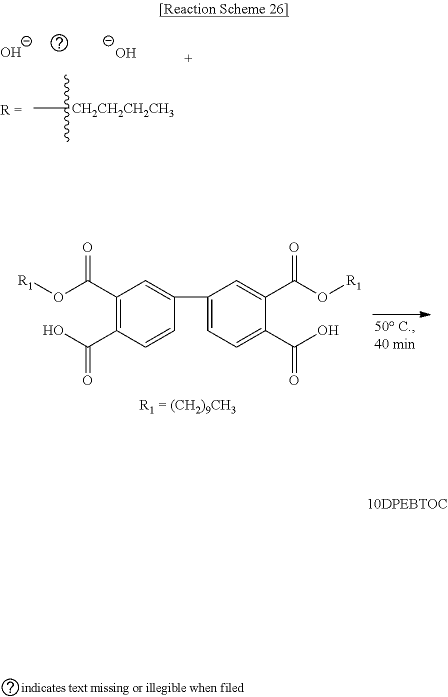

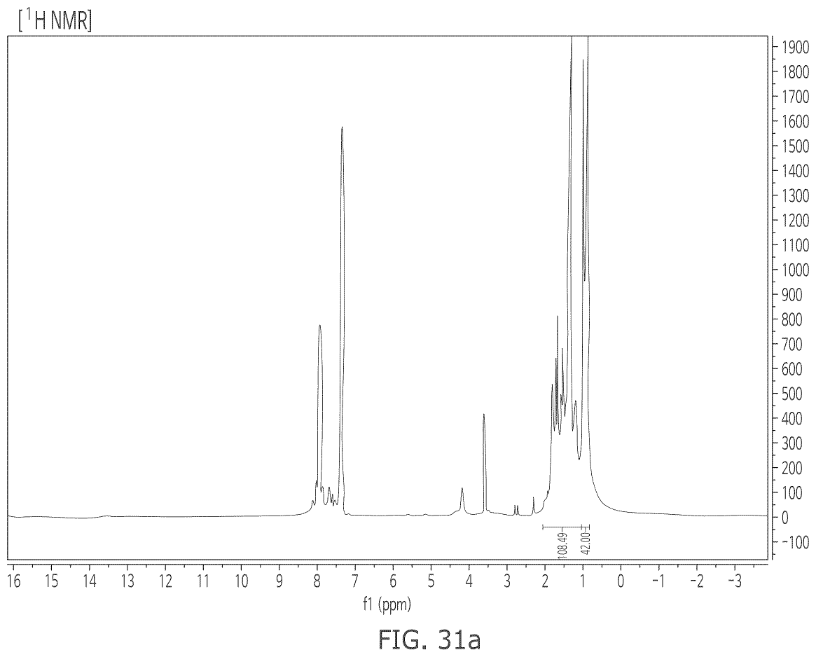

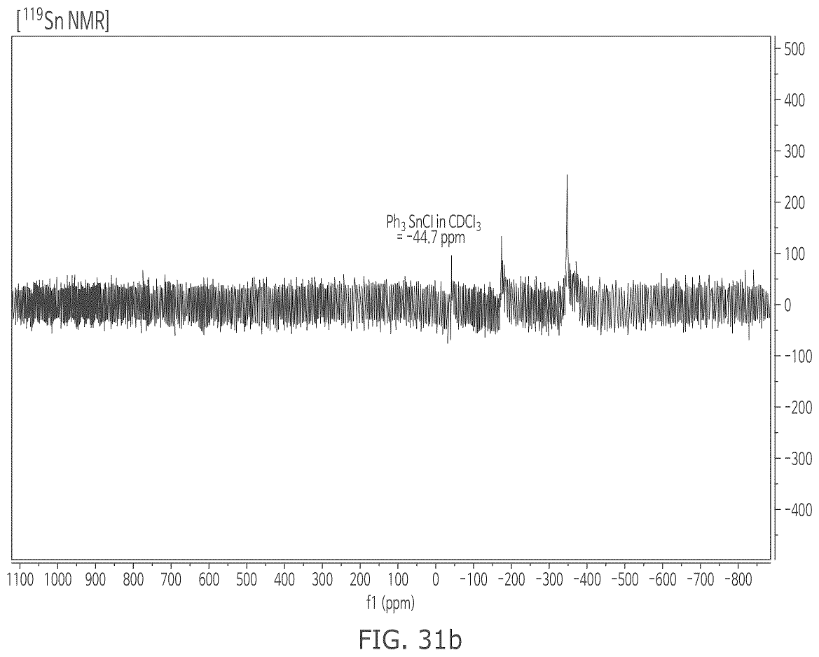

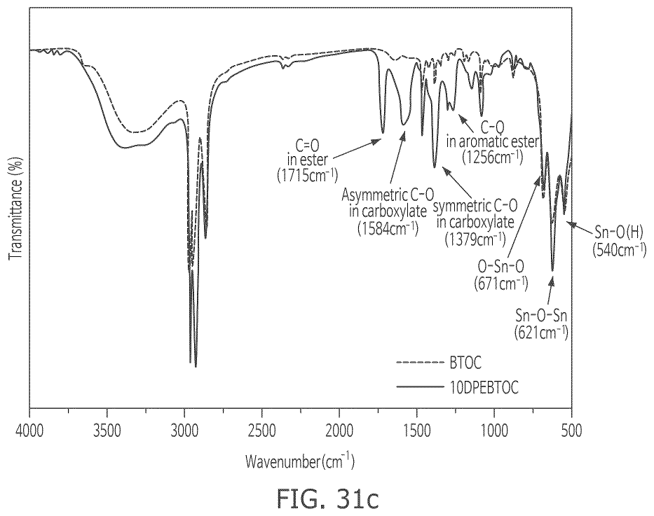

FIG. 31a illustrates a 1H-NMR graph of 10DPEBTOC synthesized according to Experimental Example 32, FIG. 31b illustrates a 119Sn-NMR graph, and FIG. 31c illustrates an FT-IR graph of 10DPEBTOC synthesized according to Experimental Example 32. (1H-NMR (400 MHz, CDCl3, ppm): δ=2.06-1.06 (m, 108H, 54xCH2), 0.93 (ddd, J=14.0, 12.9, 7.1, 42H, 24xCH3), 119Sn-NMR (149 MHz, CDCl3): δ=−169.00-−188.04 (m), —352.21 (s); IR [(KBr): vmax, (cm-1)]1715, 1584, 1379, 1256, 671, 621, 540)

Referring to FIGS. 31a to 31c, it can be confirmed that a tin oxide nanocluster (10DPEBTOC) including a conjugate base of 10DPESTER as a counter anion was synthesized according to Experimental Example 32.

### [Experimental Example 33] Synthesis of a Tin Oxide Nanocluster Including a Conjugate Base of 12DPESTER as a Counter Anion (12DPEBTOC, Structural Formula 1) (Reaction Scheme 27)

A solution was prepared by adding TMAH (5.89 g, 31.9 mmol) and DI water (64 cm³) to a 70 cm³ vial, and then butyltin trichloride (3.0 g, 10.6 mmol) was added. A reaction solution was vigorously stirred at room temperature for 2 hours, and then an obtained product was filtered while being washed several times with DI water. After vacuum drying, a tin oxide nanocluster (BTOC, 1.9 g) in a white solid form was obtained. BTOC (lg, 0.41 mmol) and THF (24 cm³) were added to a 70 cm³ vial and dissolved. 12DPESTER (0.27 g, 0.41 mmol) was diluted with THF (6 cm³) in a 20 cm³ vial. Thereafter, the diluted 12DPESTER was slowly added dropwise to the 70 cm³ vial in which BTOC was dissolved, and then stirred at 50° C. for 40 minutes. After concentration under reduced pressure, precipitation was performed in hexane to obtain 12DPEBTOC (0.52 g, 61%).

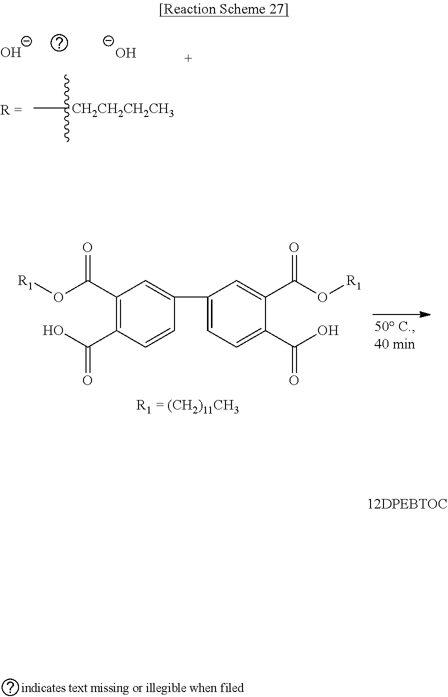

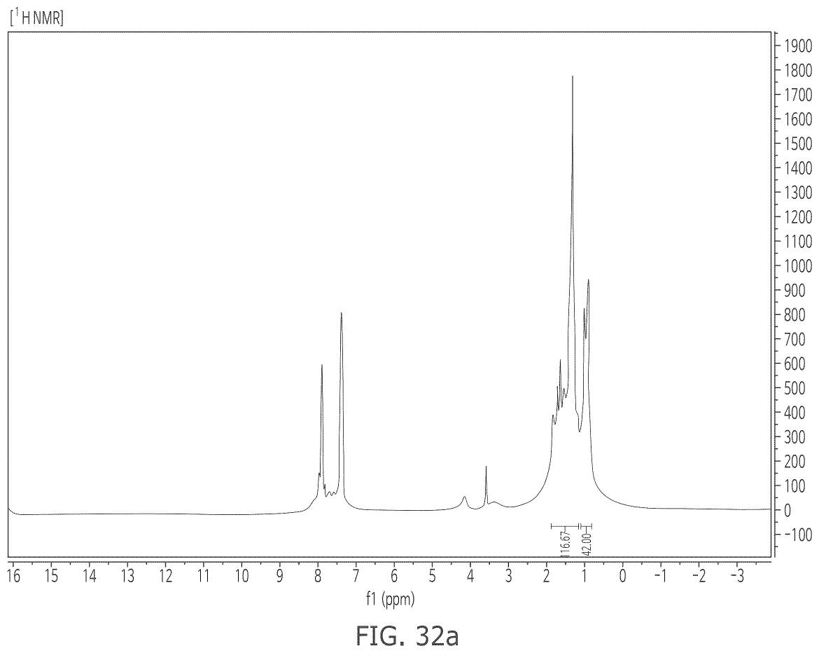

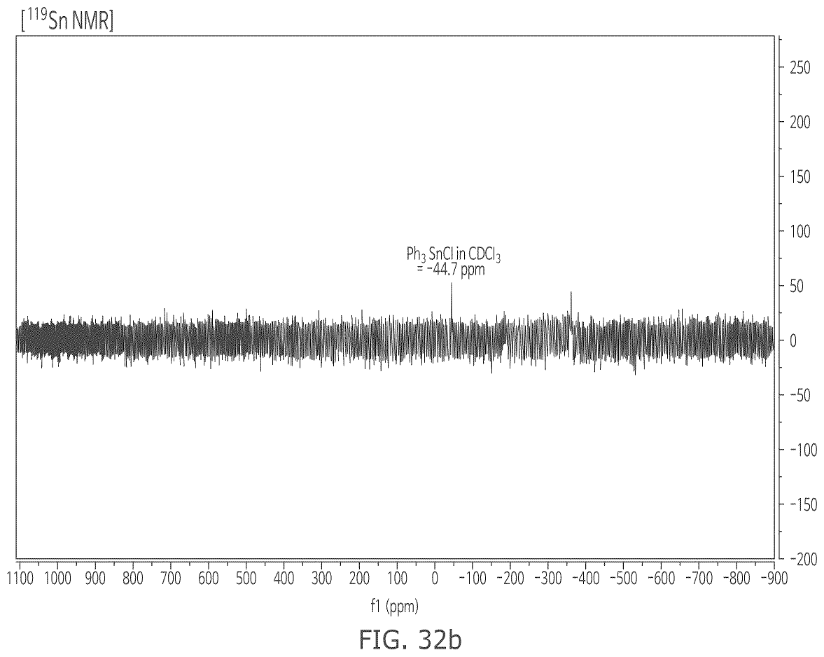

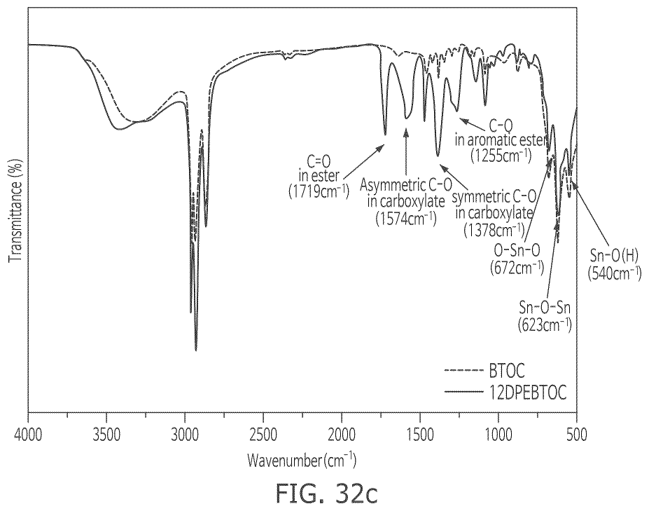

FIG. 32a illustrates a 1H-NMR graph of 12DPEBTOC synthesized according to Experimental Example 33, FIG. 32b illustrates a 119Sn-NMR graph, and FIG. 32c illustrates an FT-IR graph of 12DPEBTOC synthesized according to Experimental Example 33. (1H-NMR (400 MHz, CDCl3, ppm): δ=1.86-1.14 (m, 116H, 58xCH2), 1.08-0.81 (m, 42H, 24xCH3, 119Sn-NMR (149 MHz, CDCl3): δ=−185.60-−195.75 (m), —346.81-−367.75 (m); IR [(KBr): vmax, (cm-1)]1719, 1574, 1378, 1255, 672, 623, 540)

Referring to FIGS. 32a to 32c, it can be confirmed that a tin oxide nanocluster (12DPEBTOC) including a conjugate base of 12DPESTER as a counter anion was synthesized according to Experimental Example 33.

### [Experimental Example 34] Synthesis of a Tin Oxide Nanocluster Including a Conjugate Base of 10DPAMIDE as a Counter Anion (10DPABTOC, Structural Formula 1) (Reaction Scheme 28)

A solution was prepared by adding TMAH (5.89 g, 31.9 mmol) and DI water (64 cm³) to a 70 cm³ vial, and then butyltin trichloride (3.0 g, 10.6 mmol) was added. A reaction solution was vigorously stirred at room temperature for 2 hours, and then an obtained product was filtered while being washed several times with DI water. After vacuum drying, a tin oxide nanocluster (BTOC, 1.9 g) in a white solid form was obtained. BTOC (lg, 0.41 mmol) and THF (24 cm³) were added to a 70 cm³ vial and dissolved. 10DPAMIDE (0.25 g, 0.41 mmol) was diluted with THF (6 cm³) in a 20 cm³ vial. Thereafter, the diluted 10DPAMIDE was slowly added dropwise to the 70 cm³ vial in which BTOC was dissolved, and then stirred at 50° C. for 40 minutes. After concentration under reduced pressure, precipitation was performed in hexane to obtain 10DPABTOC (0.97 g, 78%).

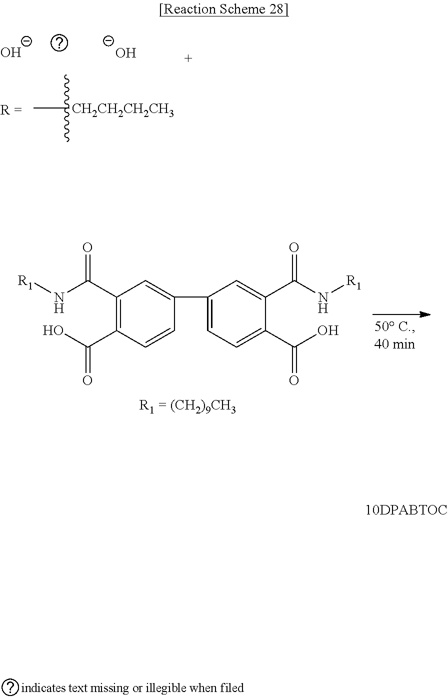

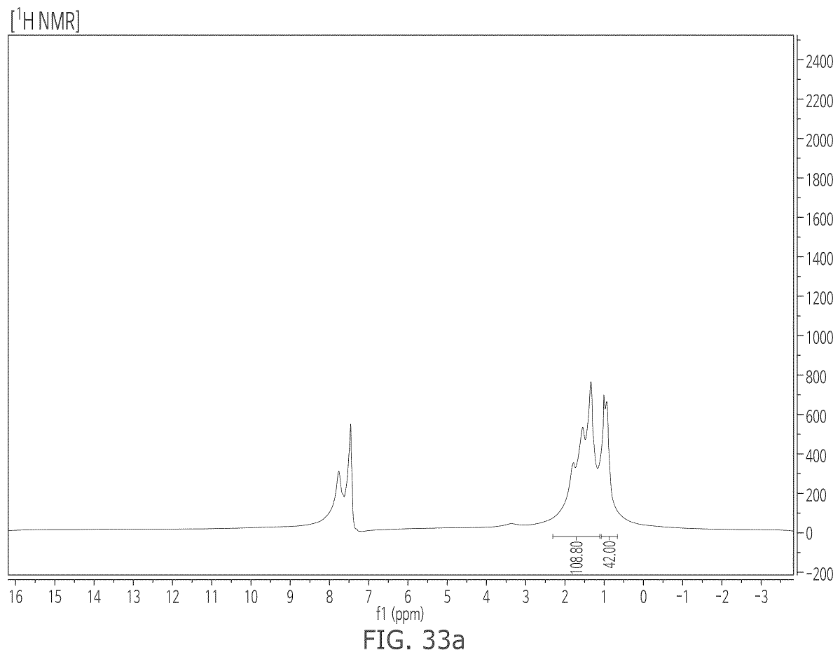

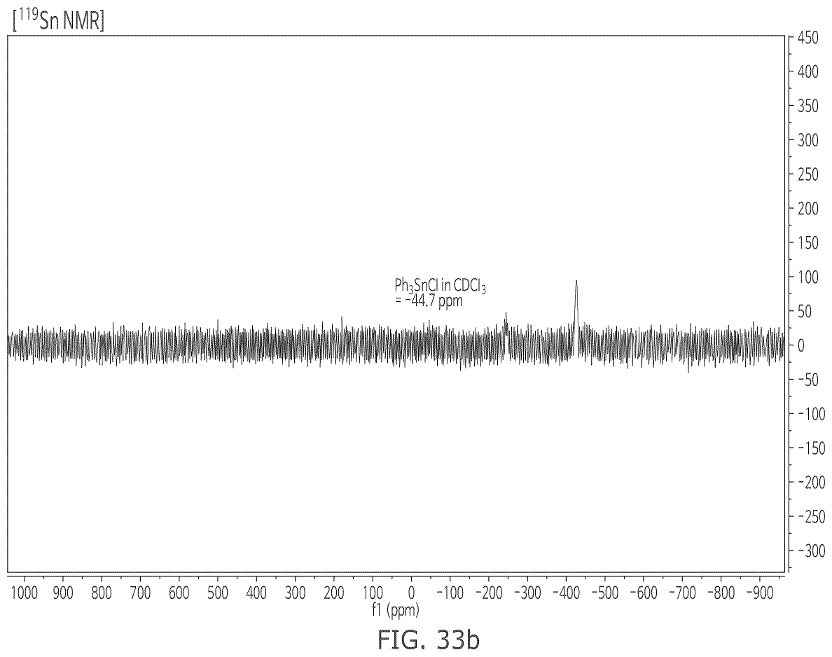

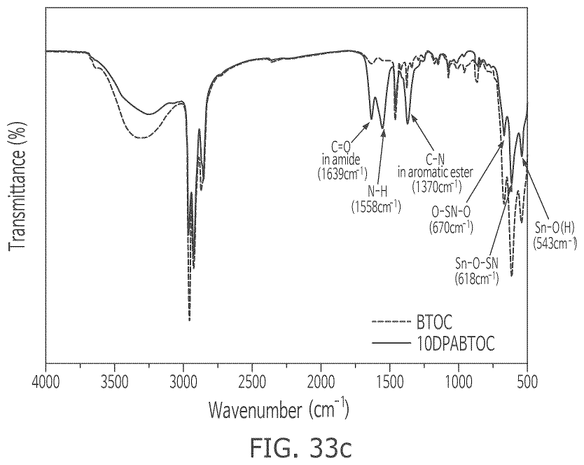

FIG. 33a illustrates a 1H-NMR graph of 10DPABTOC synthesized according to Experimental Example 34, FIG. 33b illustrates a 119Sn-NMR graph, and FIG. 33c illustrates an FT-IR graph of 10DPABTOC synthesized according to Experimental Example 34. (1H-NMR (400 MHz, CDCl3): δ=1.44 (dd, J=180.4, 91.3 Hz, 108H, 54xCH2), 0.96 (m, 42H, 14xCH3), 119Sn-NMR (149 MHz, CDCl3): δ=−240.80-−247.78 (m), —416.61-−433.74 (m) IR [(KBr): vmax, (cm-1)]1639, 1558, 1370, 670, 618, 543)

Referring to FIGS. 33a to 33c, it can be confirmed that a tin oxide nanocluster (10DPABTOC) including a conjugate base of 10DPAMIDE as a counter anion was synthesized according to Experimental Example 34.

### [Experimental Example 35] Synthesis of a Tin Oxide Nanocluster Including a Conjugate Base of Saccharin as a Counter Anion (SBTOC, Structural Formula 1) (Reaction Scheme 29)

A solution was prepared by adding TMAH (5.89 g, 31.9 mmol) and DI water (64 cm³) to a 70 cm³ vial, and then butyltin trichloride (3.0 g, 10.6 mmol) was added. A reaction solution was vigorously stirred at room temperature for 2 hours, and then an obtained product was filtered while being washed several times with DI water. After vacuum drying, a tin oxide nanocluster (BTOC, 1.9 g) in a white solid form was obtained. BTOC (lg, 0.81 mmol) and THF (4 cm³) were added to a 20 cm³ vial and dissolved. Saccharin (0.15 g, 0.41 mmol) was diluted with THF (6 cm³) in a 20 cm³ vial. Thereafter, the diluted saccharin was slowly added dropwise to the 20 cm³ vial in which BTOC was dissolved, and then stirred at 50° C. for 40 minutes. After concentration under reduced pressure, precipitation was performed in hexane to obtain SBTOC (0.67 g).

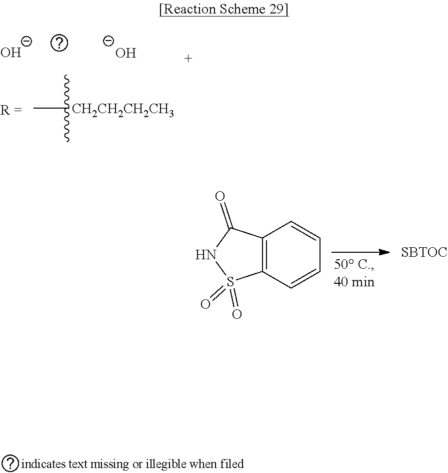

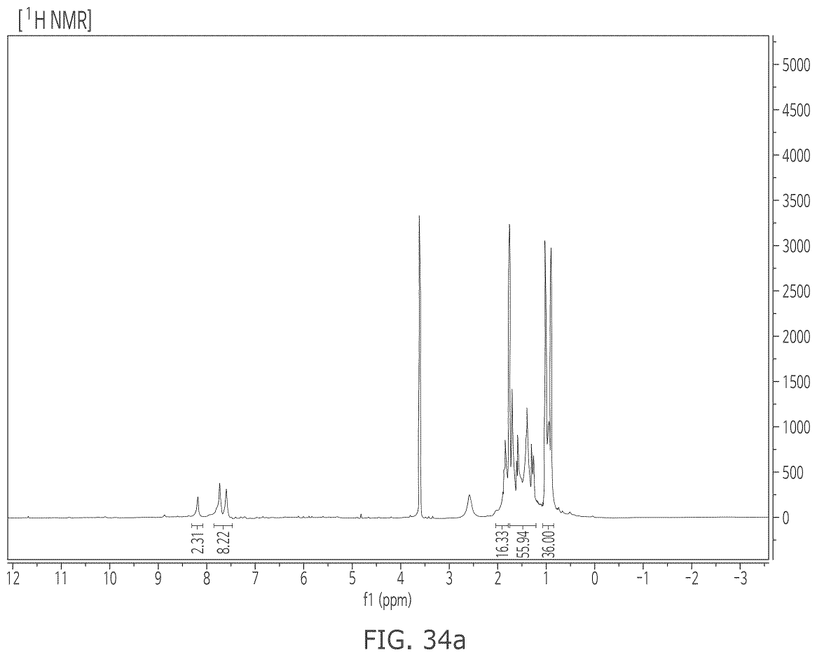

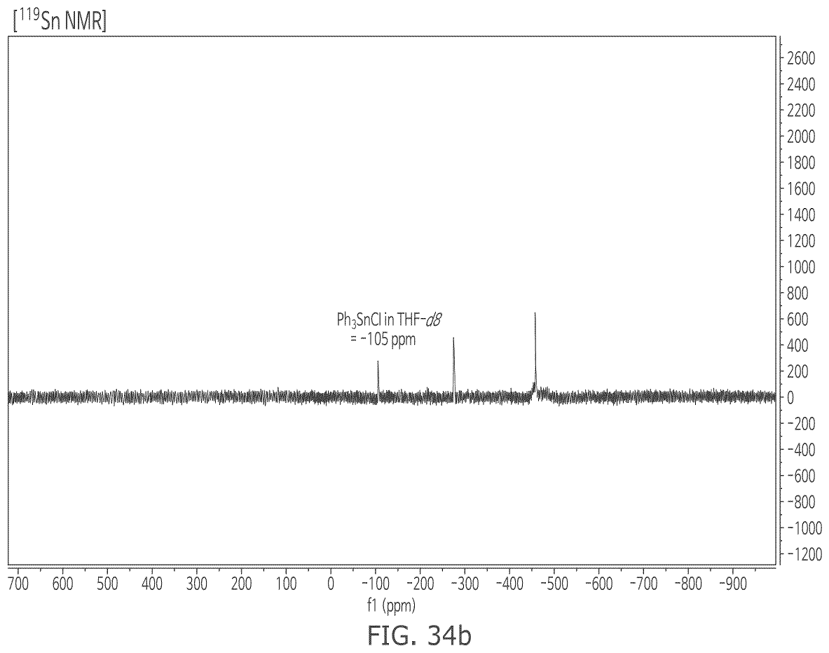

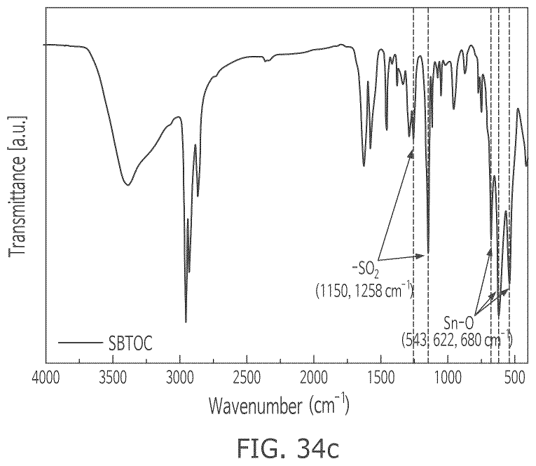

FIG. 34a illustrates a 1H-NMR graph of SBTOC synthesized according to Experimental Example 35, FIG. 34b illustrates a 119Sn-NMR graph, and FIG. 34c illustrates an FT-IR graph of SBTOC synthesized according to Experimental Example 35. (1H-NMR (400 MHz, THF-d8): δ=8.20 (S, 2H, 2xNH), 7.80-7.69 (m, 4H, 4xAr-H), 7.68-7.54 (m, 4H, 4xAr-H), 2.02-1.21 (72H, 36xCH2) 1.09-0.79 (m, 36H, 12xCH3), 119Sn-NMR (149 MHz, THF-d8 in Ph3SnCl): δ=−274.9, −457.1, IR [(KBr): vmax, (cm-1)]1258, 1150, 680, 622, 543)

Referring to FIGS. 34a to 34c, it can be confirmed that a tin oxide nanocluster (SBTOC) including a conjugate base of saccharin as a counter anion was synthesized according to Experimental Example 35.

### [Experimental Example 36] Evaluation of 254 nm Ultraviolet Lithography for 8PEBTOC (Experimental Example 27), 10PEBTOC (Experimental Example 28), 12PEBTOC (Experimental Example 29), and 10PABTOC (Experimental Example 30)

8PEBTOC, 10PEBTOC, 12PEBTOC, and 10PABTOC were dissolved in a cyclohexanone solvent to prepare resist composition solutions with concentrations of 5 wt/vol %, 5.5 wt/vol %, 4 wt/vol %, and 4.5 wt/vol %, respectively. A solution (20 wt %) in which hexamethyldisilazane (HMDS) was dissolved in propylene glycol methyl ether acetate (PGMEA_was spin-coated on a Si wafer at 3000 rpm for 30 seconds, and then a substrate was heated at 110° C. for 1 minute. The resist composition solution was spin-coated on the substrate treated with HMDS at 1000 rpm for 60 seconds, and then heated at 80° C. for 1 minute to form a thin film with an approximate thickness of 100 nm. Thereafter, irradiation was performed with an exposure dose of 25 to 300 mJ/cm² using a 254 nm ultraviolet exposure machine, a development process was performed for 60 seconds using a 2.38% TMAH standard aqueous solution, and washed with DI water for 10 seconds to confirm formation of a positive pattern. Thereafter, thickness was measured using an Alpha-step® D-300 stylus profiler manufactured by Kla-Tencor to evaluate solubility characteristics.

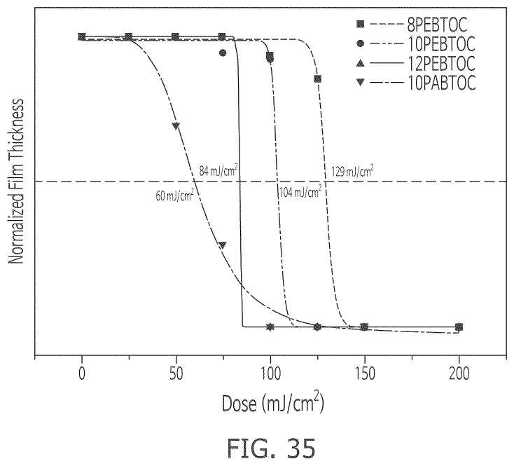

FIG. 35 illustrates solubility characteristics of 8PEBTOC, 10PEBTOC, 12PEBTOC, and 10PABTOC obtained by performing 254 nm ultraviolet lithography (deep ultraviolet) according to Experimental Example 36.

Referring to FIG. 35, it can be confirmed that when ultraviolet of 129 mJ/cm², 104 mJ/cm², 84 mJ/cm², and 60 mJ/cm² is irradiated onto a resist thin film with a thickness of 100 nm formed according to Experimental Example 9, about 50% of the resist thin film thickness can be maintained. In addition, when the ultraviolet irradiation dose is low, solubility of the resist thin film in a basic developer (TMAH) does not increase, and when the ultraviolet irradiation dose increases above a certain amount, solubility of the resist thin film in the basic developer (TMAH) increases.

### [Experimental Example 37] Evaluation of 254 nm Ultraviolet Lithography for 8DPEBTOC (Experimental Example 31), 10DPEBTOC (Experimental Example 32), and 12DPEBTOC (Experimental Example 33)

8DPEBTOC, 10DPEBTOC, and 12DPEBTOC were dissolved in a cyclohexanone solvent to prepare resist composition solutions with a concentration of 5 wt/vol %. A solution (20 wt %) in which hexamethyldisilazane (HMDS) was dissolved in PGMEA was spin-coated on a Si wafer at 3000 rpm for 30 seconds, and then a substrate was heated at 110 degrees (Celsius) for 1 minute. The resist composition solution was spin-coated on the substrate treated with HMDS at 1000 rpm for 60 seconds, and then heated at 80 degrees (Celsius) for 1 minute to form a thin film with an approximate thickness of 100 nm. Thereafter, irradiation was performed with an exposure dose of 25 to 200 mJ/cm² using a 254 nm ultraviolet exposure machine, a development process was performed for 60 seconds using a 2.38% TMAH standard aqueous solution, and washed with DI water for 10 seconds to confirm formation of a positive pattern. Thereafter, thickness was measured using an Alpha-step® D-300 stylus profiler manufactured by Kla-Tencor to evaluate solubility characteristics.

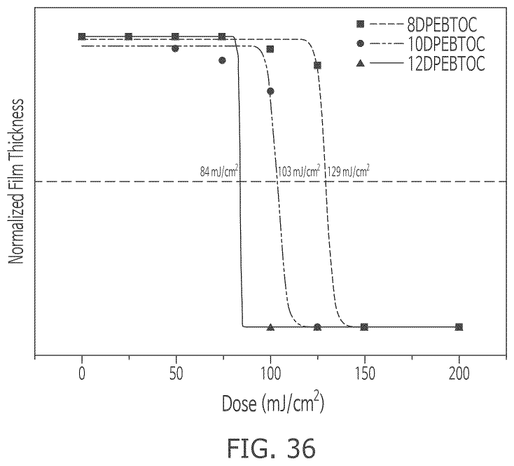

FIG. 36 illustrates solubility characteristics of 8DPEBTOC, 10DPEBTOC, and 12DPEBTOC obtained by performing 254 nm ultraviolet lithography (deep ultraviolet) according to Experimental Example 37.

Referring to FIG. 36, it can be confirmed that when ultraviolet of 129 mJ/cm², 103 mJ/cm², and 84 mJ/cm² is irradiated onto a resist thin film with a thickness of 100 nm formed according to Experimental Example 9, about 50% of the resist thin film thickness can be maintained. In addition, when the ultraviolet irradiation dose is low, solubility of the resist thin film in a basic developer (TMAH) does not increase, and when the ultraviolet irradiation dose increases above a certain amount, solubility of the resist thin film in the basic developer (TMAH) increases. In addition, as the number of carbon atoms in an alkyl group included in a counter anion increases, sensitivity of the resist thin film improves.

### [Experimental Example 38] Electron Beam Lithography of 10PEBTOC (Experimental Example 28), 12PEBTOC (Experimental Example 29), 10PABTOC (Experimental Example 30), and 10DPEBTOC (Experimental Example 32)

10PEBTOC, 12PEBTOC, 10PABTOC, and 10DPEBTOC were dissolved in a cyclohexanone solvent to prepare resist composition solutions with concentrations of 5 wt/vol %, 4 wt/vol %, 5 wt/vol %, and 6 wt/vol %, respectively. A solution (20 wt %) in which hexamethyldisilazane (HMDS) was dissolved in PGMEA was spin-coated on a Si wafer at 3000 rpm for 30 seconds, and then a substrate was heated at 110° C. for 1 minute. The resist composition solution was spin-coated on the substrate treated with HMDS at 1000 rpm for 60 seconds, and then heated at 80° C. for 1 minute to form a thin film with an approximate thickness of 100 nm. An electron beam of 100 to 1,300 μC/cm² was irradiated onto the resist composition thin film under an acceleration voltage of 80 keV. A development process was performed for 60 seconds using a 2.38% TMAH standard aqueous solution, and washed with DI water for 10 seconds to fabricate a positive resist pattern.

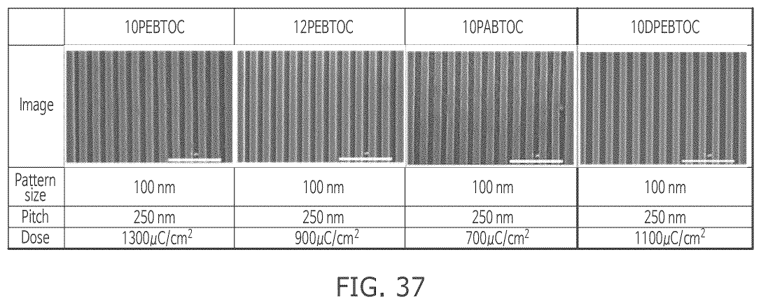

FIG. 37 illustrates positive patterns of 10PEBTOC, 12PEBTOC, 10PABTOC, and 10DPEBTOC observed through a scanning electron microscope after performing electron beam lithography according to Experimental Example 38.

Referring to FIG. 37, after patterning resist patterns by irradiating electron beams of 1300 μC/cm², 900 μC/cm², 700 μC/cm², and 1100 μC/cm² onto 10PEBTOC, 12PEBTOC, 10PABTOC, and 10DPEBTOC resist thin films formed according to Experimental Example 38, respectively, a development process was performed using a basic developer (TMAH), and as a result, positive resist patterns of 100 nm were formed.

Comparing experimental results of a 10PEBTOC resist thin film and a 12PEBTOC resist thin film, as the number of carbon atoms in an alkyl group included in a counter anion increases, sensitivity of the resist thin film improves. Comparing experimental results of the 10PEBTOC resist thin film and a 10PABTOC resist thin film, a 10PABTOC resist thin film including an amide group as a functional group functioning as a Lewis base has improved sensitivity compared to the 10PEBTOC resist thin film including an ester group as a functional group functioning as a Lewis base. Through this, it can be confirmed that as a functional group included in a counter anion corresponds to a stronger Lewis base, sensitivity of a resist thin film improves.

Referring to FIGS. 35 to 37, it can be confirmed that positive resist patterns are formed using resist compositions of 8PEBTOC, 10PEBTOC, 12PEBTOC, 10PABTOC, 8DPEBTOC, 10DPEBTOC, and 12DPEBTOC. As ultraviolet or an electron beam is irradiated onto a resist thin film formed of the resist composition, an organic ligand (butyl group) of a tin oxide nanocluster (8PEBTOC, 10PEBTOC, 12PEBTOC, 10PABTOC, 8DPEBTOC, 10DPEBTOC, 12DPEBTOC) may be detached in an exposed region of the resist thin film, and accordingly, a core structure of the tin oxide nanocluster may have Lewis acidity. In the exposed region of the resist thin film, a functional group functioning as a Lewis base of a counter anion bonded to the core structure of the tin oxide nanocluster may bond to a tin atom that has lost the organic ligand. Accordingly, solubility of an exposed region of the resist thin film in a basic developer (TMAH) may be adjusted and/or controlled, and a dissolution contrast between the exposed region and an unexposed region of the resist thin film may be increased. Thereafter, the exposed region of the resist thin film may be selectively removed by a development process using the basic developer (TMAH), and accordingly, a positive resist pattern may be formed.

### [Experimental Example 39] Evaluation of 254 nm Ultraviolet Lithography of SBTOC (Experimental Example 35)

A solution of HMDS (20 wt/vol %) dissolved in PGMEA was spin-coated on a Si substrate at 3,000 rpm for 30 seconds, and then heated at 110° C. for 1 minute. Thereafter, a SBTOC solution (2.0 wt/vol %) dissolved in 2-butanone (MEK) was spin-coated at 2,000 rpm for 60 seconds, and then heated at 80° C. for 1 minute to form a thin film (approximate thickness of 100 nm). Thereafter, KrF of 400 mJ/cm² was irradiated using a KrF exposure machine, and then a development process was performed for 60 seconds using a 2.38% TMAH standard aqueous solution to form a positive tone pattern.

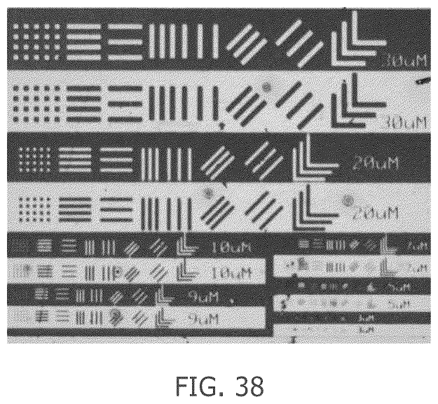

FIG. 38 illustrates a positive pattern confirmed by performing 254 nm ultraviolet lithography (deep ultraviolet) of SBTOC according to Experimental Example 39 using a 2.38% TMAH standard aqueous solution as a developer.

Referring to FIG. 38, as ultraviolet is irradiated onto a resist thin film formed of a SBTOC resist composition, an organic ligand (butyl group) of a tin oxide nanocluster (SBTOC) may be detached in an exposed region of the resist thin film, and accordingly, a core structure of the tin oxide nanocluster may have Lewis acidity. In the exposed region of the resist thin film, a functional group functioning as a Lewis base of a counter anion bonded to the core structure of the tin oxide nanocluster may bond to a tin atom that has lost the organic ligand. Accordingly, solubility of an exposed region of the resist thin film in a basic developer (TMAH) may be adjusted and/or controlled, and a dissolution contrast between the exposed region and an unexposed region of the resist thin film may be increased. Thereafter, the exposed region of the resist thin film may be selectively removed by a development process using the basic developer (TMAH), and accordingly, a positive resist pattern may be formed.

### [Experimental Example 40] Evaluation of 254 nm Ultraviolet Lithography of 12FDEBTOC (Experimental Example 7)

A 12FDEBTOC solution (3.0 wt/vol %) dissolved in Cyclohexanone was spin-coated on a Si substrate at 2,000 rpm for 60 seconds, and then heated at 100° C. for 1 minute to form a thin film (approximate thickness of 60 nm). Thereafter, KrF of 2.4 J/cm² was irradiated using a KrF exposure machine, and then post exposure bake (PEB) was performed at 140° C. for 1 minute. A development process was performed for 30 seconds using Cyclohexanone to form a negative pattern.

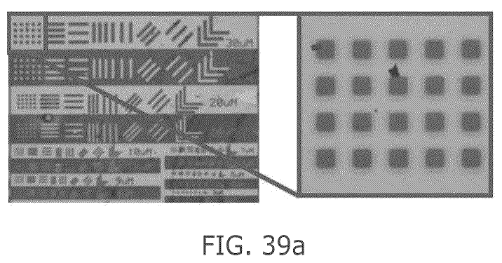

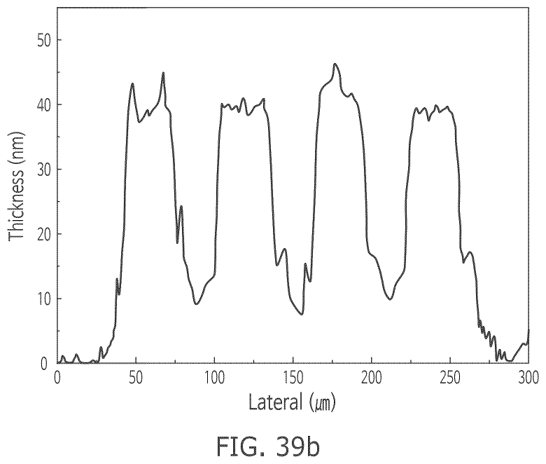

FIGS. 39a and 39b illustrate negative patterns confirmed by performing 254 nm ultraviolet lithography (deep ultraviolet) of 12FDEBTOC according to Experimental Example 40 using cyclohexanone, an organic solvent, as a developer.

Referring to FIGS. 39a and 39b, it can be confirmed that a negative resist pattern is formed using a 12FDEBTOC resist composition. As ultraviolet is irradiated onto a resist thin film formed of the resist composition, an organic ligand (butyl group) of a tin oxide nanocluster (SBTOC) may be detached in an exposed region of the resist thin film, and accordingly, a core structure of the tin oxide nanocluster may have Lewis acidity. In the exposed region of the resist thin film, an aggregation reaction between core structures of the tin oxide nanocluster having Lewis acidity proceeds, and accordingly, solubility of the exposed region of the resist thin film in an organic developer (cyclohexanone) may be adjusted and/or controlled. For example, solubility in the organic developer may be reduced. Thereafter, an unexposed region of the resist thin film may be selectively removed by a development process using the organic developer, and accordingly, a negative resist pattern may be formed.

A method for manufacturing a semiconductor device using a resist composition according to embodiments of the present disclosure is described.

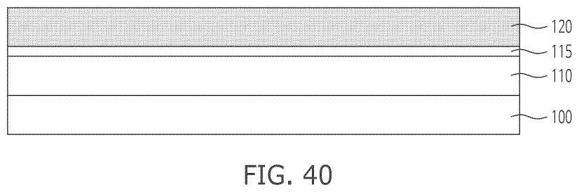

FIGS. 40 to 43 illustrate a method for manufacturing a semiconductor device using a resist composition according to embodiments of the present disclosure.

Referring to FIG. 40, a method for manufacturing a semiconductor device may include forming an etch target film 110 on a substrate 100, and forming a photoresist film 120 on the etch target film 110. In at least one embodiment, an underlayer 115 may be disposed between the etch target film 110 and the photoresist film 120. The substrate 100 may be a semiconductor substrate, for example, a silicon substrate, a germanium substrate, or a silicon/germanium substrate. As another example, the substrate 100 may be a metal substrate such as Cr or Ta. The etch target film 110 may be formed of any one selected from a semiconductor material, a conductive material, and an insulating material, or a combination thereof. The etch target film 110 may be formed as a single film or may include a plurality of films stacked on the substrate 100.

An underlayer 115 may be formed between an etch target film 110 and a photoresist film 120, and may be selected to fix the photoresist film 120 onto the etch target film 110. The underlayer 115 may include, for example, hexamethyldisilazane (HMIDS), a silane compound having a vinyl group (for example, vinyldisilazane, vinylchlorosilane, vinyloxysilane, etc.), a polymer having a vinyl group, or an organometallic oxide. According to some embodiments, the underlayer 115 may be omitted.

A photoresist film 120 may include a resist composition according to embodiments of the present disclosure. The resist composition may include a tin oxide nanocluster, and the tin oxide nanocluster may include a core structure including tin oxide, a counter anion bonded to the core structure, and an organic ligand bonded to the core structure. The tin oxide nanocluster may be represented by Chemical Formula 1. The tin oxide nanocluster represented by Chemical Formula 1 may include a material represented by Structural Formula 1. A counter anion bonded to a core structure may include a functional group functioning as a Lewis base. The counter anion bonded to the core structure may correspond to a conjugate base of an organic acid. The counter anion may include, for example, at least one selected from the group consisting of conjugate bases of organic acids having chemical structures of Structural Formulas 2 to 10.

Forming a photoresist film 120 may include applying a resist composition on an underlayer 115 or an etch target film 110. Applying the resist composition on the underlayer 115 or the etch target film 110 may be performed, for example, by a spin coating method. Forming the photoresist film 120 may further include performing a heat treatment process (for example, a soft baking process) on the applied resist composition.

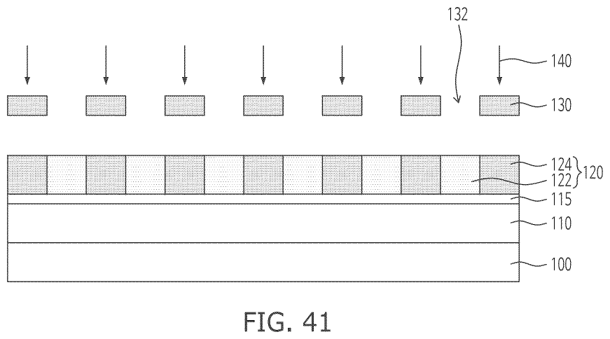

Referring to FIG. 41, a method for manufacturing a semiconductor device may include performing an exposure process on a photoresist film 120 after forming the photoresist film 120. The exposure process may include irradiating light 140 onto the photoresist film 120. For example, the exposure process may include aligning a photomask 130 on the photoresist film 120, and irradiating the light 140 onto the photoresist film 120 through the photomask 130. The light 140 may be, for example, ultraviolet. Here, the ultraviolet may be extreme ultraviolet or deep ultraviolet. As another example, the exposure process may include irradiating and scanning the light 140 onto the photoresist film 120 using an electron beam lithography apparatus. The light 140 may be, for example, an electron beam. The photoresist film 120 may include an exposed region 122 exposed to the light 140, and an unexposed region 124 not exposed to the light 140. For example, the light 140 may be irradiated to the exposed region 122 through an opening 132 of the photomask 130, and may be blocked by the photomask 130 so as not to be irradiated to the unexposed region 124.

In an exposed region 122 of a photoresist film 120, an organic ligand (R) may be detached from a tin oxide nanocluster represented by Chemical Formula 1 by photons of light 140. For example, the organic ligand may be detached from a core structure of the tin oxide nanocluster represented by Chemical Formula 1 by an electron beam or ultraviolet photons, and accordingly, the core structure of the tin oxide nanocluster may have Lewis acidity. A counter anion bonded to a core structure of a tin oxide nanocluster has a functional group functioning as a Lewis base, and the functional group functioning as a Lewis base may be bonded to a tin atom that has lost the organic ligand (R) through acid-base interaction. Accordingly, the exposed region 122 of the photoresist film 120 may have a structure in which the organic ligand (R) of the tin oxide nanocluster is substituted with the functional group of the counter anion. An unexposed region 124 of the photoresist film 120 may include a core structure including tin oxide, a counter anion bonded to the core structure, and an organic ligand (R) bonded to the core structure. As the organic ligand (R) of the tin oxide nanocluster is substituted with the functional group functioning as a Lewis base in the exposed region 122 of the photoresist film 120, solubility of the exposed region 122 of the photoresist film 120 in a developer may be adjusted and/or controlled, and a dissolution contrast between the exposed region 122 and the unexposed region 124 of the photoresist film 120 may be increased.

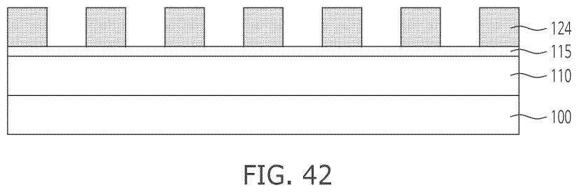

Referring to FIG. 42, after an exposure process, a photomask 130 may be removed. A development process may be performed on an exposed photoresist film 120. Performing the development process may include removing an exposed region 122 of the photoresist film 120 using a basic developer. The basic developer may include, for example, TMAH (Tetramethyl ammonium hydroxide), but is not limited thereto, and any basic developer used in the art may be possible. By the development process, the exposed region 122 of the photoresist film 120 may be selectively removed. An unexposed region 124 of the photoresist film 120 may be referred to as a photoresist pattern, and the photoresist pattern may be a positive tone pattern. In FIG. 42, a photoresist film 120 according to at least one embodiment of the present disclosure is illustrated as a positive photoresist, but is not limited thereto. For example, performing the development process may include removing an unexposed region of the photoresist film using an organic developer. The organic developer may include, for example, cyclohexanone, but is not limited thereto, and any organic developer used in the art may be possible. By the development process, the unexposed region of the photoresist film may be selectively removed. The unremoved exposed region of the photoresist film may be referred to as a photoresist pattern, and the photoresist pattern may be a negative tone pattern.

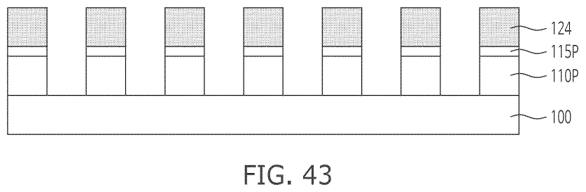

Referring to FIG. 43, an underlayer 115 and an etch target film 110 may be etched using a photoresist pattern as an etch mask. Etching the underlayer 115 and the etch target film 110 may include, for example, performing a wet or dry etch process. The underlayer 115 and the etch target film 110 may be etched to form an underlayer pattern 115P and a lower pattern 110P, respectively. After the lower pattern 110P is formed, the photoresist pattern may be removed. The lower pattern 110P may be a semiconductor pattern, a conductive pattern, or an insulating pattern in a semiconductor device.

A multilayer structure formed using a resist composition according to embodiments of the present disclosure is described.

Referring again to FIG. 40, a multilayer structure may include an etch target film 110 on a substrate 100, and a photoresist film 120 on the etch target film 110. According to some embodiments, an underlayer 115 may be interposed between the etch target film 110 and the photoresist film 120.

A photoresist film 120 may include a resist composition according to embodiments of the present disclosure. The resist composition may include a tin oxide nanocluster, and the tin oxide nanocluster may include a core structure including tin oxide, a counter anion bonded to the core structure, and an organic ligand bonded to the core structure.

Referring again to FIG. 41, a photoresist film 120 may include an exposed region 122 exposed to light 140, and an unexposed region 124 not exposed to the light 140. The exposed region 122 of the photoresist film 120 may have a structure in which an organic ligand (R) of a tin oxide nanocluster represented by Chemical Formula 1 is substituted with a functional group functioning as a Lewis base. An unexposed region 124 of the photoresist film 120 may include a core structure including tin oxide, a counter anion bonded to the core structure, and an organic ligand (R) bonded to the core structure.

The above description of embodiments of the present invention provides examples for explanation of the present invention. Therefore, the present invention is not limited to the above embodiments, and it is apparent that many modifications and changes are possible, such as implementing by combining the above embodiments, by one of ordinary skill in the art within the technical spirit of the present invention.

What is claimed is:

1. A resist composition comprising:
a tin oxide nanocluster, the tin oxide nanocluster comprising
a core structure comprising tin oxide,
a counter anion bonded to the core structure, and
an organic ligand bonded to the core structure,
wherein the counter anion comprises a functional group functioning as a Lewis base.

2. The resist composition as claimed in claim 1, wherein the tin oxide nanocluster is represented by Chemical Formula 1 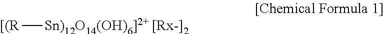
wherein in the Chemical Formula 1, R is the organic ligand, and Rx⁻ is the counter anion.

3. The resist composition as claimed in claim 1, wherein the functional group has a non-shared electron pair.

4. The resist composition as claimed in claim 1, wherein the functional group comprises a hydroxyl group, a phenol group, a thiol group, an amine group, a carboxylic acid group, an ester group, a carbonyl group, an amide group, a carbamate group, a urea group, a sulfoxy group, a sulfonyl group, a sulfone ester group, a cyanide group, an isocyanide group, or a combination thereof.

5. The resist composition as claimed in claim 1, wherein the counter anion comprises a carboxylate anion, a sulfonate anion, a sulfonamidate anion, or a combination thereof.

6. The resist composition as claimed in claim 1, wherein the counter anion comprises a conjugate base of an organic acid having a chemical structure of at least one of Structural Formulas 2 to 4: 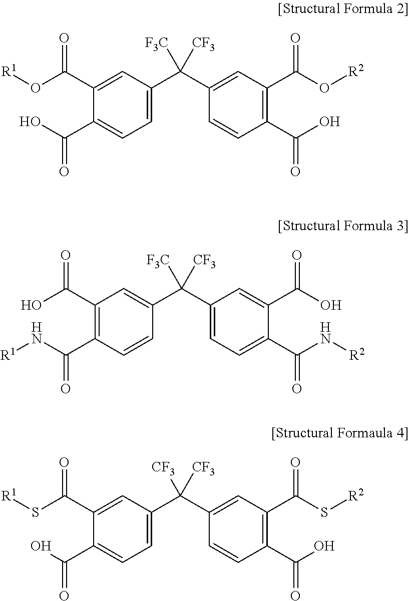
wherein, in the Structural Formulas 2 to 4, R¹ and R² are alkyl groups having 6 to 18 carbon atoms.

7. The resist composition as claimed in claim 1, wherein the counter anion comprises at least one conjugate base of at least one organic acid having a chemical structure of at least one of Structural Formulas 5 to 7: 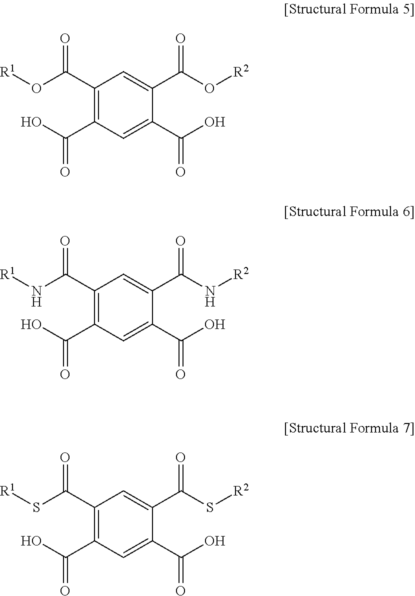
wherein in the Structural Formulas 5 to 7, R¹ and R² are alkyl groups having 6 to 18 carbon atoms.

8. The resist composition as claimed in claim 1, wherein the counter anion comprises a conjugate base of an organic acid having a chemical structure of at least one of Structural Formulas 8 to 10: 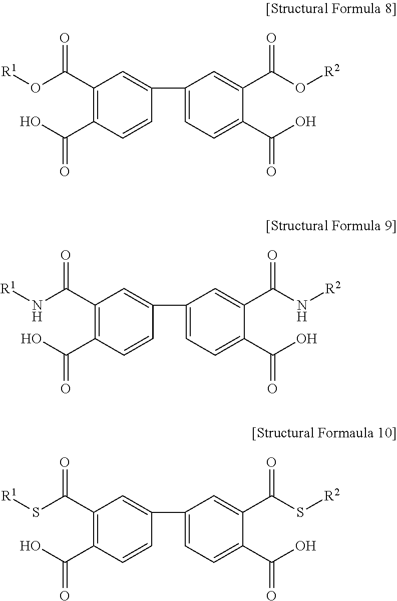
wherein in the Structural Formulas 8 to 10, R¹ and R² are alkyl groups having 6 to 18 carbon atoms.

9. The resist composition as claimed in claim 1, wherein the counter anion comprises a conjugate base of an organic acid having a chemical structure of Structural Formula 11:

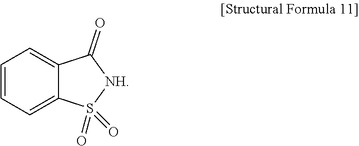 [SMILES: O=C1NS(=O)(=O)c2ccccc21]

10. The resist composition as claimed in claim 1, wherein the organic ligand is an alkyl group having 1 to 20 carbon atoms bonded to a tin element included in the core structure.

11. A method for manufacturing a semiconductor device, comprising:
forming an etch target film on a substrate;
forming a photoresist film on the etch target film;
performing an exposure process on the photoresist film; and
performing a development process to selectively remove an exposed region or an unexposed region of the photoresist film,
wherein the photoresist film comprises a resist composition comprising a tin oxide nanocluster, and the tin oxide nanocluster comprises
a core structure comprising tin oxide,
a counter anion bonded to the core structure, and
an organic ligand bonded to the core structure, and
wherein the counter anion comprises a functional group functioning as a Lewis base.

12. The method for manufacturing the semiconductor device as claimed in claim 11, wherein the performing the exposure process on the photoresist film includes forming the exposed region exposed by the exposure process, and forming the unexposed region not exposed by the exposure process, and
the exposed region has a structure in which the organic ligand bonded to the core structure is substituted with the functional group of the counter anion.

13. The method for manufacturing the semiconductor device as claimed in claim 11, wherein the exposure process includes using an electron beam or ultraviolet light.

14. The method for manufacturing the semiconductor device as claimed in claim 11, wherein the development process includes using an alkali developer or an organic developer to remove the exposed region or the unexposed region.

15. The method for manufacturing the semiconductor device as claimed in claim 11, wherein the tin oxide nanocluster is represented by Chemical Formula 1, 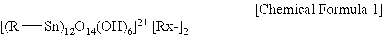
wherein in the Chemical Formula 1, R is the organic ligand, and Rx⁻ is the counter anion.

16. The method for manufacturing the semiconductor device as claimed in claim 11, wherein the functional group has a non-shared electron pair.

17. The method for manufacturing the semiconductor device as claimed in claim 11, wherein the functional group comprises a hydroxyl group, a phenol group, a thiol group, an amine group, a carboxylic acid group, an ester group, a carbonyl group, an amide group, a carbamate group, a urea group, a sulfoxy group, a sulfonyl group, a sulfone ester group, a cyanide group, an isocyanide group, or a combination thereof.

18. The method for manufacturing the semiconductor device as claimed in claim 11, wherein the counter anion comprises a carboxylate anion, a sulfonate anion, a sulfonamidate anion, or a combination thereof.

19. The method for manufacturing the semiconductor device as claimed in claim 11, wherein the counter anion comprises a conjugate base of an organic acid having a chemical structure of at least one of Structural Formulas 2 to 11: 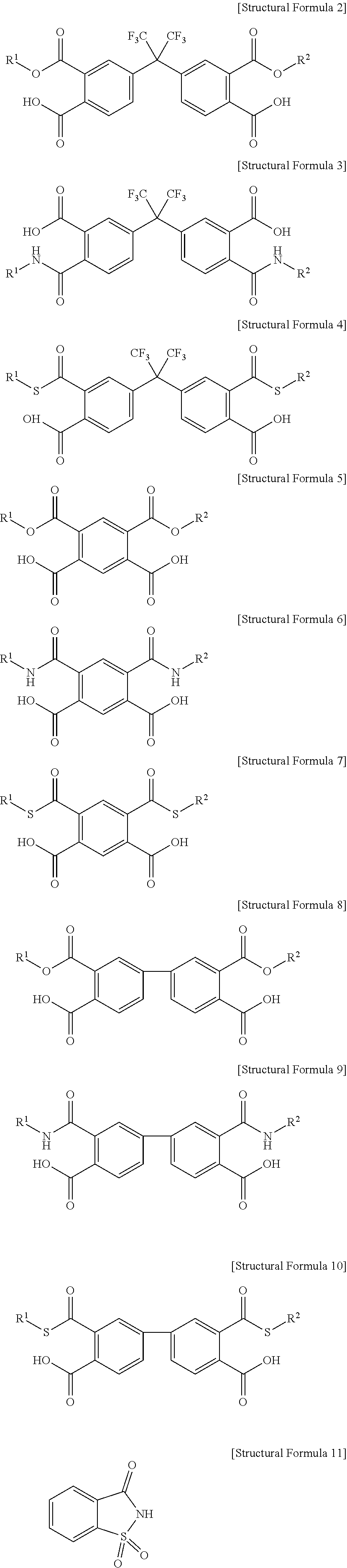
wherein in the Structural Formulas 2 to 11, R¹ and R² are alkyl groups having 6 to 18 carbon atoms.

20. The method for manufacturing the semiconductor device as claimed in claim 11, wherein the organic ligand is an alkyl group having 1 to 20 carbon atoms bonded to a tin element included in the core structure.
